(19) United States
(12) Patent Application Publication
(10) Pub. No.: US 2021/0095369 A1
(43) Pub. Date: Apr. 1, 2021

(54) KIRIGAMI-INSPIRED STRAIN-INSENSITIVE SENSORS

(71) Applicant: The Board of Trustees of the University of Illinois, Urbana, IL (US)

(72) Inventors: SungWoo NAM, Savoy, IL (US); Keong YONG, Urbana, IL (US); Subhadeep DE, Hillsboro, OR (US); Narayana R. ALURU, Urbana, IL (US); Hyochan LEE, Urbana, IL (US); Ezekiel Y. HSIEH, Urbana, IL (US)

(21) Appl. No.: 17/010,202

(22) Filed: Sep. 2, 2020

Related U.S. Application Data
(60) Provisional application No. 62/895,323, filed on Sep. 3, 2019.
(60) Provisional application No. 62/898,949, filed on Sep. 11, 2019.

(51) Int. Cl. C23C 14/18; C23C 16/26; C23C 16/56; G01D 5/14

(52) U.S. Cl. CPC C23C 14/18; G01D 5/14; C23C 16/56; C23C 16/26

(57) ABSTRACT

Provided here are sensors characterized by strain-insensitivity, the sensors comprising: a sheet in electrical communication with a positive electrode and a negative electrode; wherein the sheet comprises: an electrically conductive primary layer in electrical communication with the positive electrode and the negative electrode; at least one active-sensing region comprising at least one sensor-portion of the primary layer and in electrical communication with the positive electrode and the negative electrode; wherein the sensor is configured to perform sensing during use at the at least one active-sensing region; and at least one perforated region having a perforation design configured to provide for the sensor's strain-insensitivity.

### CROSS-REFERENCE TO RELATED APPLICATIONS

This application claims the benefit of priority to U.S. Provisional Patent Application No. 62/895,323, filed Sep. 3, 2019, and U.S. Provisional Patent Application No. 62/898,949, filed Sep. 11, 2019, each of which is hereby incorporated by reference in its entirety.

### STATEMENT REGARDING FEDERALLY SPONSORED RESEARCH OR DEVELOPMENT

This invention was made with government support under Award Numbers EEC-1720701, MRSEC DMR-1720633, CMMI-1554019, awarded by the National Science Foundation, Award Numbers FA2386-17-1-4071 and FA9550-16-1-0251, awarded by the Air Force Office of Scientific Research, Award Number N00014-17-1-2830, awarded by the Office of Naval Research, and Award Number NNX16AR56G, awarded by the National Aeronautics and Space Administration. The government has certain rights in the invention.

### BACKGROUND OF INVENTION

Retention of device functionalities under high mechanical strain is desirable for applications which are subjected to active strain environments. For example, devices worn on skin may encounter high degrees of strain due (e.g., 55%) to normal human motion. Strain can induce measurement artifacts and/or decrease the signal-to-noise ratio. At the same time, applications such as skin-mounted sensors have practical limitations in terms of size and weight. Some latest approaches for addressing this issue include, for example, use of integrated nanomaterials in stretchable polymers or pre-strained flexible elastomeric substrates to impart mechanical flexibility or stretchability into otherwise low strain limit nanomaterials. However, the resulting variance of electrical signal due to intrinsic piezoresistivity or premature failure modes can lead to unwanted strain dependency for intended applications. Even use of advanced materials such as graphene presents does not, alone, address the issue of strain, at least because graphene has been shown to preserve conductance at only very low degrees of strain (e.g., 6.5%). Moreover, devices in applications such as skin-mounted sensors experience more than one type of strain, such as uniaxial and/or biaxial strain with torsion, and varying ranges of each type of strain. Altogether, this creates a demanding set of challenges that have been unmet in the field.

### SUMMARY OF THE INVENTION

Provided herein are strain-insensitive sensors and associated methods that address at least the above-noted challenges by decoupling desired measurement signals from mechanical stretchability-induced electrical signal changes. These strain-insensitive sensors are advantageous for a wide array of applications wherein electrical measurements are preferably decoupled from strain experienced by the devices, such as, but not limited to, wearable (e.g., skin-mounted) devices, such as for measuring health-related factors and environmental conditions. In some embodiments, sensors are provided having an island-bridge geometry, wherein bridge components are capable of physical deformation (e.g., via bending, twisting, buckling, titling, etc.) so as to reduce, or avoid, strain for island components, thereby providing strain-insensitivity.

Aspects of the invention disclosed herein include, a sensor characterized by strain-insensitivity comprises: a sheet in electrical communication with a positive electrode and a negative electrode; wherein the sheet comprises: an electrically conductive primary layer in electrical communication with the positive electrode and the negative electrode; at least one active-sensing region comprising at least one sensor-portion of the primary layer and in electrical communication with the positive electrode and the negative electrode; wherein the sensor is configured to perform sensing (during use) at the at least one active-sensing region; and at least one secondary layer covering or encapsulating the primary layer except at each sensor-portion; and at least one perforated region having a perforation design configured to provide for the sensor's strain-insensitivity. The secondary layer is preferably but not necessary and it can provide structural support, for example, to the primary layer, such as when the primary layer comprises or consists essentially of graphene. Use of a secondary layer, such as polyimide, as described in embodiments herein, can be a substitute for having the primary layer, such as graphene, suspended in a liquid medium, such as water. Having at least one secondary layer covering or encapsulating the primary layer can reduce the stress experienced by the primary layer of a sheet, particularly in an active-sensing region, when the sheet is strained. Decreasing an overall thickness of the assembly, such as by decreasing a thickness of the primary layer can reduce the stress experienced by a sheet when strained. Preferably in any sensor and method disclosed herein, the strain-insensitivity is characterized by a strain-induced change of at least one figure-of-merit of the sensor being less than 10% if the sheet is strained (or, in other words, in response to the strain experienced by the sheet when it is strained); wherein strain experienced by the strained sheet is characterized by uniaxial strain of at least 50%, multiaxial strain of at least 50%, torsional strain of at least 90°, or a combination of these (in response to which the sensor retains its strain-insensitivity). Preferably in any sensor and method disclosed herein, the sensor is characterized by strain-insensitivity at each active-sensing region or each sensor-portion. Preferably in any sensor and method disclosed herein, the perforated region comprises a perforated portion and a remaining portion. Preferably in any sensor and method disclosed herein, the sensor is configured to perform sensing at each sensor-portion.

Aspects of the invention disclosed herein include, a sensor characterized by strain-insensitivity comprises: a sheet in electrical communication with a positive electrode and a negative electrode; wherein the sheet comprises: an electrically conductive primary layer in electrical communication with the positive electrode and the negative electrode; at least one active-sensing region comprising at least one sensor-portion of the primary layer and in electrical communication with the positive electrode and the negative electrode; wherein the sensor is configured to perform sensing during use at the at least one active-sensing region; and a perforated region having a perforation design configured to provide for the sensor's strain-insensitivity; wherein the strain-insensitivity is characterized by a strain-induced change of at least one figure-of-merit of the sensor being less than 10% if the sheet is strained (or, in other words, a strain-induced change of at least one figure-of-merit of the sensor is less than 10% in response to the strain experienced by the sheet when it is strained); wherein strain experienced by the strained sheet is characterized by uniaxial strain of at least 50%, multiaxial strain of at least 50%, torsional strain of at least 90°, or a combination of these (in response to which the sensor retains its strain-insensitivity). Preferably in any sensor and method disclosed herein, the sensor is characterized by strain-insensitivity at each active-sensing region or each sensor-portion. Preferably in any sensor and method disclosed herein, the perforated region comprises a perforated portion and a remaining portion. Preferably in any sensor and method disclosed herein, the sensor is configured to perform sensing at each sensor-portion.

Preferably in any sensor and method disclosed herein, the strain-induced change of at least one figure-of-merit is less than or equal to 10%, preferably less than or equal to 8%, preferably less than or equal to 5%, preferably less than or equal to 1%, more preferably less than or equal to 0.75%, more preferably less than or equal to 0.5%, more preferably less than or equal to 0.25%, if the sheet is strained (or, in other words, during and in response to the strain experienced by the sheet when it is strained). Optionally in any sensor and method disclosed herein, the strain experienced by the strained sheet is characterized by uniaxial strain of at least 100%, multiaxial strain of at least 50%, torsional strain of at least 180°, or a combination of these (or, in other words, the sensor is capable of and configured to retain its strain-insensitivity during and in response to experiencing strain as such). Optionally in any sensor and method disclosed herein, the strain experienced by the strained sheet is characterized by uniaxial strain of at least 100%, multiaxial strain of at least 100%, torsional strain of at least 180°, or a combination of these (or, in other words, the sensor is capable of and configured to retain its strain-insensitivity during and in response to experiencing strain as such). Optionally in any sensor and method disclosed herein, the strain experienced by the strained sheet is characterized by uniaxial strain of at least 100%, multiaxial strain of at least 100%, torsional strain of at least 360°, or a combination of these (or, in other words, the sensor is capable of and configured to retain its strain-insensitivity during and in response to experiencing strain as such). Preferably in any sensor and method disclosed herein, the sensor is capable of and configured to retain its strain-insensitivity during and in response to the strain experienced by the strained sheet being characterized by: uniaxial strain of at least 50%; uniaxial strain of at least 100%; multiaxial strain of at least 50%; multiaxial strain of at least 100%; torsional strain of at least 90°; torsional strain of at least 180°; torsional strain of at least 360°; uniaxial strain of at least 50% and torsional strain of at least 90°; uniaxial strain of at least 100% and torsional strain of at least 90°; uniaxial strain of at least 50% and torsional strain of at least 180°; uniaxial strain of at least 50% and torsional strain of at least 360°; uniaxial strain of at least 100% and torsional strain of at least 180°; uniaxial strain of at least 100% and torsional strain of at least 360°; multiaxial strain of at least 50% and torsional strain of at least 90°; multiaxial strain of at least 100% and torsional strain of at least 90°; multiaxial strain of at least 50% and torsional strain of at least 180°; multiaxial strain of at least 50% and torsional strain of at least 360°; multiaxial strain of at least 100% and torsional strain of at least 180°; and/or multiaxial strain of at least 100% and torsional strain of at least 360°. Optionally in any sensor and method disclosed herein, the multiaxial strain is a biaxial strain. Optionally in any sensor and method disclosed herein, the torsional strain comprises a shear strain. Optionally in any sensor and method disclosed herein, the sensor is capable of and configured to retain its strain-insensitivity during and in response to the strain experienced by the strained sheet being characterized by a shear strain being greater than 0% and less than or equal to 50%, optionally selected from the range of 5% to 50%, optionally selected from the range of 10% to 50%, optionally selected from the range of 15% to 50%, optionally selected from the range of 20% to 50%, optionally selected from the range of 25% to 50%. Preferably in any sensor and method disclosed herein, the sensor is capable of and configured to retain its strain-insensitivity during, in response to, and after at least 100 cycles, preferably at least 200 cycles, more preferably at least 500 cycles, more preferably at least 700 cycles, more preferably at least 1000 cycles, of said strain experienced by the strained sheet. Preferably in any sensor and method disclosed herein, the sensor is capable of and configured to retain its strain-insensitivity during at least 100 cycles, preferably at least 200 cycles, more preferably at least 500 cycles, more preferably at least 700 cycles, more preferably at least 1000 cycles, of said strain experienced by the strained sheet.

Optionally in any sensor and method disclosed herein, strain experienced by the strained sheet corresponds to a strain applied to the sensor. Optionally in any sensor and method disclosed herein, the sensor is free of a pre-strained substrate and/or wherein the sheet is not held under strain by a pre-strained substrate. Optionally in any sensor and method disclosed herein, the sheet is free-standing. Optionally in any sensor and method disclosed herein, the sheet is not free-standing as a result of to a compressive force imparted by a pre-strained substrate. Preferably in any sensor and method disclosed herein, the sheet is not suspended in a liquid during use of the sensor. Preferably in any sensor and method disclosed herein, the perforation design is deterministic. Preferably in any sensor and method disclosed herein, the strain-insensitivity is further characterized by stress at the least one active-sensing region being at most 100 MPa, preferably at most 50 MPa, preferably at most 25 MPa, more preferably at most 10 MPa, more preferably at most 5 MPa, further more preferably at most 1 MPa, during and in response to the sheet being strained. Preferably in any sensor and method disclosed herein, the sheet is characterized by a stress distribution in response to the sheet being strained, the stress distribution being deterministic. Preferably in any sensor and method disclosed herein, a stress within 40%, optionally within 30%, optionally within 20%, of maximum stress is localized at locations of highest curvature at the at least one perforated region (or perforated portion thereof) during and in response to the sheet being strained. Optionally in any sensor and method disclosed herein, a location corresponding to stress within 40%, preferably within 20% of maximum stress is constant during and in response to the sheet being strained. Optionally in any sensor and method disclosed herein, the sheet is characterized by a uniaxial strain limit of at least 100%, preferably at least 120%, more preferably at least 150%, more preferably at least 175%, more preferably at least 200%, more preferably at least 250%. Optionally in any sensor and method disclosed herein, when the sheet is strained, the strain experienced by the strained sheet is applied to at least two ends of the sheet, the two ends being opposite of each other. Optionally the perforation design is further configured such that, during and in response to the sheet being strained, at least a portion of the sheet is characterized by an out-of-plane deformation. Preferably in any sensor and method disclosed herein, the out-of-plane deformation occurs at one or more perforated regions of the at least one perforated region during and in response to the sheet being strained. Optionally in any sensor and method disclosed herein, the perforation design is further configured such that, during and in response to the sheet being strained, the strain experienced by the strained sheet is less than an ultimate strain limit of the sheet when the strain experienced by the strained sheet is up to 325% of uniaxial strain.

Optionally in any sensor and method disclosed herein, the at least one figure-of-merit is selected from the group consisting of a strain gauge factor (SGF), a specific detectivity, a normalized photocurrent, a responsivity, a transconductance, efficiency, fill factor, turn-on voltage, minimum detectable analyte concentration, resistance or resistivity, a normalized change in resistance or resistivity, and any combination thereof. Optionally in any sensor and method disclosed herein, the at least one figure-of-merit comprises a strain gauge factor (SGF), and wherein the SGF is less than 0.1, preferably less than or equal to 0.05, preferably less than or equal to 0.02, more preferably less than or equal to 0.005, more preferably less than or equal to 0.0025, during and in response to the sheet being strained. Optionally in any sensor and method disclosed herein, the sensor is selected from the group consisting of a photodetector, a biological analyte sensor, a temperature sensor, a pressure sensor, a field-effect transistor, or a combination of these. Optionally in any sensor and method disclosed herein, the sensor comprises a plurality of sensor-portions and the plurality of sensor-portions are configured for sensing of a plurality of analytes (such as a biological analyte in a biological fluid, such as glucose in sweat) or environmental characteristics (such as temperature of subject and/or surrounding medium, pressure, and/or light). Optionally in any sensor and method disclosed herein, the biological analyte comprises glucose.

Optionally in any sensor and method disclosed herein, each active-sensing region is physically separated from the positive electrode or the negative electrode by a perforated region. Optionally in any sensor and method disclosed herein, each perforated region is separated from each other perforated region by one or more active-sensing regions. Optionally in any sensor and method disclosed herein, the sensor-portion is in electrical communication with the positive electrode via a first perforated region and in electrical communication with the negative electrode via a second perforated region. Optionally in any sensor and method disclosed herein, each active-sensing region is directly connected to at least one perforated region. Optionally in any sensor and method disclosed herein, each active-sensing region is directly connected to two or four perforated regions. Optionally in any sensor and method disclosed herein, the active-sensing region is non-perforated and/or does not comprise a perforation design. Optionally in any sensor and method disclosed herein, during and in response to the sheet being strained, the resulting stress is highest at a perforated region and lowest at an active-sensing region. Preferably in any sensor and method disclosed herein, the sensor is configured to perform sensing at each sensor-portion. Optionally in any sensor and method disclosed herein, the sheet comprises a plurality of active-sensing regions. Optionally in any sensor and method disclosed herein, the sensor comprises a plurality of the sheets. Optionally in any sensor and method disclosed herein, the sensor comprises one sheet and at least four active sensing regions. Optionally in any sensor and method disclosed herein, the sensor comprises the positive electrode and the negative electrode. Optionally in any sensor and method disclosed herein, the sensor comprises a plurality of positive electrodes, a plurality of negative electrodes, a plurality of perforated regions, and a plurality of active-sensing regions. Optionally in any sensor and method disclosed herein, the primary layer or the sensor-portion of the primary layer comprises graphene, a metal, and/or a metal alloy. Optionally in any sensor and method disclosed herein, the primary layer or the sensor-portion of the primary layer comprises graphene. Optionally in any sensor and method disclosed herein, the primary layer or the sensor-portion of the primary layer consists essentially of graphene. Optionally in any sensor and method disclosed herein, the primary layer or the sensor-portion of the primary layer comprises an electrically conductive carbon allotrope. Optionally in any sensor and method disclosed herein, the primary layer or the sensor-portion of the primary layer consists essentially of an electrically conductive carbon allotrope. Optionally in any sensor and method disclosed herein, a top-view area of the primary layer is at least 30%, optionally at least 40%, at least 50%, optionally at least 60%, optionally at least 70%, optionally at least 80%, optionally at least 85%, with respect to a top-view area of the sheet. Optionally in any sensor and method disclosed herein, a top-view area of the primary layer is equal to or within 20% of a top-view area of the sheet. Preferably in any sensor and method disclosed herein, each perforated region comprises a perforated portion and a remaining portion; wherein a top-view area of the remaining portion is 30% to 90%, optionally 35% to 90%, optionally 40% to 90%, optionally 45% to 90%, optionally 50% to 90%, optionally 55% to 90%, optionally 60% to 90%, optionally 30% to 85%, optionally 30% to 80%, optionally 30% to 75%, optionally 35% to 85%, optionally 40% to 85%, optionally 40% to 80%, of a top-view area of the respective perforated region. Preferably in any sensor and method disclosed herein, each perforated region comprises a perforated portion and a remaining portion; wherein a top-view area of the perforated portion is 10% to 70%, optionally 15% to 65%, of a top-view area of the respective perforated region. Preferably in any sensor and method disclosed herein, a thickness of the sheet is less than or equal to 100 μm, optionally less than or equal to 85 μm, optionally less than or equal to 75 μm, optionally less than or equal to 65 μm, optionally less than or equal to 50 μm, optionally less than or equal to 40 μm, optionally less than or equal to 30 μm, optionally less than or equal to 20 μm, optionally less than or equal to 10 μm.

Preferably in any sensor and method disclosed herein, the sheet comprises at least one secondary layer covering or encapsulating the primary layer outside of each sensor-portion. Preferably in any sensor and method disclosed herein, the secondary layer is electrically insulating. Optionally in any sensor and method disclosed herein, the secondary layer comprises at least one polymer. Optionally in any sensor and method disclosed herein, the at least one polymer is polyimide. Optionally in any sensor and method disclosed herein, the secondary layer is characterized by a Young's modulus selected from the range of 0.5 GPa to 7 GPa, or any range therebetween inclusively. Optionally in any sensor and method disclosed herein, the at least one secondary layer encapsulates at least 50%, optionally at least 55%, optionally at least 70%, optionally at least 80%, optionally at least 85%, of the primary layer except at (or, outside of) the at least one sensor-portion of the primary layer.

Optionally in any sensor and method disclosed herein, the perforation design or perforated portion comprises a repeating and/or a non-repeating pattern. Optionally in any sensor and method disclosed herein, the perforation design or perforated portion comprises spiral perforations, islands, fillets, radial perforations, or any combination of these. Optionally in any sensor and method disclosed herein, at least one perforated region, or perforated portion thereof, comprises at least 3, optionally at least 4, optionally at least 5, preferably at least 6, optionally at least 7, optionally at least 8, optionally at least 9, optionally at least 10, perforations or notches. Optionally in any sensor and method disclosed herein, at least one perforated region, or perforated portion thereof, comprises at least one perforation or notch having a perforation or notch length selected from the range of 1 mm to 3.5 mm, optionally 0.1 mm to 3.5 mm, optionally 1.5 mm to 3.5 mm, optionally 2 mm to 3.5 mm. Optionally in any sensor and method disclosed herein, at least one perforated region, or perforated portion thereof, comprises at least one hinge, optionally at least 3 hinges, optionally at least 4 hinges, optionally at least 5 hinges, preferably at least 6 hinges, optionally at least 7 hinges, optionally at least 8 hinges, optionally at least 9 hinges, optionally at least 10 hinges, having a hinge length selected from the range of 20% to 55% with respect to a neighboring or nearest perforation or notch length. Optionally in any sensor and method disclosed herein, at least one perforated region, or perforated portion thereof, comprises at least one beam, optionally at least 3 beams, optionally at least 4 beams, optionally at least 5 beams, preferably at least 6 beams, optionally at least 7 beams, optionally at least 8 beams, optionally at least 9 beams, optionally at least 10 beams, having a beam width selected from the range of 100 μm and 400 μm, optionally 100 t μm o 350 μm, optionally 200 μm to 400 μm, optionally 200 μm to 350 μm, optionally 250 μm to 400 μm, optionally 250 μm to 350 μm. Optionally in any sensor and method disclosed herein, the perforated region or perforated portion thereof comprises at least 3, optionally at least 4, optionally at least 5, preferably at least 6, perforations or notches, having a perforation or notch length selected from the range of 1 mm to 3.5 mm, a hinge length selected from the range of 20% to 55% with respect to the perforation or notch length, and/or a beam width selected from the range of 100 μm and 400 μm. Optionally in any sensor and method disclosed herein, the perforated region or perforated portion thereof comprises at least 3, optionally at least 4, optionally at least 5, preferably at least 6, perforations or notches, a perforation or notch length selected from the range of 1 mm to 3.5 mm, a hinge length selected from the range of 20% to 55% with respect to the perforation or notch length, and/or a beam width selected from the range of 100 μm and 400 μm. Optionally in any sensor and method disclosed herein, the perforation design comprises a plurality of internal cutouts and a plurality of external cutouts. Optionally in any sensor and method disclosed herein, each perforated region forms a bridge (i) between one active-sensing region and one of a positive electrode or a negative electrode or (ii) between two active sensing regions. Optionally in any sensor and method disclosed herein, the sensor is characterized by strain-insensitivity during and in response to multiaxial strain due to the sensor comprising a plurality of the perforated regions. Optionally in any sensor and method disclosed herein, each perforated region has a length along a length axis and a width; wherein the length is greater than the width. Optionally in any sensor and method disclosed herein, the sensor comprises a plurality of the perforated regions; wherein the plurality of the perforated regions comprises at least one perforated region having a first length axis and at least one perforated region having a second length axis; wherein the first length axis and the second length axis are different. Optionally in any sensor and method disclosed herein, each active-sensing region is physically (directly) connected to at least one perforated region (or perforated portion thereof) characterized by a first length axis and to at least one perforated region (or perforated portion thereof) characterized by a second length axis; wherein the second length axis is different from the first length-direction. Optionally in any sensor and method disclosed herein, the first length axis and the second length axis are perpendicular with respect to each other. Optionally in any sensor and method disclosed herein, each perforated region and each active-sensing region is at least partially suspended in air. Optionally in any sensor and method disclosed herein, each active-sensing region is fully suspended between two different perforated regions. Optionally in any sensor and method disclosed herein, each perforated region is physically connected to one positive electrode or one negative electrode. Optionally in any sensor and method disclosed herein, each perforated region is suspended except where physically connected or attached to one positive electrode or one negative electrode. Optionally in any sensor and method disclosed herein, each perforated region is: (i) between one active-sensing region and one of a positive electrode or a negative electrode, or (ii) between two active sensing regions; wherein each perforated region has a first end and a second end; and wherein the first end of each perforated region is physically connected to an active-sensing region or a positive electrode or a negative electrode and the second end of each perforated region is physically connected or attached to a different one of an active-sensing region or a positive electrode or a negative electrode. Optionally in any sensor and method disclosed herein, each active-sensing region is characterized by a length and a width; and wherein the length and/or width of each active-sensing region is equal to or within 20% of the width of each perforated region to which it is physically connected. Preferably in any sensor and method disclosed herein, the sensor is characterized by strain-insensitivity at each active-sensing region or each sensor-portion. Preferably in any sensor and method disclosed herein, the perforated region comprises a perforated portion and a remaining portion.

Aspects of the invention disclosed herein include, a method of making a strain-insensitive sensor comprising steps of: perforating a sheet according to a perforation design to form at least one perforated region of the sheet; providing the sheet in electrical communication with a positive electrode and a negative electrode; wherein the sheet comprises: an electrically conductive primary layer in electrical communication with the positive electrode and the negative electrode; and at least one active-sensing region comprising at least one sensor-portion of the primary layer and in electrical communication with the positive electrode and the negative electrode; wherein the sensor is configured to perform sensing during use at the at least one active-sensing region; and wherein the perforation design is configured to provide for the sensor's strain-insensitivity. Preferably in any sensor and method disclosed herein, the sheet further comprises at least one secondary layer covering or encapsulating the primary layer outside of each sensor-portion. Preferably in any sensor and method disclosed herein, the strain-insensitivity is characterized by a strain-induced change of at least one figure-of-merit of the sensor being less than 10% if the sheet is strained (or, in other words, in response to the strain experienced by the sheet when it is strained); wherein strain experienced by the strained sheet is characterized by uniaxial strain of at least 50%, multiaxial strain of at least 50%, torsional strain of at least 90°, or a combination of these (in response to which the sensor retains its strain-insensitivity).

Any of the methods and sensors, or sheet(s) thereof, can have any one or a combination of any embodiments of sensor, or sheet(s) thereof, described herein.

Without wishing to be bound by any particular theory, there may be discussion herein of beliefs or understandings of underlying principles relating to the devices and methods disclosed herein. It is recognized that regardless of the ultimate correctness of any mechanistic explanation or hypothesis, an embodiment of the invention can nonetheless be operative and useful.

### BRIEF DESCRIPTION OF THE DRAWINGS

FIGS. 1A-1F. Kirigami-inspired architecture for strain-insensitive graphene device. FIG. 1A. Schematic illustrations of the strain-insensitive graphene electrode. (b-d) Photographs of the kirigami architecture in (FIG. 1B) neutral position, (FIG. 1C) 360° twisted and 100% stretched, and (FIG. 1D) 360° twisted, respectively. Scale bars are 3.5 mm. FIGS. 1E-1F. Highly conformal kirigami structures on the surface of a human wrist under (FIG. 1E) flexion and (FIG. 1F) extension articulations, respectively. The insets show the magnified photographs of the delineated regions on the wrist.

FIG. 2. Schematic illustrations of fabrication steps for the kirigami-inspired graphene devices.

FIGS. 3A-3D. Strain-insensitive electrical measurements of a kirigami-inspired graphene electrode under different strain states. The strain-insensitive electrical measurement is conducted under (FIG. 3A) uniaxial strain ranging from 0 to 240%; (FIG. 3B) torsion strain up to 720° or two full revolutions; (FIG. 3C) mixed strain states including uniaxial strain, torsion, and shear; and (FIG. 3D) cyclic stretching between 0% and 120% up to 10,000 cycles.

FIGS. 4A-4K. Finite element analysis (FEA) of kirigami-inspired graphene structure under strain. FIGS. 4A-4C. Photographs of side view graphene electrode with increasing uniaxial tensile strain from 10% to 120%. Scale bar is 2 mm. FIGS. 4D-4F. Simulated results corresponding the strain effect for a-c on the graphene electrode.

FIG. 4G. Experimental observations and simulated results for z-displacement of the 8 kirigami edges as numbered in c. FIG. 4H. Simulated stress values at the edges of kirigami notches and the corresponding breaking/ultimate stress. FIGS. 4I-4K. FEA analysis illustrating the stress distribution and uniaxial strain limit of different kirigami designs.

FIGS. 5A-5C. Parametric studies of different kirigami designs and their corresponding strain limit. FIG. 5A. Different notch designs are evaluated including varying beam length, notch length, hinge length, and number of notches. FIG. 5B. Different polyimide thicknesses are evaluated and small stretchability variance is found for the chosen kirigami design and scale of interest. FIG. 5C. Drastic discrepancies in stretchability between two different device designs with respect to island width and notch length.

FIGS. 6A-6F. Kirigami-inspired strain-insensitive multi-functional graphene devices. FIG. 6A. Schematic illustrations of the kirigami design chosen for sensing application. Inset shows the photograph of the actual device. FIG. 6B. FEA simulation results on the stress distribution of the center island and the nearby notches at ˜196% uniaxial strain. FIGS. 6C-6D. Schematic illustrations of PBS-gated FET sensing and photodetection, respectively. FIG. 6E. Strain-insensitive am bipolar transfer curves of the PBS-gated graphene FET under 3 structural configurations. Photographs show the experimental configuration of PBS-gated FET under stretching and twisting. Scale bar is 5 mm. FIG. 6F. Normalized photocurrent (by photocurrent value measured with the incident laser power of 3 mW) of the graphene photodetector under 3 structural configurations and laser power ranging from 1 to 3 mW. N denotes neutral, T denotes 130% stretched, and S denotes 360° twisted.

FIG. 7. Raman spectrum for CVD synthesized graphene on copper foil.

FIG. 8. Strain-sensitive electrical characterization of buckle-delaminated crumpled graphene electrode. Biaxial pre-strains of ˜350% and 200% are applied on the elastomeric substrate before the graphene transfer. The normalized change in resistance as a function of uniaxial tensile strain from 0% to 200% in the larger substrate prestrained direction is presented. Inset shows the schematic illustration of crumpled graphene on flexible elastomer.

FIGS. 9A-9C. Kirigami electrode with restricted out-of-plane deformation by adhering to a VHB substrate. The kirigami electrode is uniaxially extended from (FIG. 9A) 0% to (FIG. 9B) 120%. FIG. 9C. The kirigami electrode exhibited limited strain-insensitivity in the case of restricted out-of-plane deformation.

FIGS. 10A-10C. Kirigami-inspired graphene electrode with PDMS as an encapsulation material. The kirigami electrode is uniaxially extended from (FIG. 10A) 0% to (FIG. 10B) 140%. Insets present the top view device images. FIG. 10C. The PDMS kirigami electrode exhibited strain-insensitivity below 50% uniaxial strain. All scale bars are 5 mm.

FIGS. 11A-11H. Simulated z-displacements and stress distribution of a kirigami design. FIG. 11A. Variables corresponding to the dimensions of kirigami design shown in FIGS. 4A-4H. FIG. 11B. Fixed experimental boundaries on glass slide and tracked edge profile of kirigami unit cell under varying uniaxial tensile strain for z-displacement shown in FIG. 4G. FIG. 11C. z-displacement of kirigami architecture at ˜129% uniaxial tensile strain. FIG. 11D. Fixed experimental boundaries on glass slide and tracked edge profile of kirigami unit cell under varying uniaxial tensile strain for stress distribution shown in FIG. 4H. FIG. 11E. Stress distribution of kirigami architecture at ˜129% uniaxial tensile strain. FIGS. 11F-11H. Evolution of stress distribution of kirigami architecture from 40% to 120%. Regions of maximum stresses occur at locations with highest change in curvature, and these regions remain constant throughout the buckling process.

FIGS. 12A-12B. Deformation modes of a twisted kirigami graphene. FIG. 12A. Displacement of kirigami when subjected to ˜113° rotation. FIG. 12B. Strain in torsional state.

FIGS. 13A-13E. Parametric studies of different kirigami designs and their corresponding strain limit. FIG. 13A. Different notch designs are evaluated including varying beam length, notch length, hinge length, and number of notches. FIG. 13B. Effects of different beam widths (where beam width is increased by decreasing notch width) to tune directional stretchability. FIG. 13C. Different row numbers (mow) to tune the uniaxial strain limit of kirigami designs. FIG. 13D. Different polyimide thicknesses are evaluated and small stretchability variance is found for the chosen kirigami design and scale of interest. FIG. 13E. Drastic discrepancies in stretchability between two different device designs with respect to island width and notch length.

FIG. 14. Uniaxial strain limit as a function of surface area by varying kirigami designs. The designs for kirigami-inspired graphene electrode, multi-row electrode, and graphene device are evaluated separately given the differences in design motif. Bottom left inset demonstrates the conformity and breathability of a kirigami graphene electrode on a wrist as a result of lower relative area coverage. Bottom middle inset shows how the relative area is measured.

FIGS. 15A-15B. Strain-insensitive graphene devices. FIG. 15A. Normalized transconductance plot derived from transfer curve shown in FIG. 6E. FIG. 15B. Normalized photocurrents as a function of 3 different structural configurations (neutral, 130% uniaxially stretched, and 360° twisted).

FIGS. 16A-16B. All-graphene FET with extended Au source and drain electrodes removed. FIG. 16A. Photograph of the FET without the inner meandering source and drain electrodes compared to FIG. 6A. Inset shows rendering of the active sensing region. Scale bar is 1 mm. FIG. 16B. Strain-insensitive ambipolar transfer curves of the PBS-gated all-graphene FET under 2 structural configurations (neutral and 150% uniaxially stretched).

FIGS. 17A-17B. Integrated Au gate electrode FET. FIG. 17A. Photograph of the FET with source, drain, and gate electrodes in a single plane. Inset shows a schematic drawing of the graphene FET active sensing region. Scale bar is 1 mm.

FIG. 17B. Strain-insensitive ambipolar transfer curves of the PBS-gated integrated Au electrode graphene FET under 2 structural configurations (neutral and 150% uniaxially stretched).

FIG. 18A. Schematic illustration of strain-insensitive glucose sensor device fabricated in a kirigami-patterned mesh structure. FIG. 18B. Graphene sensing channels and metal electrodes are embedded in polyimide. Photographs of the kirigami-patterned stretchable sensor at a (FIG. 18C) neutral state and a (FIG. 18D) 100% biaxially stretched state. Insets in (FIG. 18C) show photographs of graphene transistors (left) and temperature sensor (right) fabricated on islands, respectively. Lower image in (FIG. 18D) shows side-view out-of-plane deformation of a kirigami bridge.

FIGS. 19A-190. The changes in electrical resistance of the kirigami device under (FIG. 19A) twist angle (φ) up to 180°, (FIG. 19B) biaxial strain up to 100%. Inset images in FIG. 19A and FIG. 19B show von Mises stress distribution simulated by FEA and photographs of the kirigami-patterned device at φ=90° (viewed at an angle slightly tilted from vertical) and εₙ=100%, respectively. FIG. 19C. Time-resolved current of the kirigami device under dynamic stretching conditions. The device was biaxially stretched in two consecutive cycles from εₙ=0% to εₙ=100%. The stretching was initiated at time 0s. FIG. 19D. Changes in electrical resistance of the kirigami device under cyclic biaxial stretching between εₙ=0% and εₙ=100% up to 800 cycles.

FIG. 20A: Top view of the entire kirigami structure and von Mises stress distribution in the structure under biaxial nominal stress of 10 MPa (or biaxial nominal strain of 105%). FIG. 20B: Nominal stress-nominal strain curve of the kirigami structure. Inset shows the magnified plot for very small strains (εₙ<0.6%). FIG. 20C: Average principal strain in the island as a function of nominal strain. Inset shows strain distribution in the island under a biaxial nominal stress of 10 MPa. FIG. 20D: Schematic diagram of the unit cell of bridges and various geometric parameters. The unit cell comprises two P1 plates, two P2 plates, and one P3 plate. FIG. 20E: Top view and side view of the unit cell structure and stress distribution in the structure under nominal stress of 10 MPa (left) and 50 MPa (right). The thickness of kirigami structures in FIGS. 20A-20E is 10 μm. FIG. 20F: The correlation between FEA-simulated (ε_{10MPa}(t,g)) and analytically calculated (ι_{g}) nominal strain of kirigami structures at nominal stress of 10 MPa. FIG. 20G: Multiple microcracks and nanocracks (inset) formed in Au/Cr thin film deposited on the kirigami structure after stretching up to 100%. FIG. 20H: FEA simulation of stress distribution in Au thin film (50 nm) with initial cracks. FIG. 20I: FEA simulation of average strain in the Au thin film as a function of applied strain on the film.

FIG. 21A. Source-drain current (lips) versus gate bias voltage (V_{G}) of a solution-gated GFET at εₙ=0, 20, 40, 60, 80, 100%. Inset is a photograph of the experimental configuration with an island solution-gated GFET under stretching. FIG. 21B. Dirac voltage (upper) and normalized I_{DS} at V_{G}=0 V (triangle) and 1.5 V (square) (lower) as a function of εₙ. I_{DS} is normalized by I_{DS} at εₙ=0%. FIG. 21C. Resistance of temperature sensor as a function of temperature at εₙ=0% (black square) and εₙ=100% (red circle). FIG. 21D. Normalized strain-dependent resistance change of the temperature sensor from εₙ=0% to εₙ=100% as a function of temperature. FIG. 21E. I_{DS}-V_{G} curves of a GFET-based glucose sensor for different glucose concentrations. The measurement was carried out at εₙ=30%. FIG. 21F. Dirac voltage of the glucose sensor as a function of glucose concentration.

FIG. 22. Fabrication scheme for the kirigami device.

FIG. 23. Raman spectrum of graphene used in the kirigami device.

FIG. 24A. Graphene channels and metal electrodes are embedded in polyimide. The unit of measurement is micrometers. FIG. 24B. Cross-sectional scanning electron microscopy image of the kirigami device.

FIG. 25A. von Mises stress distribution in 10 μm-thick kirigami structure, and (FIG. 25B) principal strain distribution in the island region at a nominal stress of 0 (left), 10 (middle) and 50 MPa (right). FIG. 25C. Z-component displacement of 10 μm-thick kirigami structure showing the transition from in-plane bending to out-of-plane bending.

FIG. 26A. von Mises stress distribution (left) and (FIG. 26B) displacement (right) in the z-direction under torsion strain of 150°. Inset in FIG. 26A shows strain distribution in the island.

FIG. 27. Cracks formed near the tip of cut after fracture of Au/Cr/Polyimide kirigami structure.

FIG. 28A. Top view and side view of the unit cell structure and stress distribution in the structure under nominal stress of 10 MPa (left) and 50 MPa (right).

FIG. 28B. Rotation angle θ defined in FIG. 28A (black) and average principal strains in P1 (blue), P2 (green) and P3 (red) plates as a function of nominal strain.

FIG. 29A. Schematic diagram of the overall kirigami pattern, a single unit cell of a bridge, and various design parameters. The effect of the change in (FIG. 29B) CW, (FIG. 29C) BH, (FIG. 29D) CH, (FIG. 29E) BW, and (FIG. 29F) Won the nominal stress-nominal strain curve of kirigami structures. FIG. 29G. The correlation between nominal strain in kirigami structures with various design parameters at a nominal stress of 10 MPa and the dimensionless geometric parameter δₘ.

FIG. 30A. Nominal stress-nominal strain curves of kirigami structures having different thicknesses (left) and the magnified plot for small strains (εₙ<20%). FIG. 30B. Strains at the transition from in-plane bending to out-of-plane bending of kirigami structures as a function of thickness. FIG. 30C. Z-component displacement of 75 μm-thick kirigami structure showing the transition from in-plane bending to out-of-plane bending.

FIG. 31A. Strain of the black line (as indicated in inset schematic drawing) at the neutral plane as a function of nominal strain. FIG. 31B. Estimated resistance change of a line electrode following the black line as indicated in FIG. 31A at the neutral plane.

FIGS. 32A-32E. Average strain on the top plane (black) and the neutral plane (red) of an (FIG. 32A) island, (FIG. 32B) P1 plate, (FIG. 32C) P2 plate, and (FIG. 32D) P3 plate. (FIG. 32E) Ratio of average strain on the neutral plane to average strain on the top plane for an island (black), P1 plate (red), P2 plate (green), and P3 plate (blue).

FIG. 33. A schematic of an exemplary perforated region identifying certain features thereof.

FIG. 34. A schematic of an exemplary sensor, according embodiments herein, identifying certain features thereof.

FIG. 35. A schematic of an exemplary sensor, according embodiments herein, identifying certain features thereof.

FIG. 36. A blown up schematic of an exemplary sensor, according embodiments herein, identifying certain layers thereof.

### STATEMENTS REGARDING CHEMICAL COMPOUNDS AND NOMENCLATURE

In general, the terms and phrases used herein have their art-recognized meaning, which can be found by reference to standard texts, journal references and contexts known to those skilled in the art. The following definitions are provided to clarify their specific use in the context of the invention.

The term “strain-insensitivity” refers to a sensor characterized by performance that is substantially insensitive to or unchanged by strain experienced by at least portions of the sensor, such as a sheet that comprises an active-sensing region of the sensor. For example, preferably, one reason sensors disclosed herein can be characterized by strain-insensitivity is because the strain and/or stress (resulting from the strain imparted on the sensor, or sheet(s) thereof)(preferably strain and stress) is distributed primarily at the perforated regions of the sensor, or sheet(s) thereof, and minimally, if at all, at the active-sensing region(s), or more particularly, minimally if at all, at the sensor-portion(s) thereof. Therefore, substantial lack of strain and stress at the active-sensing region(s), preferably at the sensor-portion(s) thereof, allows the figure(s)-of-merit to be insensitive to the strain being imparted on or experienced by the sensor, or sheet(s) thereof. The design of the perforated region, having the deterministically determined perforation design, provides for this strain and/or stress (preferably strain and stress) distribution that distributes the stress at the perforated region(s) but minimally, if at all, at the active-sensing region(s). Preferably, the performance of the sensor is characterized by at least one figure-of-merit, such that the at least one figure-of-merit is substantially insensitive to or unchanged by the strain experienced by the at least portions of the sensor, such as a sheet of the sensor. For example, the figure-of-merit being substantially insensitive to the strain corresponds to the strain-induced change of the at least one figure-of-merit being less than or equal to 10%, preferably less than or equal to 9%, preferably less than or equal to 8%, preferably less than or equal to 7%, preferably less than or equal to 6%, preferably less than or equal to 5%, preferably less than or equal to 4%, preferably less than or equal to 3%, preferably less than or equal to 2%, preferably less than or equal to 1%, preferably less than or equal to 1%, preferably less than or equal to 0.9%, preferably less than or equal to 0.8%, preferably less than or equal to 0.7%, preferably less than or equal to 0.6%, preferably less than or equal to 0.5%, preferably less than or equal to 0.4%, preferably less than or equal to 0.3%, preferably less than or equal to 0.2%, more preferably less than or equal to 0.1%. Therefore, preferably, a sensor characterized by strain-insensitivity is a sensor capable of having and configured to have at least one figure-of-merit that is substantially insensitive to strain (as just described in the previous sentence) during and in response to one or more strains experienced by the sensor. The strain experienced by the sensor and/or sheet can be characterized as one or a combination of strain states (or, strain types), such as, but not limited to, uniaxial strain, biaxial strain, torsional strain (twisting), shear strain, or a combination of these. Thus, preferably, the performance of the sensor is characterized by at least one figure-of-merit wherein the at least one figure-of-merit is substantially insensitive to or unchanged by uniaxial strain, biaxial strain, multiaxial strain, and torsional strain experienced by the at least portions of the sensor, such as a sheet of the sensor. As used herein, a sensor characterized by strain-insensitivity is a strain-insensitive sensor. Preferably, sensors of the invention are strain-insensitive during and after at least 10, preferably at least 100, preferably at least 1000 cycles of strain. As used herein, cycles of strain, or a strain cycles, correspond to repetitions of a sensor transitioning between experiencing no or low strain and the sensor experiencing a higher strain. In any embodiment, the strain experienced by a sensor, or portion(s) thereof, such as a sheet, can be strain applied to the sensor, or the portion(s) thereof. For example, strain can be applied to a sheet of a sensor by the movement of the human subject's skin on which the sensor is mounted. Preferably, but not necessarily, the minimum strain of a strain cycle corresponds to a state of the sensor, or sheet thereof, before experiencing any strain or strain-induced stress (or, substantially zero strain). Preferably, but not necessarily, the maximum strain of a strain cycle corresponds to a given maximum strain value. For example, in embodiments, a sheet, of a sensor, uniaxially strained to 100% (the given maximum strain value in this case) for 100 cycles refers to the sheet transitioning 100 times between an unstrained state and a strain of 100%. Cycles of strain can be uniform, where each strain is cycled between the same two strain conditions in each cycle of a set of cycles. In practice, cycles of strain can also, or instead, be dynamic and non-uniform, such that each strain cycle of a set of cycles does not necessarily have the same minimum and maximum bounds (e.g., 0% strain to 100% strain to 30% strain to 150% strain), and optionally such that each cycle is not necessarily consisting of the same strain types as other cycles.

The term “strain-induced change” refers to a change due to strain. As used herein, strain-induced change can refer to change, due to strain, in a property, such as, but not limited to, a figure-of-merit of a sensor. A strain-induced change of a figure-of-merit of a sensor refers to change in the figure-of-merit due to strain experienced by the sensor. For any strain-insensitive sensor described herein, strain experienced by said sensor preferably, but not necessarily, refers to strain experienced by sheet(s) of said strain-insensitive sensor. As used herein, strain that is experienced by a sensor, or sheet thereof, can refer to strain applied to the sensor, or sheet thereof. As used herein, a “strained sensor” is a sensor experiencing strain. As used herein, a “strained sheet” is a sheet (of a sensor) experiencing strain. As used herein, a sensor whose sheet is strained is a sensor experiencing strain. For example, the strain which induces said strain-induced change (or lack thereof) can be applied strain, such as strain applied to the sensor by motion of a body party where the sensor is skin-mounted. A strain-induced change in a sensor's figure-of-merit is a useful measure of the sensor's performance as a result of strain experienced by the sensor. For example, strain can induce artifact electrical signals and/or induce an increase in a level of background signal and/or otherwise induce a degradation of the sensor's performance, which is reflected by a strain-induced change the sensor's figure-of-merit.

The term “figure-of-merit” refers to a measurable and quantified characteristic of a device, such as a sensor, that characterizes the performance of the device. The performance of a device can be characterized one or more than one figure-of-merit. The units of a figure-of-merit depends on the device or performance being characterized. A device can be useful for more than one application or measurement, such as to detect more than one type of environmental change, such that more than one figure-of-merit can be relevant to a device and a useful figure-of-merit can depend on the application of a device. Exemplary figures-of-merit include, but are not limited to, a strain gauge factor (SGF), a specific detectivity (e.g., for photodetector), a photocurrent under given conditions (optionally normalized photocurrent, e.g., for a photodetector), a responsivity (e.g., for photodetector), a transconductance (e.g., for transistor), efficiency (e.g., solar cell or light emitting diode), fill factor (e.g., solar cell), turn-on voltage (e.g., light emitting diode), minimum detectable analyte concentration (e.g., for a chemical or biochemical sensor), a resistance or resistivity under given conditions (such as normalized resistance or resistivity; such as normalized change in resistance (ΔR/R₀), as described herein, or normalized change in resistivity), and any combination thereof.

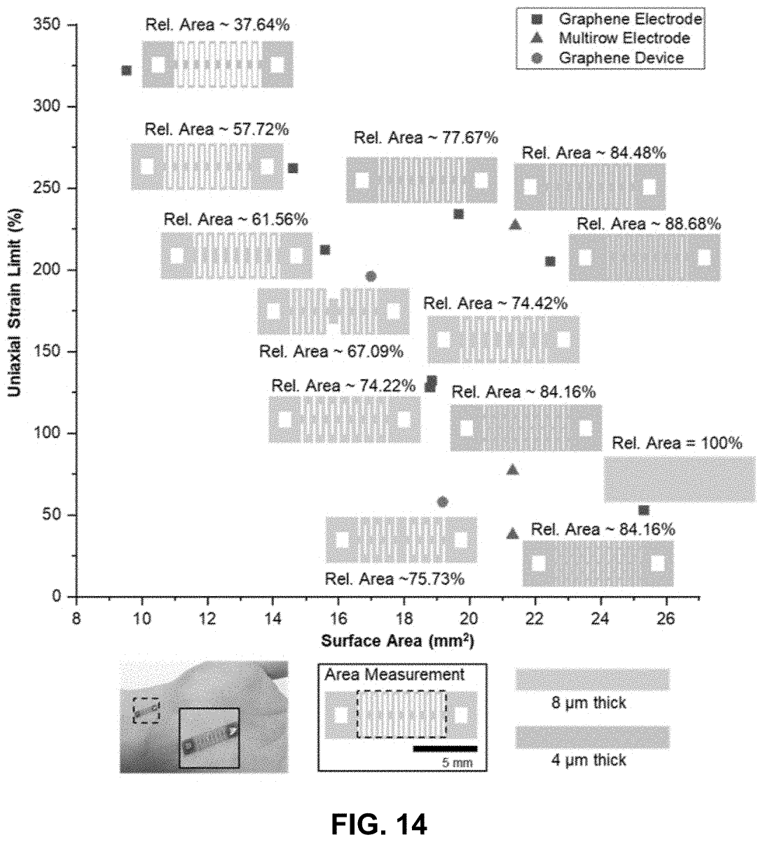

The term “relative perforated area” refers to an area of an element, such as a sheet of a sensor, that is perforated with respect to a total area of the sheet if it were free of perforations, such as perforations of the perforation design. In embodiments, as used herein, an area (e.g., perforated area or unperforated area) refers to a surface area of the sheet when the sheet is free of strain and is viewed from above (e.g., as represented in FIG. 14. In FIG. 14, “Rel. Area” corresponds to a relative unperforated area (e.g., “Rel. Area” of 37.64% as depicted in FIG. 14 corresponds to a relative perforated area of 62.36%). A higher relative perforated area, such in comparison of similar perforation designs, can correspond to higher stretchability of the perforated sheet.

The term “perforation design” refers to design of perforations of an element, such as a sheet of a sensor. The perforation design characterizes a distribution, shape(s), and contour(s) of perforations, thereby also characterizing the shape and contour(s) a perforated portion defined by the perforation design. As used herein, a “perforation” is generally a cut-out, hole, aperture, slit, incision, indentation, notch, gap, or other such region of the element where the element is absent, preferably when the element is viewed along an axis corresponding to the top-view area. Typically, a perforation can be formed by removing the respective portion of the element, such as by, but not limited to, etching a perforated portion of the element. For example, a perforation design and perforated region having the perforation design can be formed using appropriate nanofabrication and/or microfabrication techniques or processes. Optionally in any sensor and method disclosed herein, a perforation can be formed by forming the element in a configuration that includes the perforation. For example, a perforation design, perforated region having the perforation design, or remaining portion of a perforated region can be formed using a printing process, an additive manufacturing process, or another bottom up manufacture or growth method. For example, optionally, a remaining portion of a perforated region can be printed or grown according to a perforation design, without having to necessarily perform a perforation, cutting, or etching (for example, alternatively to etching/cutting/removing a rectangle perforation/notch out of a square sheet, one might be able to directly print/grow/form a square sheet having a missing rectangle perforation/notch therein). A perforation design can include a variety of features, such as notches, straight cuts or perforations, spiral or radial cuts or perforations, fillet corners, etc., and/or patterns of any of these.

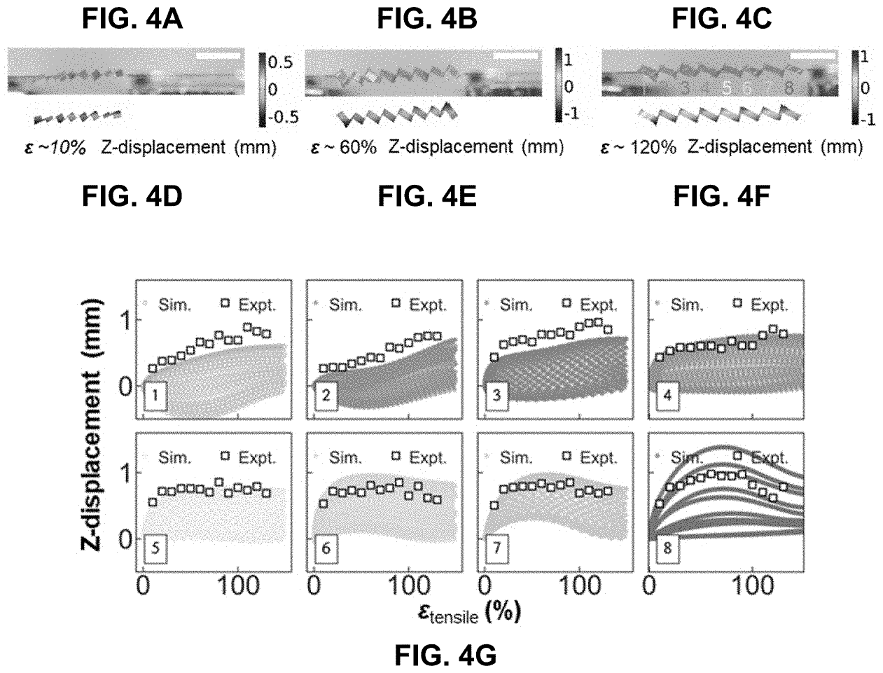

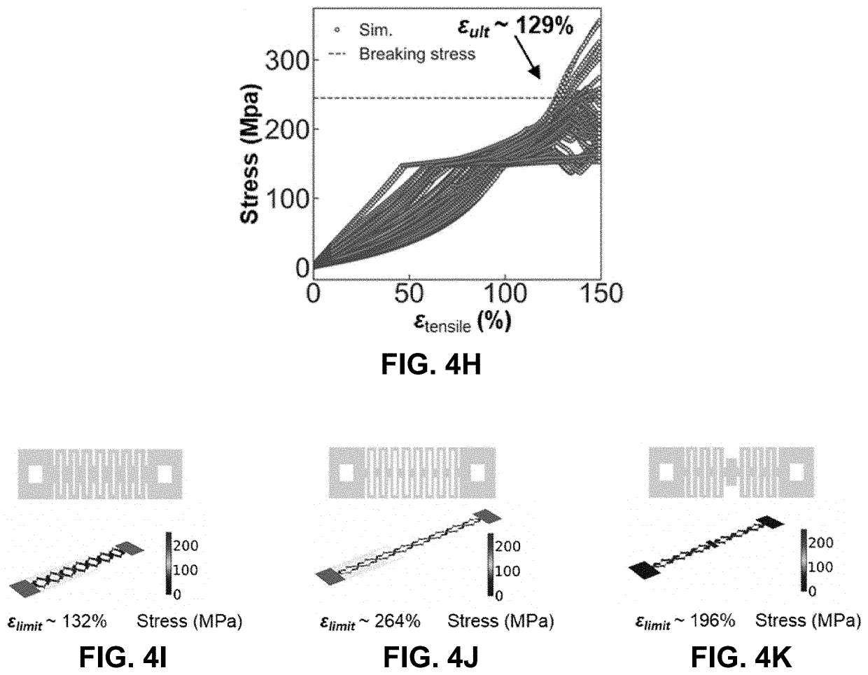

A “perforated region” of an element, such as of a sheet of a sensor, is a region comprising or characterized by the perforation design. The perforated region comprises a “remaining portion” of the element and a “perforated portion” of the element, wherein the perforated portion corresponds to the perforated design and is characterized by an absence of the element in the perforated region, and wherein the remaining portion corresponds to the portion of the element that is not absent in the perforated region or is remaining after the perforation design is applied to the perforated region. A perforated region of a planar element, such as a sheet or portion thereof, has a top-view area that is equivalent to the sum of a top-view area of the remaining portion of said perforated region and a top view area of the perforated portion of said perforated region. In an embodiment, for example, a perforated region corresponds to a bridge component of a sensor having an island-bridge geometry. As noted above, a perforation design characterizes a distribution, shape(s), and contour(s) of perforations thereby characterizing the shape and contour(s) the perforated portion defined by the perforation design. As described herein and shown in various figures, a perforated portion of a perforated region may be and typically is non-contiguous, comprising a plurality of disconnected, non-adjoining, or otherwise non-contiguous perforations. Likewise, as described herein throughout and shown in various figures, a remaining portion of a perforated region may be and typically is non-contiguous, comprising a plurality of disconnected, non-adjoining, or otherwise non-contiguous remaining sections. A perforated region, or remaining portion thereof, can include a variety of features, such as notches, hinges, beams, spiral or radial portions, fillet corners, etc., and/or patterns of any of these. Exemplary perforation designs and perforated regions are shown at least in FIGS. 4, 5, 6, 11, 13, 14, 18A, 20A-D, 24A, 28A, 29A, and others. The perforation design is determined or selected to provide for a sensor's strain-insensitivity, as described in embodiments herein, for example. For example, the perforation design can provide for stress to be concentrated or localized at deterministic, or intended, regions, such as regions of highest curvature, when the sheet experiences strain. In addition to the distribution, shape(s), and contour(s) of perforations, important variables that determine whether the sensor is strain-insensitive and the strain limits of the sensor's strain-insensitivity are the top-view area of a perforated portion (or, by correlation, the top-view area of a remaining portion) and the thickness of a thickness of the sheet, especially at the remaining portion. For example, if the top-view area of the perforated portion is too large, the perforated region may tear or otherwise fail at low strain. On the other hand, if the top-view area of the perforated portion is too small, a greater fraction of the stress and/or strain may be distributed in the active-sensing region(s) thereby eliminating the sensor's strain-insensitivity. For example, at 100% uniaxial strain, a maximum stress in a sheet of a sensor can be 117 MPa with 50 MPa and above of stress being concentrated at regions of highest curvature. For example, at 217% uniaxial strain, a maximum stress in a sheet of a sensor can be 226 MPa with 120 MPa and above of stress being concentrated at regions of highest curvature. For example, the portion of the sheet not corresponding to region(s) of highest curvature experiences less than 60% of the maximum stress. In each instance, the term “bridge” as used in Examples 1-4 herein refers to an exemplary “perforated region” of a sensor disclosed herein, according to certain embodiments.

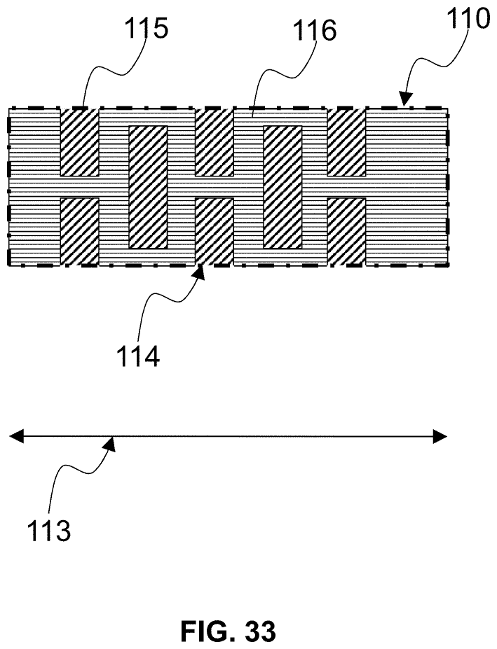

For example, FIG. 33 shows a schematic, for illustration purposes, for a perforated region 110 (outlined by the dashed perimeter line). Perforated region 110 comprises a perforation design 114. Perforation design 114 defines a perforated portion 115. Perforation region 110 comprises perforated portion 115 and a remaining portion 116. Perforated region 110 is characterized by a length axis 113. As illustrated, the top-view area of perforated region 110 is equivalent to the sum of the top-view area of perforated portion and the top-view area of remaining portion 116.

The term “top-view area” of an element or portion thereof refers to a two-dimensional geometric area of the element or portion thereof when it is viewed along an axis that is perpendicular to a primary geometric plane that characterizes the element or portion thereof. For example, the primary geometric plane that characterizes an element is a plane defined by the two spatial axes which define a majority of the object, or the two spatial axes corresponding to the two (of three) largest spatial dimensions of the object (e.g., x-y plane of an element having x, y, and z dimensions; e.g., geometric plane defined by length and width of a planar element, such as a sheet, having a thickness dimension that is less than each of the width and length dimensions). Preferably, the top-view area refers to the top-view area determined when the element is at rest or otherwise not subject to strain, such as an unstrained sensor.

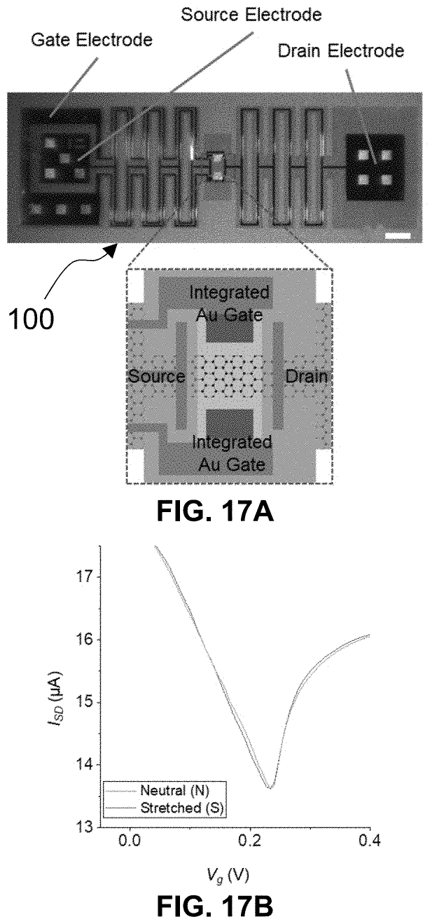

The term “active-sensing region” corresponds to a region, of a sensor, or sheet thereof, where the sensor is configured to perform sensing during use of the sensor. Each active-sensing region can include at least one sensor-portion of an electrically conductive primary layer, wherein the sensor's sensing occurs more particularly at the at least one sensor-portion. For example, the sensor-portion is where the electrically conductive primary layer (e.g., a metallic or graphene layer) can be exposed to an analyte (e.g., glucose in a biological fluid) or an environmental characteristic (e.g., temperature of a subject, light, etc.), thereby providing for the sensor's sensing of said analyte or environmental characteristic. Preferably, but not necessarily, each active-sensing region is a non-perforated region, being free of a perforation design or a perforated portion. In an embodiment, for example, an active sensing region corresponds to an island component of a sensor having an island-bridge geometry. For example, a biological analyte sensor (e.g., a glucose sensor; e.g., sensor of glucose in sweat) performs sensing of the biological analyte(s) at the active-sensing region(s), or more particularly at sensor-portion(s) thereof. For example, a biological analyte sensor can measure a concentration of the biological analyte(s) in proximity of the active-sensing region(s), or more particularly at sensor-portion(s) thereof. For example, the bottom, zoomed-in photo, of FIG. 17A shows an active-sensing region of the sensor imaged in the top image of FIG. 17A. In each instance, the term “island” as used in Examples 1-4 herein refers to an exemplary “active-sensing region” of a sensor disclosed herein, according to certain embodiments.

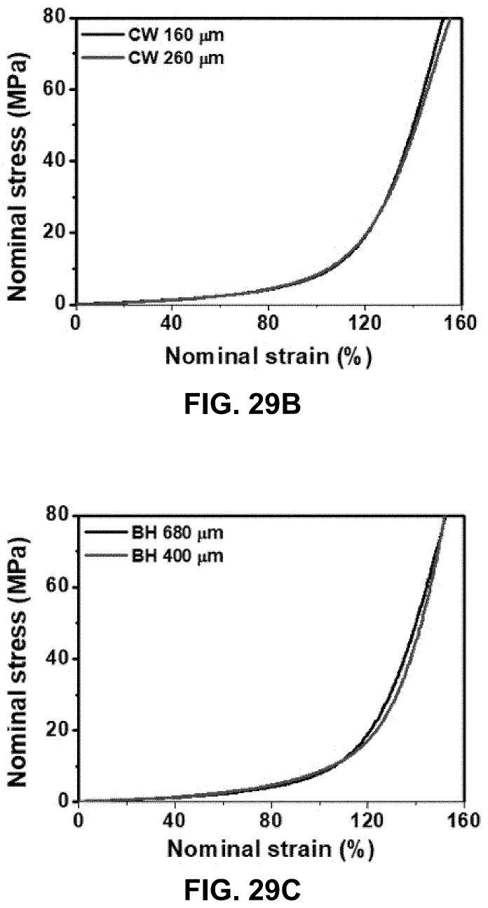

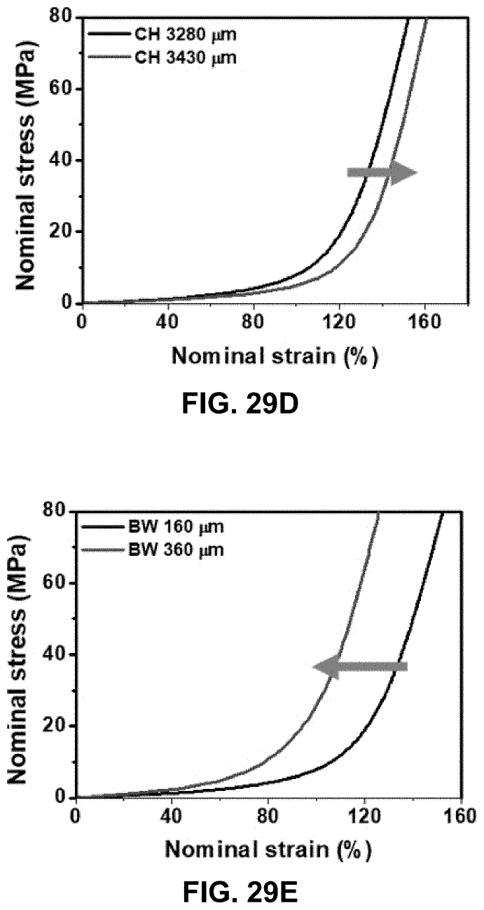

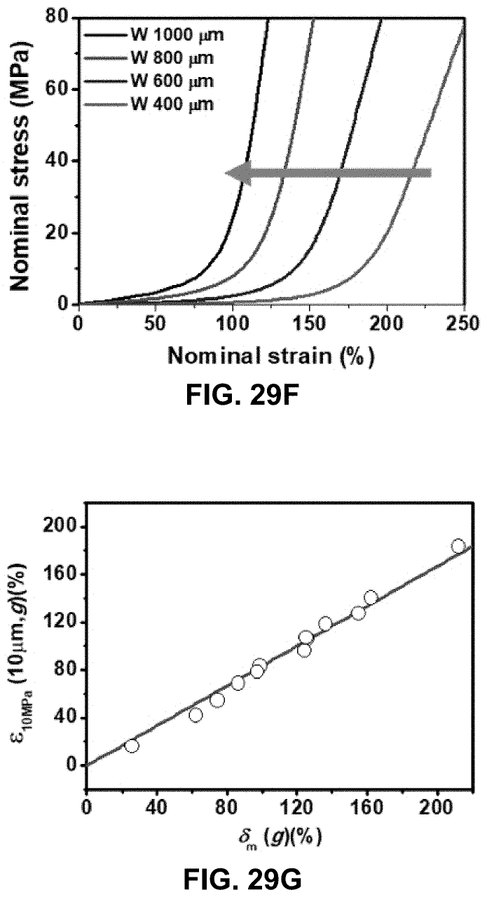

The term “notch” refers to a type of perforation. A notch, as may be recognized by one of skill in engineering and/or materials science fields, such as referring to a deliberately introduced v-shaped, u-shaped, circular cut-out, internal cutout, external cutout, or another such perforation in an element, particularly a planar element. The term “internal cutout” refers to a hole in a planar object, such as a sheet, wherein the hole is surrounded by the planar object in the geometric plane characterizing said planar object. The hole can have any shape, including a rectangular shape, a circular shape, a combination of these. The term “external cutout” refers to a cutout or notch in a planar object, such as a sheet, such that the cutout is open or not fully surrounded by the planar object in the geometric plane of said planar object. For example, the perforation design shown in FIG. 29A comprises both internal cutouts and external cutouts.

The term “electrical communication” refers to elements in direct or indirect communication via a flow of electrons. For example, electrical current can pass between elements that are in electrical communication. For example, a sheet of a sensor, or the electrically conductive primary layer thereof, can be in electrical communication with at least one electrode, such as electrical current can flow between the sheet and the at least one electrode.

The term “suspended” refers to an element, or portion or region thereof, being suspended, hanging, or otherwise positioned in a fluid medium, preferably a gaseous medium, preferably air, such that the suspended element, or portion or region thereof, is surrounded (e.g., above and below) by the fluid medium. Preferably, a suspended element (or suspended portion thereof), such as a suspended active-sensing region, is not held under strain or pre-strained by a substrate at any point along the suspended element (or suspended portion thereof). For example, a first element has a suspended portion between two points of physical attachment to other elements, such the suspended portion is surrounded by a fluid medium, optionally except where physically attached to said other elements. For example, a bridge over a river may be suspended between two points of physical attachment (the opposite banks of a river).

The term “multiaxial strain” refers to strain along two or more axes. A quantitative amount of multiaxial strain refers to that amount of strain along each of the axes of said multiaxial strain. As an illustrative example, a multiaxial strain of 50% corresponds to strain along a plurality of axes (e.g., 3 axes) wherein strain along each of the plurality of axes is 50%.

In an embodiment, a composition or compound of the invention, such as an alloy or precursor to an alloy, is isolated or substantially purified. In an embodiment, an isolated or purified compound is at least partially isolated or substantially purified as would be understood in the art. In an embodiment, a substantially purified composition, compound or formulation of the invention has a chemical purity of 95%, optionally for some applications 99%, optionally for some applications 99.9%, optionally for some applications 99.99%, and optionally for some applications 99.999% pure.

### DETAILED DESCRIPTION OF THE INVENTION

In the following description, numerous specific details of the devices, device components and methods of the present invention are set forth in order to provide a thorough explanation of the precise nature of the invention. It will be apparent, however, to those of skill in the art that the invention can be practiced without these specific details.

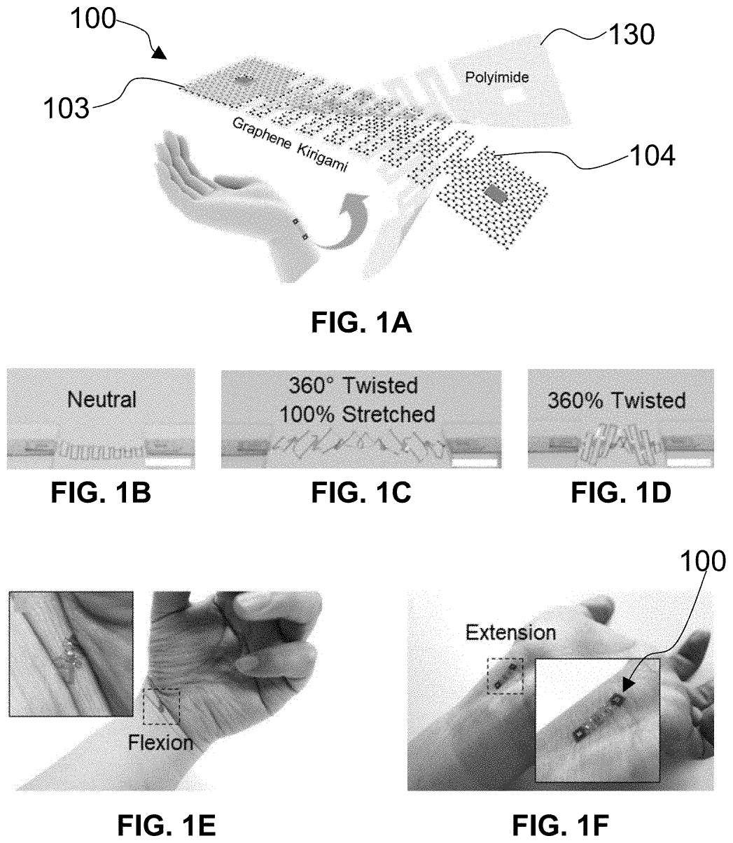

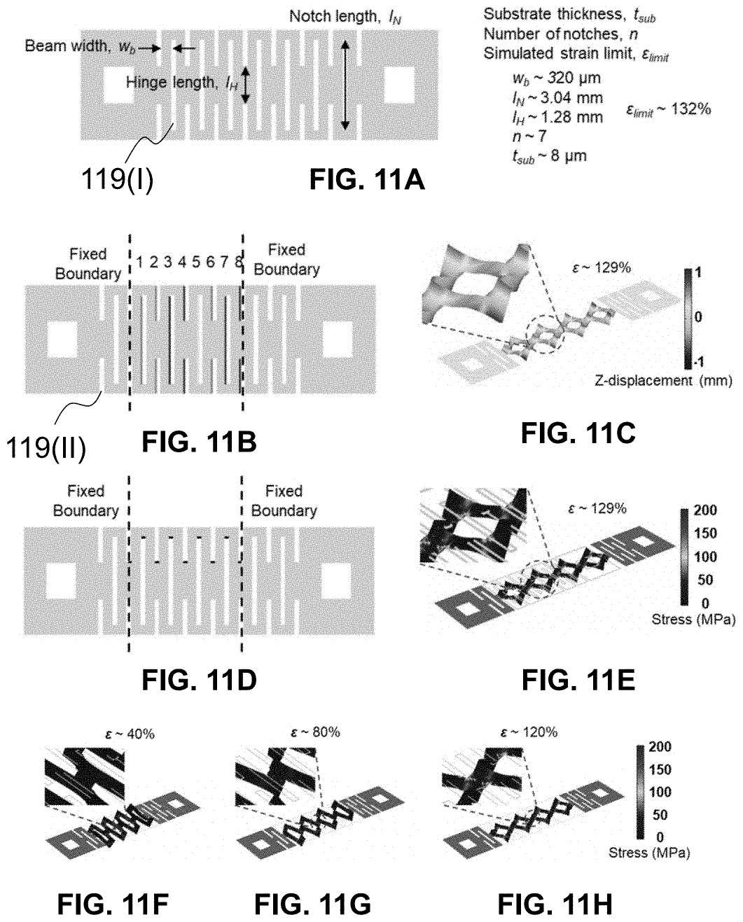

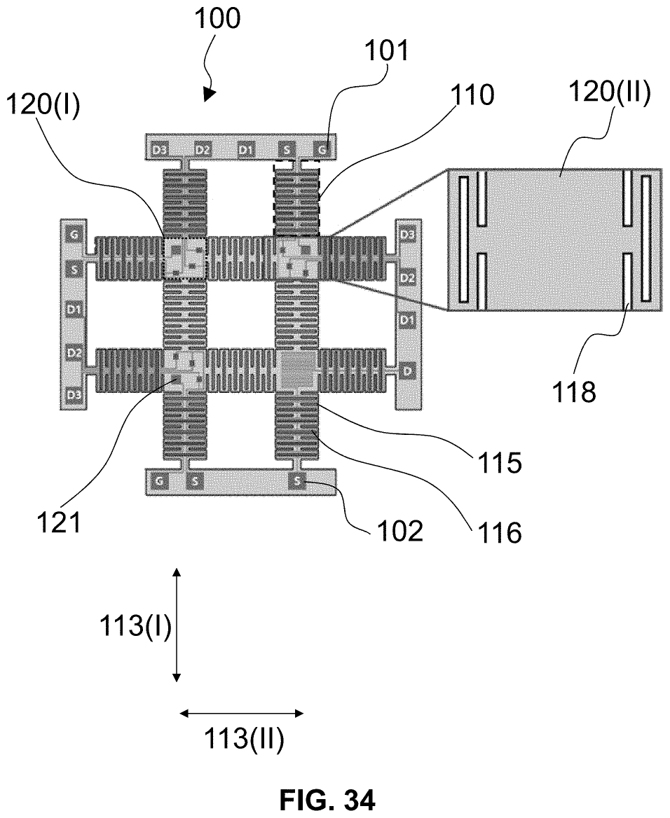

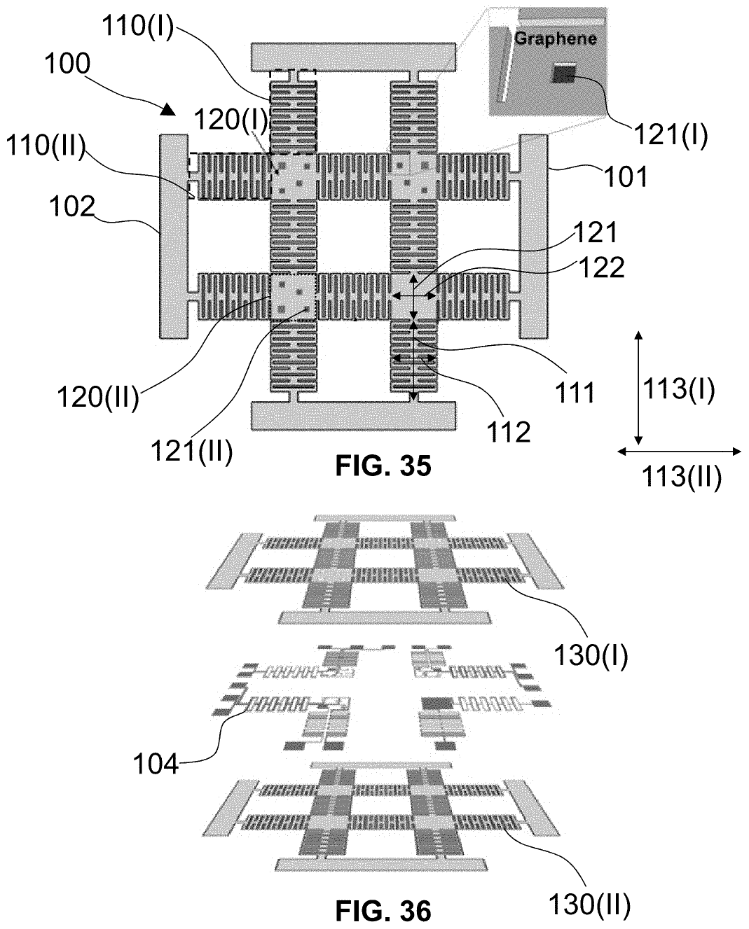

Various drawings herein, such as FIGS. 1, 5A-5C, 6A, 11A-11D, 13A-13E, 14, 16A, 17A, 18A-18B, 20D, 20H, 22, 24A, 29A, and 33-36, show exemplary sensors and identify certain features, according to embodiments. Generally, a Roman numeral in a numerical label or annotation identifying an element in these figures corresponds to one of a plurality of instances of the element (e.g., (I) or (II) corresponds to a first or a second, respectively, instance of an element). A sensor 100 comprises a sheet 103, which comprises an electrically conductive primary layer 104. Sheet 103 preferably comprises at least one secondary layer 130, such as a first (e.g., bottom) secondary layer 130(I) and a second (e.g., top) secondary layer 130(II). Each secondary layer 130 is optionally formed of a polyimide. A sensor may comprise electrodes, such as a positive electrode 101 and a negative electrode 102. A sensor may comprise a plurality of each type of electrode. Depending on how the sensor, including the electrically conductive primary layer, is designed, a single contact pad may be used as one electrode, as a plurality of electrodes, and optionally as more than one type of electrode. Sensor 100 comprises at least one perforated region 110 (e.g., 110(I), 110(II), etc.) and at least active-sensing region 120 (e.g., 120(I), 120(II), etc.). Each active-sensing region comprises at least one sensor-portion 121 of electrically conductive primary layer 104 (e.g., sensor portions 121(I), 121(II), etc.). A perforated region 110 (such as outlined by the dashed perimeter line in FIG. 33). Each perforated region 110 comprises a perforation design 114. Perforation design 114 defines a perforated portion 115. Perforation region 110 comprises perforated portion 115 and a remaining portion 116. Each perforated region 110 is characterized by a length 111, a width 112, and a length axis 113. Sensor 100 may comprise at least one perforated region 110(I) having a length axis 113(I) and at least one perforated region 110(II) having a length axis 113(II). As illustrated in FIG. 33, the top-view area of perforated region 110 is equivalent to the sum of the top-view area of perforated portion and the top-view area of remaining portion 116. Each active-sensing region 120 is characterized by a length 121 and a width 122. Each perforation design 114 and each perforated portion 115 may comprise a notch or perforation 119, such as an internal cutout 117 and/or an external cutout 118. For example, FIGS. 11A and 11B show examples of notch or perforation 119(I), which is an internal cutout as shown, and a notch or perforation 119(II), which is an external cutout as shown.

The invention can be further understood by the following non-limiting examples.

### Example 1: Overview and Certain Embodiments of Strain-Insensitive Sensors and Associated Methods

Provided below are non-limiting embodiments and non-limiting examples of the disclosed invention. In the following description, numerous specific details of the devices, device components and methods of the present invention are set forth in order to provide a thorough explanation of the precise nature of the invention. It will be apparent, however, to those of skill in the art that the invention can be practiced without these specific details.

We demonstrated strain-insensitive, surface conformal graphene-based stretchable electrodes and multifunctional devices by adopting kirigami-inspired architectures. While liquid-suspended graphene kirigami has been demonstrated, we sought to overcome its limitation to aqueous environment and realize strain-insensitive sensing under mixed strain states. First, we exploited the ability of kirigami-inspired perforations or notches to tune the stiffnesses of our devices in order to improve conformity and breathability on a human skin. Second, we demonstrated controllable stretchability and preserved electrical signal up to 240% uniaxial strain and other mixed strain states by systematic investigations of multitude graphene kirigami designs. Third, we found great correspondence between experimental observations and simulated deformity of kirigami unit cells under strain which implied the applicability of computational driven design optimization. Finally, we achieved strain-insensitive solution-gated graphene field-effect transistor (FET) and photodetection under high tensile and torsional strain states by strategically redistributing stress concentration away from the active sensing elements via kirigami notches and island-bridge motif or island-bridge geometry. Kirigami (e.g., kirigami notches, kirigami bridges, etc.) is an exemplary characterization of exemplary perforation designs, useful in embodiments herein. An island-bridge motif or island-bridge geometry, as described herein, corresponds to a sensor device, or sheet thereof, having at least one island and at least one bridge, wherein the at least one island is physically connected to at least one bridge. A bridge is an exemplary perforated region, according to embodiments herein. An island is an exemplary active-sensing region, according to embodiments herein.

The graphene is sandwiched in between two ultrathin polyimide layers (−2-4 μm) and the assembly is patterned into a kirigami shape. We intended the active sensing element to be at the neutral plane to further minimize the stress subjected to it during deformation. The principle of kirigami is based on patterning the two-dimensional (2D) precursor surface with cuts or notches, where subsequent strain will transform it into a reconfigurable 3D architecture owing to mechanical bistabilty at the vicinity of those patterns. As the kirigami-inspired graphene electrode is stretched uniaxially, the unit cell is subjected to out-of-plane buckling with gradual tilting towards the vertical direction through both bending and twisting accompanied by the widening of unit cell. By introducing strategic notches, kirigami now provides a distinct route to locally relieve stresses through these geometric features. Suppression of strain profile around the active sensing region is critical to strain-insensitive performance of flexible/stretchable devices. Notably, the perforated/notch kirigami designs further reduced the effective stiffness of the ultrathin form factor structure, therefore improving the conformity and breathability of the device, which is conducive to long-term wearable applications.

Retention of device functionalities under high mechanical strain is desirable for applications which are subjected to active strain environments. Previous studies have utilized either integrated nanomaterials in stretchable polymer, pre-strained flexible elastomeric substrate, or multi-layered nanomaterials to impart mechanical flexibility or stretchability in otherwise low strain limit nanomaterials. However, the variance of electrical signal due to intrinsic piezoresistivity or premature failure modes would lead to unwanted strain dependency for intended applications. While exceptional bendability could be achieved by adopting an ultrathin form factor or placing the active sensing element at the neutral plane, the sensor may still fail prematurely under tension.

In order to retain functional electrical properties of a device as desired, there is a great need to decouple desired measurement signals from mechanical stretching induced electrical signal changes. Kirigami, an art of paper cutting, in general has been well established as a template to create materials with reconfigurable morphological responses. In fact, mechanically driven form of three-dimensional (3D) mesostructures by kirigami micro/nanomembranes has demonstrated topographical complexity that significantly exceeded those possible with other schemes.

Our study demonstrated that the deformation engineering of atomically-thin materials' devices has the potential to decouple desired measurement signals from mechanical stretchability induced electrical changes. Our research will allow for the realization of enhanced stretchability, strain-insensitive, surface-conformal and breathable skin electronics. The kirigami-inspired stretchable architecture also has the future potential for multifunctional sensor integrations demanded in wearable health monitoring applications.

Kirigami/origami is an ancient art of paper cutting/folding. However, this art has the potential to improve the stretchability of micro-nano systems, at the same time providing a means to preserve electrical signals under active working environment.

The primary feature of our finding is the ability to decouple desired measurement signals from mechanical stretchability induced electrical signal changes. In other words, it enables strain-insensitive devices. In the meanwhile, its perforated ultrathin form factor also improves the conformity and breathability on human skin conducive to wearables.

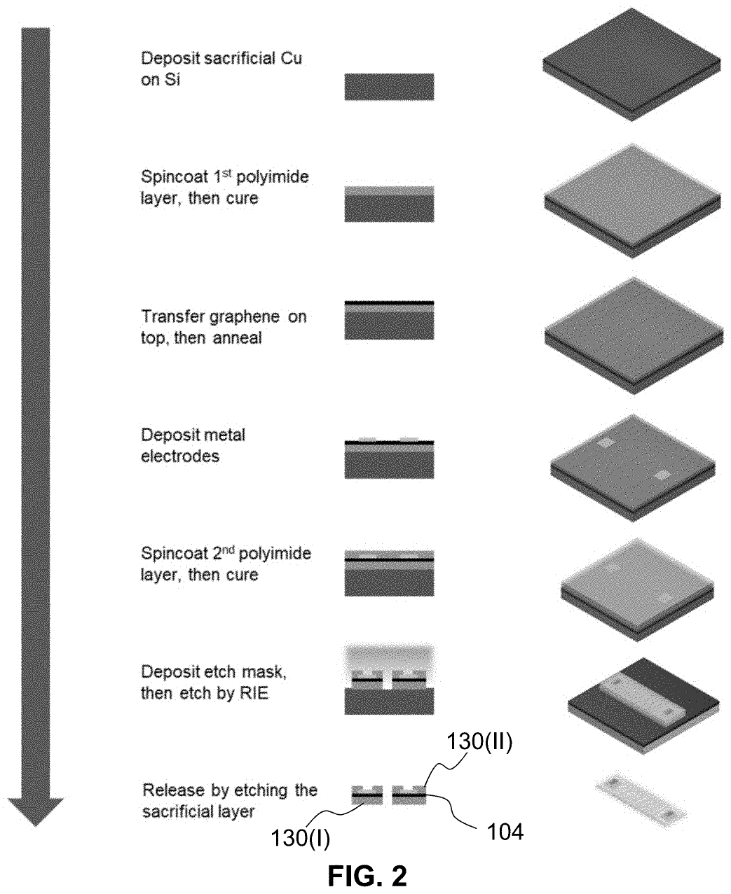

The architecture of our kirigami-inspired devices is illustrated in FIG. 1A. The graphene is sandwiched in between two ultrathin polyimide layers (˜2-4 μm) and the assembly is patterned into kirigami shape (FIG. 2). We intended the active sensing element to be at the neutral plane to further minimize the stress subjected to it during deformation. The principle of kirigami is based on patterning the two-dimensional (2D) precursor surface with cuts or notches, where subsequent strain will transform it into a reconfigurable 3D architecture owing to mechanical bistability at the vicinity of those patterns. Moreover, topographical deformation of a kirigami structure is shown to be highly dependent on the applied strain states (FIGS. 1B-1D), such as mixed tensile and torsional strain (FIG. 1C) or just torsional strain (FIG. 1D). As a preliminary test for structural conformity, we mounted the kirigami architecture on the surface of a human wrist and strained under different wrist articulations, including flexion and extension (FIGS. 1E-1F). Notably, the perforated/notch kirigami designs further reduced the effective stiffness of the ultrathin form factor structure, therefore improving the conformity and breathability of the device, which is conducive to long-term wearable applications.

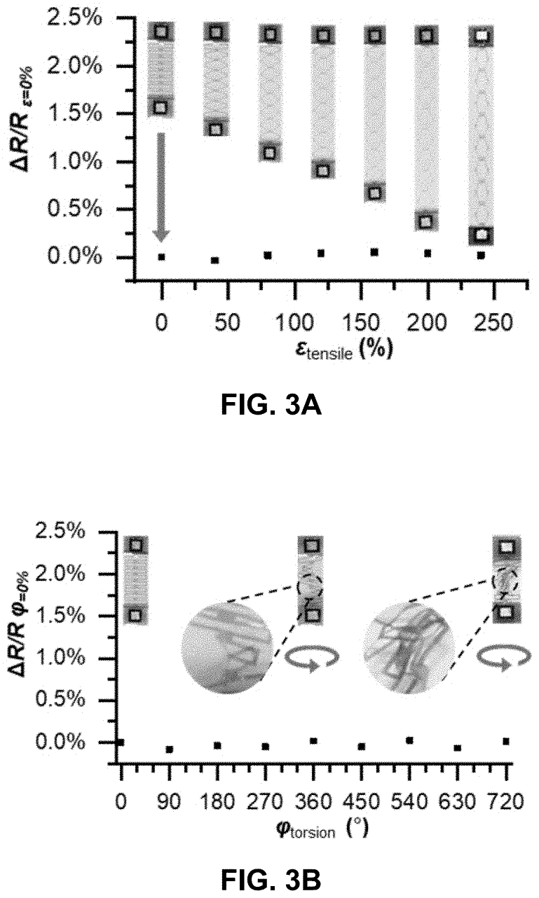

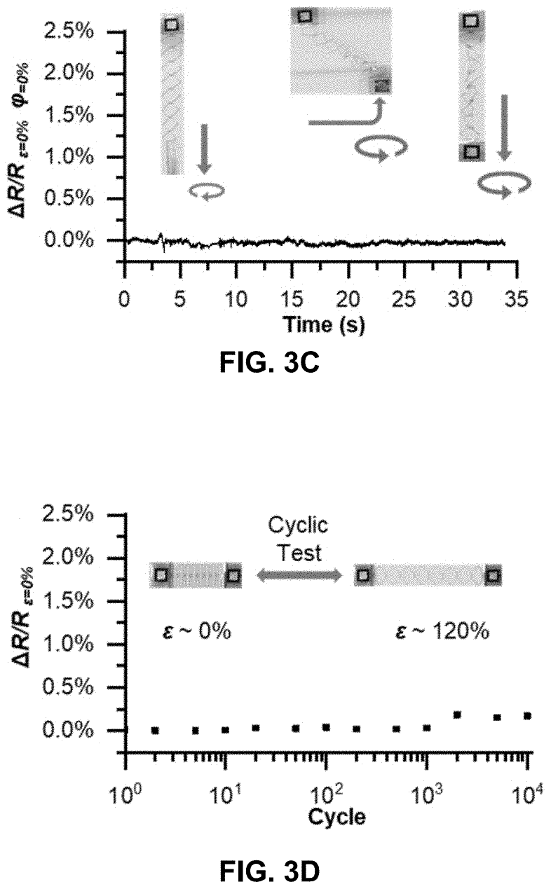

To demonstrate strain-insensitive electrical measurements, we characterized normalized change in resistance (ΔR/R₀) of a kirigami-inspired graphene electrode under varying types of strain states (FIGS. 3A-3D). As the graphene electrode is stretched uniaxially from 0% to 240%, there is negligibly small change (<0.25%) in resistance (FIG. 3A) even when the unit cells are drastically widened. The stable electrical signal is also observed when the graphene electrode is twisted up to two full revolutions or 720° as manifested by the structural distortion in the middle region (FIG. 3B). In addition, we demonstrated time-stable electrical signal preservation under mixed strains states by subjecting the graphene electrode to a combination of uniaxial strain, torsion strain, and/or shear strain, reflecting active working conditions (FIG. 3C). Mechanical robustness throughout recurring deformations is another important design consideration for wearable device. To demonstrate the robustness of our stretchable graphene electrode, we characterized the normalized change in resistance over ten thousand periods of cyclic uniaxial tensile strains, between 0% and 120% (FIG. 3D). Notably, no degradation of the normalized resistance is observed over such large number of stretching/releasing cycles, implying that the graphene kirigami's integrity is preserved during the cyclic motion.

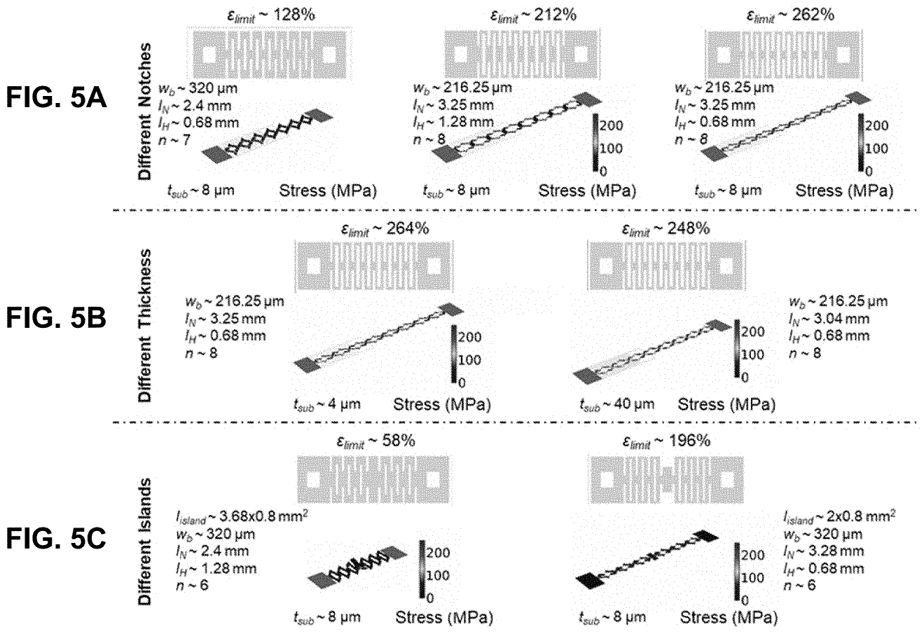

Moreover, FEA can also reveal the distribution of stress in a kirigami structure, thus providing insights to the ability of kirigami to redistribute stress concentrations within the structure. Conveniently by a computational mean, we predicted the uniaxial strain limit of specific kirigami designs by corresponding the ultimate/breaking stress to the stresses at the vicinity of the notches. A multitude of kirigami designs with varying notch length, beam width, hinge length, number of notches and thickness are evaluated for their strain limit and corresponding morphology (FIGS. 4A-4K and 5A-5C). As we evaluated different notch designs (FIGS. 4I-4K and FIG. 5A), we found that notch length, hinge length and beam width played critical roles in determining the stretchability of a specific kirigami design. Increasing notch length or decreasing beam width (and hinge length) lowers the critical force needed to buckle out-of-plane. The out-of-plane deformation redistributes the stress concentrations to the vicinity of patterned notches which affords the kirigami structure to withstand higher overall applied strain (stretchability). On the other hand, we found that thickness of polyimide in the scale of interest (4 μm-40 μm) yielded little variance in effective uniaxial strain limit (FIG. 5B). Essentially, there is a general tradeoff between structure stretchability and mechanical rigidity appreciated for device handling. Our range of evaluated designs implied controllable stretchability enabled by kirigami architecture engineering.

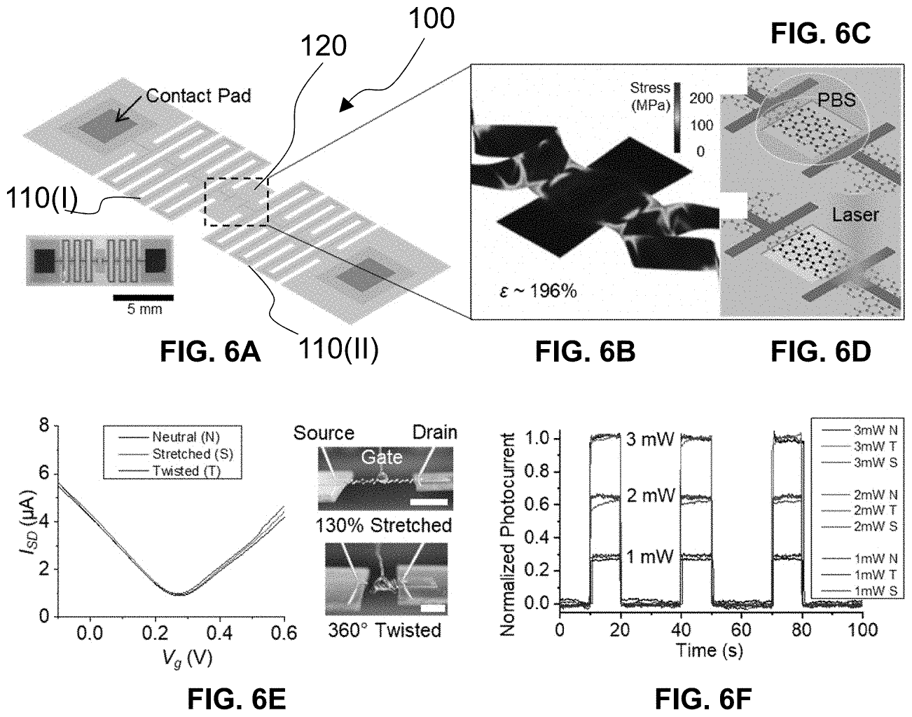

To substantiate the implications for strain-insensitive applications, we investigated solution-gated FET and photodetection enabled by kirigami-inspired architecture (FIGS. 6A-6F). A kirigami design with island-bridge motif or island-bridge geometry is chosen for the dual function device platform (FIG. 6A). Solution-gated FET plays a crucial role in chemical and biological sensing applications for enabling electrical signal transduction and amplification. The working principal of our solution-gated FET is based on applying gate potential via the semi-stable electric double layer (EDL) on the surface of graphene channel, which results in the modulation of graphene conductance. For a gate sweep between −0.2V to 0.6V using Ag/AgCl reference electrode, we observed am bipolar field-effect gating (FIG. 6E), with p- and n-type normalized transconductance, g_{mN} of −1.13 and 0.90 mS/V, respectively, comparable to reported device performance of flat graphene on flexible polymeric substrate.^{[42]} Notably, we demonstrated strain-insensitive transfer curves (FIG. 6E) across all three different structural configurations: neutral, 130% uniaxial strain, and 360° torsional strain enabled by kirigami architecture. The demonstration of kirigami graphene FET has the potential to be extended to health monitoring applications. In addition, the same device platform and structural configurations are also extended to photodetection (FIG. 6D) under green laser illumination. Photodetection is an integral part of noninvasive heart rate monitoring or photoplethsmography (PPG) by monitoring light absorption caused by variations in blood volume passing through arteries^{[43]}. We demonstrated strain-insensitive photodetection by measuring photocurrent generation with three varying laser powers (1-3 mW) under different structural configurations (FIG. 6F). For each laser power, we observed dynamic photoresponse of time-varying photocurrent with the laser turned on (˜10 s) and off (˜20 s) for all structural configurations (neutral, N; stretched, S; and twisted, T). The measured photocurrents are normalized to the photocurrent measured at 3 mW laser power. Our strain-insensitive normalized photocurrent successfully demonstrated that our kirigami-inspired structure with island-bridge motif or island-bridge geometry provided a stable photodetection under distorted configurations (FIG. 6F). Our kirigami-inspired solution-gated FET and photodetection further implied the potential multifunctional wearables complemented by surface conformity and general breathability.

The combination of ultra-thin form factor, conformity on skin, and breathable notches, as disclosed herein, demonstrates the applicability of the kirigami-inspired architecture, as disclosed herein in embodiments, for atomically-thin materials in a broader set of wearable technology, including strain-insensitive sensors.

The following references are incorporated herein by reference, to the extent not inconsistent herewith: Blees, M. K. et al. Graphene kirigami. Nature (2015). doi:10.1038/nature14588; and Shyu, T. C. et al. A kirigami approach to engineering elasticity in nanocomposites through patterned defects. Nat. Mater. (2015). doi:10.1038/nmat4327

### Example 2: Kirigami-Inspired Strain-Insensitive Sensors Based on Atomically-Thin Materials

This Example describes kirigami-inspired architectures of graphene for strain-insensitive, surface-conformal stretchable multifunctional electrodes and sensors. The kirigami-inspired graphene electrode exhibits strain-insensitive electrical properties up to, for example, 240% applied tensile strain and mixed strain states, including a combination of stretching, twisting, and/or shearing. Moreover, a multitude of kirigami designs of graphene are explored computationally to predict deformation morphologies under different strain conditions and to achieve controllable stretchability. Notably, strain-insensitive graphene field-effect transistor and photodetection under 130% stretching and 360° torsion are achieved by strategically redistributing stress concentrations away from the active sensing elements via strain-responsive out-of-plane buckling at the vicinity of the kirigami notches. The combination of ultra-thin form factor, conformity on skin, and breathable notches suggests the applicability of kirigami-inspired platform based on atomically-thin materials in a broader set of wearable technology.

Strain-insensitive, surface-conformal, and breathable graphene-based stretchable electrodes and multifunctional devices are developed by adopting kirigami-inspired architectures. The fabricated devices demonstrate preservation of electrical signal up to 240% applied tensile strain and mixed strain states, including a combination of stretching, twisting, and/or shearing. Finally, strain-insensitive solution-gated field effect transistor and photodetection are shown by redistributing stress concentrations away from the active sensing elements via strain-responsive out-of-plane buckling.

### Introduction

Recent progress in the fabrication of flexible electronics has enabled various nanomaterials-based flexible devices to be conformal to the skin or even implanted into the human body for continuous monitoring and treatment purposes.[1-8] From the perspective of material development, atomically-thin materials offer tunable properties with enhanced performance over their bulk counterparts.[9,10] Graphene, an atomically-thin layer of hexagonally bonded carbon atoms, has been widely developed for use in next generation flexible optoelectronic, electromechanical, and bioelectronics applications owing to its outstanding electrical, mechanical and optical properties.[11-14] However, the implementation of graphene into a broader set of flexible/stretchable applications has been hindered by its tendency to fail or deviate electrically at small strain.[15] Ultimately, the covalently bonded graphene carbon networks do not provide sufficient energy dissipation mechanisms under mechanical loading.[15] Specifically, the conductance of chemical vapor deposition (CVD) grown graphene transferred onto an elastomeric substrate is preserved and reversible only up to ˜6.5% tensile strain.[16] In contrast, the minimally demanded strain tolerance for wearable health-monitoring devices is ˜55% based on basic human motions.[17]

Retention of device functionalities under high mechanical strain is desirable for applications which are subjected to active strain environments.[18] Previous studies have utilized either integrated nanomaterials in stretchable polymers,[17,19,20] pre-strained flexible elastomeric substrates,[11,12,21,22] or multi-layered nanomaterials[15,23] to impart mechanical flexibility or stretchability into otherwise low strain limit nanomaterials. However, the resulting variance of electrical signal due to intrinsic piezoresistivity or premature failure modes can lead to unwanted strain dependency for intended applications. While exceptional bendability can be achieved by adopting an ultrathin form factor or placing the active sensing element in the neutral plane, the sensor may still fail prematurely under tension.[9]

In order to retain functional electrical properties of a device as desired, there is a great need to decouple desired measurement signals from mechanical stretchability induced electrical signal changes. Kirigami, an art of paper cutting, in general has been well established as a template to create materials with reconfigurable morphological responses. In fact, mechanically driven form of three-dimensional (3D) mesostructures by kirigami micro/nanomembranes have demonstrated topographical complexity that significantly exceeds those possible with other schemes.[24,25] Following that, numerous kirigami-inspired applications have been reported such as multidirectional photodetection/imaging systems,[26] tunable optical windows,[24,27] sun-tracking solar cells,[28] stretchable bioprobes,[29] smart adhesion,[30] and motion detection.[31] As kirigami features generate geometric deformations that dominate the inherent material elasticity, properties and structures of kirigami are controlled by pattern and orientation of these cuts.[18,32-37]

In this paper, we report strain-insensitive, surface conformal graphene-based stretchable electrodes and multifunctional devices by adopting kirigami-inspired architectures (FIGS. 1A-1F). While liquid-suspended graphene kirigami has been demonstrated,[38] we seek to overcome its limitation to aqueous environments and realize strain-insensitive sensing under mixed strain states. We exploit the ability of kirigami-inspired perforations or notches to tune the stiffness of our devices in order to improve conformity and breathability onto human skin. Furthermore, we carry out systematic investigations of multitude graphene kirigami design to demonstrate controllable stretchability and preserved electrical signals up to 240% uniaxial strain and other mixed strain states. Moreover, the simulated deformability of kirigami unit cells under strain is found to correspond well with experimental observations, thereby promoting the applicability of computational driven design optimization. Finally, we achieve strain-insensitive solution-gated graphene field-effect transistor (FET) and photodetection under high tensile and torsional strain states by strategically redistributing stress concentrations away from the active sensing elements via kirigami notches and an island-bridge motif or island-bridge geometry. Kirigami (e.g., kirigami notches, kirigami bridges, etc.) is an exemplary characterization of exemplary perforation designs, useful in embodiments herein. An island-bridge motif or island-bridge geometry, as described herein, corresponds to a sensor device, or sheet thereof, having at least one island and at least one bridge, wherein the at least one island is physically connected to at least one bridge. A bridge is an exemplary perforated region, according to embodiments herein. An island is an exemplary active-sensing region, according to embodiments herein.

### Results and Discussions

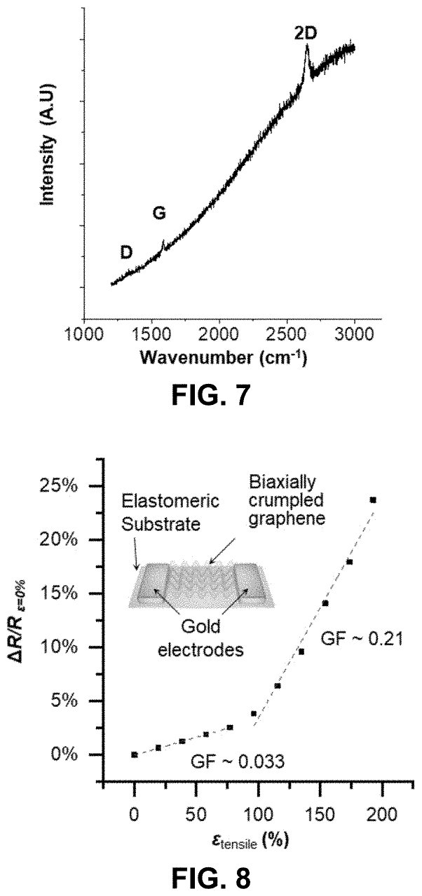

The architecture of our kirigami-inspired devices is illustrated in FIG. 1A. The monolayer graphene (FIG. 7) is sandwiched in between two ultrathin polyimide layers (˜2-4 μm) and the assembly is patterned into a kirigami shape (FIG. 2). We intended the active sensing element to be in the neutral plane to further minimize the stress subjected to it during deformation. The principle of kirigami is based on patterning the two-dimensional (2D) precursor surface with cuts or notches, where subsequent strain will transform it into a reconfigurable 3D architecture owing to mechanical bistability at the vicinity of those patterns. As the kirigami-inspired graphene electrode is stretched uniaxially, the unit cell is subjected to out-of-plane buckling with gradual tilting towards the vertical direction through both bending and twisting accompanied by the widening of unit cell. Depending on the loading direction, the unit cells will tilt either clockwise or counterclockwise when the kirigami structure is stretched from one end with the other end fixed.[34] The kirigami designs would deform initially in-plane via cut/notch widening, followed by rotation of kirigami beams via hinges.[18,32-34] Further extension causes the in-plane beam bending to become more energetically expensive than out-of-plane beam bending.[32,33] Continued stretching loads the structure until full extension, resulting in strain hardening and ultimately failure.[32] We have also noticed that the strain rate affects the general uniformity and sequence of unit cell widening under mechanical loading. Moreover, the topographical deformation of a kirigami structure is shown to be highly dependent on the applied strain states (FIGS. 1B-1D), such as mixed tensile and torsional strain (FIG. 1C) or only torsional strain (FIG. 1D). As a preliminary test for structural conformity, we mounted the kirigami architecture on the surface of a human wrist and strained under different wrist articulations, including flexion and extension (FIGS. 1E-1F). Notably, the perforated/notch kirigami designs further reduced the effective stiffness of the ultrathin form factor structure,[32] therefore improving the conformity and breathability of the device, which is conducive to long-term wearable applications.[39]

To demonstrate strain-insensitive electrical measurements, we characterized the normalized change in resistance (ΔR/R₀) of a kirigami-inspired graphene electrode under varying types of strain states (FIG. 2). As the graphene electrode is stretched uniaxially from 0% to 240%, there is a negligibly small change (<0.25%) in resistance (FIG. 3A) even when the unit cells are drastically widened. The stable electrical signal is also observed when the graphene electrode is twisted up to two full revolutions or 720° as manifested by the structural distortion in the middle region (FIG. 3B). In addition, we demonstrated time-stable electrical signal preservation under mixed strains states by subjecting the graphene electrode to a combination of uniaxial strain, torsion strain, and/or shear strain, reflecting active working conditions (FIG. 3C).

Mechanical robustness throughout recurring deformations is another important design consideration for wearable devices. To demonstrate the robustness of our stretchable graphene electrode, we characterized the normalized change in resistance over ten thousand periods of cyclic uniaxial tensile strains, between 0% and 120% (FIG. 3D). Notably, no degradation of the normalized resistance was observed over such a large number of stretching/releasing cycles, implying that the graphene kirigami's integrity is preserved during the cyclic motion.

In contrast to kirigami-inspired architecture, the crumpling of atomically thin materials has similarly been reported to enhance device stretchability.[12,22,40] Given the shared attributes of topography engineering, we characterized the normalized change of resistance as a function of strain for a crumpled graphene electrode. As the buckle-delaminated graphene electrode on elastomeric substrate is stretched up to ˜200% uniaxially, we measured a ˜25% change in normalized resistance (FIG. 8), which is >100 times larger than the recorded resistance change by kirigami-inspired graphene electrode (FIG. 3A). Even though the pre-strained value (350%) of the elastomeric substrate is much larger than the applied strain, the variance in resistance under mechanical loading suggests its susceptibility to strain effects.

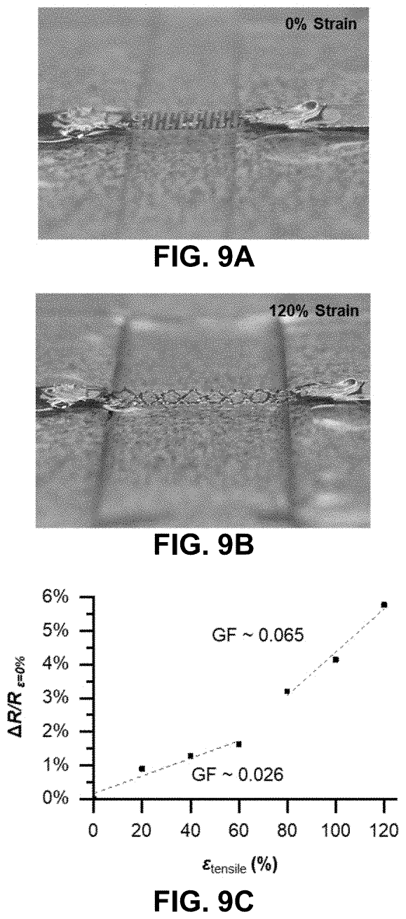

To evaluate the case in which out-of-plane deformation is limited, we adhered the kirigami-inspired graphene electrode onto an elastomeric very high bond (VHB) substrate (FIGS. 9A-9C). The setup effectively constrained the out-of-plane deformation of the kirigami electrode under any mechanical loading, thereby diminishing the stress alleviation thereof. As the restricted kirigami electrode was uniaxially stretched, the normalized resistance changed monotonically when compared to the strain-insensitive unconstrained setup (FIGS. 3A-3D and FIGS. 9A-9C).

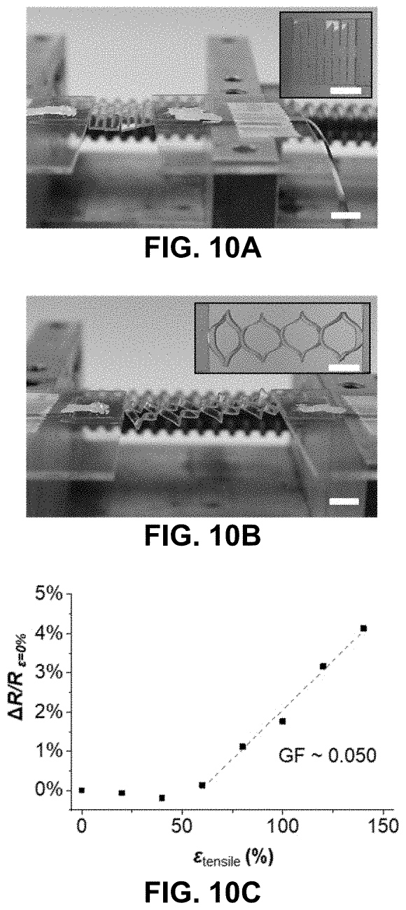

To extend the strain-insensitivity scheme to another compliant substrate material, we utilized polydimethylsiloxane (PDMS). Given the incompatibility of PDMS with the proposed microfabrication procedures (e.g., swelling by organic solvent), we used a laser cutter to pattern the kirigami design of the sandwiched architecture and to highlight the versatility of a new kirigami patterning scheme (FIGS. 10A-10C). As the kirigami electrode was uniaxially stretched under smaller strains (below 50%), the normalized resistance remained unchanged. The level of strain insensitivity exhibited by kirigami-inspired PDMS structures was better than that of crumpled graphene structures (gauge factor ˜0.033 between 0-80%) (FIG. 8) and restricted kirigami-inspired polyimide structures (gauge factor ˜0.026 between 0-60%) (FIGS. 9A-9C). Further extension of the kirigami-inspired PDMS structure indicated monotonic increment in normalized resistance (e.g., gauge factor ˜0.050 above 50%).

To predict the morphology of a kirigami-inspired structure under strain, we used finite element analysis (FEA) to simulate the polyimide strain-responsive architecture without accounting for graphene given the significant thickness difference (FIGS. 4A-4K). Side view photographs of graphene kirigami electrode are investigated to study the evolution of morphology under increasing uniaxial strain (FIGS. 4A-4C). The general correspondence between experimental observations (FIGS. 4A-4C) and simulated results (FIGS. 4D-4F) with respect to the deformity of kirigami unit cells established simulation as a means for computationally driven design optimization, as suggested subsequently in the engineering of multifunctional kirigami devices. Quantitative agreement of the experimental configuration states of 8 kirigami edges (or 4 kirigami unit cell) with FEA predictions of z-displacements under increasing tensile strain (0% to 120%) is presented in FIG. 4G and FIGS. 11A-11C.

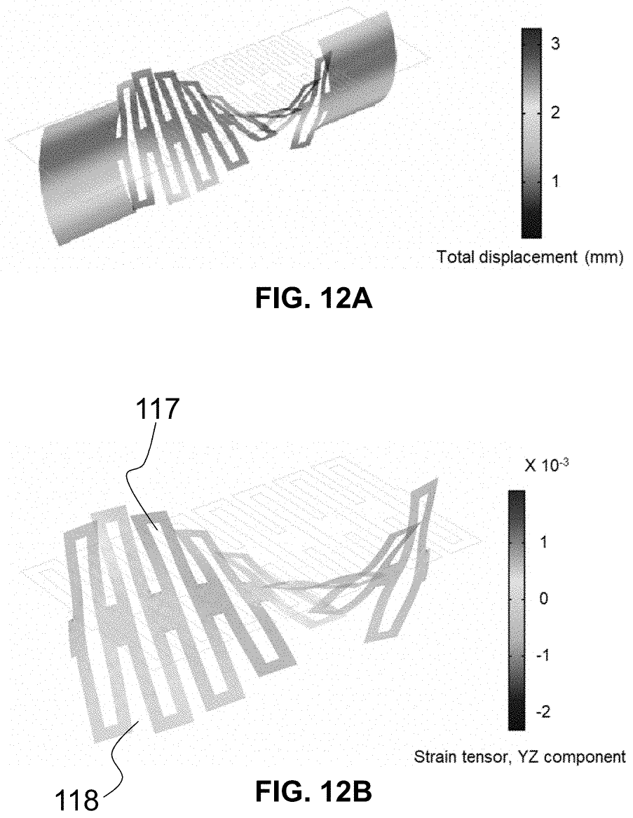

Moreover, FEA can also reveal the distribution of stress in a kirigami structure, thus providing insights into the ability of kirigami to redistribute stress concentrations within a structure (FIGS. 11D-11E). Conveniently by a computational mean, we predicted the uniaxial strain limit of specific kirigami designs by corresponding the ultimate/breaking stress to the stresses at the vicinity of the notches (FIG. 4H and FIGS. 11D-11E). We captured the strain-responsive complex out-of-plane bending and twisting by studying the evolution of unit cell morphology under linear stretching motions (FIGS. 11F-11H). The kirigami architecture becomes reconfigured under strain, with maximum stresses occurring at the regions with the highest change in curvature, and these regions remained constant throughout the buckling process (FIGS. 11F-11H). Following that, the surface strain distribution of a twisted kirigami indicated both tension and compression at localized regions (FIGS. 12A-12B). The deterministic stress distributions validated our approach to mitigate stresses away from active sensing element and towards the vicinity of patterned notches. However, interfacial stress transfer may lead to shear sliding under tension and buckling under compression above the corresponding critical strains in the graphene kirigami at large deformations.[41]

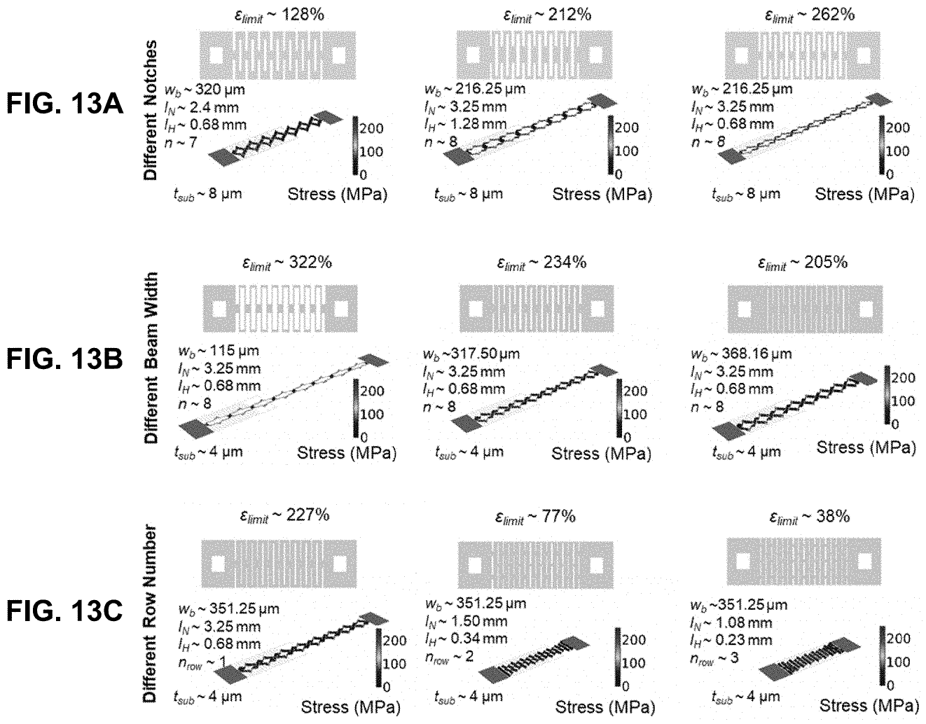

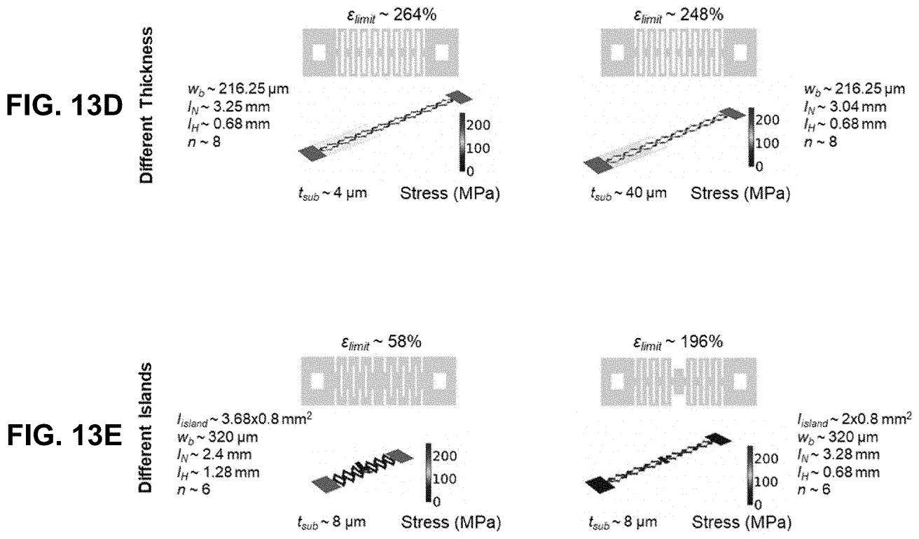

A multitude of kirigami designs with varying notch length, beam width, hinge length, number of notches, number of rows, and thickness were evaluated for their strain limit and corresponding morphology (FIGS. 13A-13E). As we evaluated different notch designs (FIGS. 4I-4K and FIGS. 13A-13A), we found that notch length, hinge length and beam width play critical roles in determining the stretchability of a specific kirigami design. The control of beam width, reflected by the change of notch width, represents an effective approach to tune the directional stretchability of explored kirigami designs (FIGS. 13A-13B). Increasing notch length or decreasing beam width (and hinge length) lowers the critical force needed to buckle out-of-plane. The out-of-plane deformation redistributes the stress concentrations to the vicinity of patterned notches (FIG. 11E and FIGS. 13A-13E) which affords the kirigami structure to withstand higher overall applied strain (stretchability). On the other hand, we found that thickness of polyimide in the scale of interest (4 μm-40 μm) yielded little variance in effective uniaxial strain limit (FIG. 13B). Essentially, there is a general tradeoff between structure stretchability and mechanical rigidity appreciated for device handling. Our range of evaluated designs implied controllable stretchability enabled by kirigami architecture engineering.

Impermeable ultrathin films or rubber sheets, as demonstrated by previous studies, may disturb sweat secretion and block airflow around the skin, causing irritation and inflammation, which may ultimately lead to lasting physiological and psychological effects.[39] In contrast, kirigami-inspired architectures can improve the breathability of skin electronic devices by reducing the relative area coverage and through out-of-plane deformation (FIG. 14 and FIGS. 1E-1F). However, the relationship between surface area and uniaxial stretchability is found to be neither linear nor monotonic, but instead, more design dependent. In the case of preserved overall dimensions (e.g., length, width, and thickness), directional mechanical stiffness can be tuned by modulating the number of kirigami rows without compromising breathability (FIG. 14). Our skin mounting demonstrations showed the application in skin wear electronics, where conformity and breathability are appreciated.

To substantiate the implications for strain-insensitive applications, we investigated solution-gated FET and photodetection enabled by kirigami-inspired architecture (FIGS. 6A-6F). A kirigami design with an island-bridge motif or island-bridge geometry is chosen for the dual function device platform (FIG. 6A). As we explored different island designs, we found that drastic improvement in stretchability was found by reducing island width and hinge length (FIG. 13C). By introducing strategic notches, kirigami now provides a distinct route to locally relieve stresses through these geometric features (FIG. 6B). Suppression of strain profile around the active sensing region is critical to strain-insensitive performance of flexible/stretchable devices.

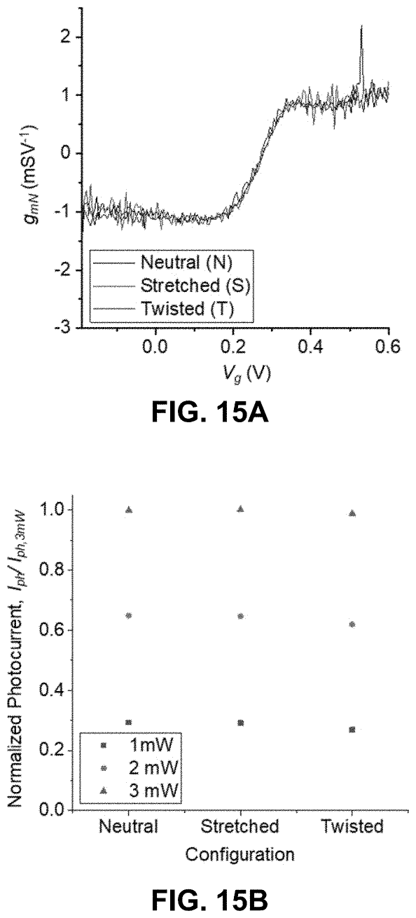

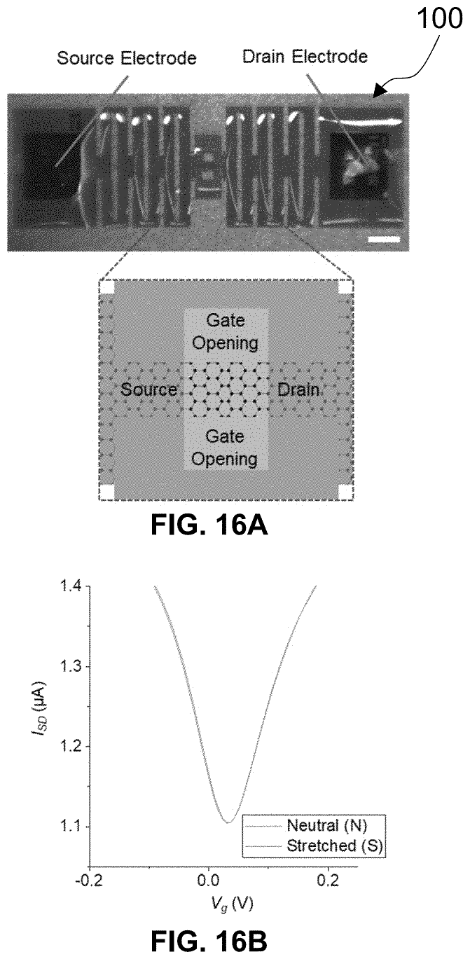

Solution-gated FET plays a crucial role in chemical and biological sensing applications for enabling electrical signal transduction and amplification. Correspondingly, there is a growing interest into in-situ perspiration analysis among skin electronic devices, namely sweat metabolites such as glucose and lactate, as well as electrolytes such as sodium and potassium ions.[5] The working principal of our solution-gated FET is based on applying gate potential via the electric double layer (EDL) on the surface of graphene channel, which results in the modulation of graphene conductance. The stretchable solution-gated graphene kirigami FET device consisted of gold electrodes as the source and drain contacts and an exposed graphene channel in phosphate-buffered saline (PBS) solution (FIG. 6C). For a gate sweep between −0.2V to 0.6V using Ag/AgCl reference electrode, we observed ambipolar field-effect gating (FIG. 6E), with p- and n-type normalized transconductance, g_{mN} of −1.13 and 0.90 mS/V (FIG. 15A), respectively, comparable to reported device performance of flat graphene on flexible polymeric substrate.[42] Notably, we demonstrated strain-insensitive transfer curves (FIG. 6E) and transconductance characteristics (FIG. 15A) across all three different structural configurations: neutral, 130% uniaxial strain, and 360° torsional strain enabled by kirigami architecture. Similar levels of strain insensitivity were observed for all-graphene FETs (i.e., extended Au source and drain electrodes are removed) between their neutral state and 150% uniaxial strain (FIGS. 16A-16B).

Moreover, we have explored an integrated planar gate electrode design to further close the practicality gap of solution-gated FET sensing (FIGS. 17A-17B). While there are small discrepancies in the transfer curve characteristics between the Ag/AgCl reference gate electrode and the planar Au gate electrode, strain-insensitivity was demonstrated between 0% and 150% uniaxial strain. The demonstration of kirigami graphene FET can be extended to health monitoring applications.

In addition, the same device platform and structural configurations are also extended to photodetection (FIG. 6D) under green laser illumination. Photodetection is an integral part of noninvasive heart rate monitoring or photoplethsmography (PPG) by monitoring light absorption caused by variations in blood volume passing through arteries.[43] Our photodetector is based on the separation of photogenerated electron-hole pairs under an electric field sustained by applied bias voltage.[44] The green laser is illuminated at the junction of graphene channel and gold electrode to maximize photocurrent generation.[45] We demonstrated strain-insensitive photodetection by measuring photocurrent generation with three varying laser powers (1-3 mW) under different structural configurations (FIG. 6F and FIG. 15B). For each laser power, we observed dynamic photoresponse of time-varying photocurrent with the laser turned on (˜10 s) and off (˜20 s) for all structural configurations (neutral, N; stretched, S; and twisted, T). The measured photocurrents are normalized to the photocurrent measured at 3 mW laser power. Our strain-insensitive normalized photocurrent successfully demonstrated that our kirigami-inspired structure with an island-bridge motif or island-bridge geometry provided stable photodetection under distorted configurations (FIG. 6F). Our kirigami-inspired solution-gated FET and photodetection further can be used for multifunctional wearables complemented by surface conformity and general breathability.

### Conclusion

We have demonstrated that engineering of graphene device deformability via kirigami architecture has the potential to achieve strain-insensitive electrical sensing. The kirigami-inspired graphene architectures exhibited controllable stretchability and preserved electrical signals up to 240% uniaxial stretching and other strain states. In addition, the kirigami-inspired perforations and notches improved conformity and breathability by tuning the stiffness of the system. In addition, FEA simulation of kirigami architecture suggested the applicability of computationally driven design optimization to strain-responsive structural reconfiguration. More notably, we achieved strain-insensitive solution-gated graphene FET and photodetection under stretching and torsion by strategically redistributing stress concentrations away from the active sensing elements via kirigami notches and an island-bridge motif or island-bridge geometry. We believe that the kirigami-inspired strain-insensitive design template presented a simple and robust platform which is applicable to a wide range of other atomically thin materials of recent interest (e.g., hBN, MoS₂, and other transition metal dichalcogenides). This disclosure allows for the realization of enhanced stretchability, strain-insensitive, surface-conformal and breathable skin electronics. The kirigami-inspired highly stretchable architecture can be used for multifunctional sensor integrations demanded in wearable health monitoring applications.

Materials and Methods

Kirigami Device Fabrication

Graphene is synthesized on copper foil by low-pressure CVD using a mixture of methane (CH₄), hydrogen (H₂), and argon (Ar). The first or bottom polyimide layer is spincoated and cured on a sacrificial metal layer. The graphene is subsequently transferred on top of the assembly and annealed to enhance the adhesion. Metal electrodes are deposited before the graphene is patterned by photolithography and oxygen (O₂) plasma. Following that, the second or top polyimide layer is then spincoated and cured. The assembly is then patterned into a kirigami shape by reactive ion etching (RIE) after etch mask deposition. Finally, the device is released by etching the sacrificial layer chemically. The detailed procedures and conditions during sample preparation, e.g., graphene synthesis, sample preparation for buckle-delaminated crumpled graphene, etc., are provided in supplementary material.

Electrical Characterizations

Two terminal resistance measurements are performed with a probe station (PM8, SUSS Micro Tec, Germany) and a sourcemeter (2614B, Keithley Instruments, OH). The current-voltage curve of the kirigami-inspired graphene devices are characterized at varying strain states.

Cyclic Uniaxial Tensile Test

The kirigami-inspired graphene electrode is mounted on top of an automatic translational stage (MTS50-Z8, Thorlabs, NJ) interfaced with a brushed motor controller. The cyclic uniaxial tensile test is run at a maximum velocity of 1.5 mm/s with an acceleration of 1.5 mm/s².

Finite Element Modeling

Non-linear finite element (FE) analysis is carried out to predict the mechanical response of various kirigami designs using the Structural Mechanics Module in COMSOL Multiphysics® software. The non-linear treatment is essential due to large displacements and rotations involved with the kirigami deformation. A 3D solid element is employed to model the kirigami structures. A triangular prism non-uniform meshing is used with maximum and minimum mesh size of ˜1.3 mm and ˜0.096 mm, respectively. The discretization is verified by checking simulation results with smaller mesh sizes. For the polyimide material of the kirigami, an elasto-plastic constitutive model is adopted.[46] The FE simulation involved two steps. First, very small perturbative forces are applied in the out-of-plane direction along the top edges of the cuts while keeping the ends of the kirigami fixed to prevent bifurcation during buckling transition.[24] Next, the axial loading is imposed by moving one end along the plane in steps, and the increments are kept small enough to ensure the convergence of the non-linear problem.

We have also developed a supplementary open source web-based kirigami simulation design and mechanical assist tool to assist computationally-driven morphology prediction of kirigami structure under strain, GAM IAN (website: https://nanohub.org/tools/gamian). The details are provided in the supplementary information.

FET Sensor Measurements

Solution-gated FET transfer curves are measured with a digital sourcemeter (2614B, Keithley Instruments, OH) with an Ag/AgCl reference electrode (Harvard Instruments, MA) to gate the device through 1×PBS solution (Corning Cellgro, VA). The gate voltage is swept from −0.2V to 0.6V, while the bias voltage is kept at 30 mV.

Photocurrent Measurements

The photocurrent of the device generated by the incident beam from a diode laser of 515 nm wavelength (power ˜1-3 mW through a 5× objective lens) (CPS532, Thorlabs, NJ) is measured using a sourcemeter (Keithley 2614B, OR) and a microprobe station. To maintain a consistent power and illumination position, the laser power and beam focus/alignment is calibrated through a 5× objective lens with a photodiode power sensor (S120C and PM100USB, Thorlabs, NJ). The bias voltage of 15 pV is applied for the electrical potential.

Performed demonstrations include showing a kirigami-inspired graphene electrode under uniaxial strain up to ˜240%. The kirigami-inspired graphene electrode is mounted on top of a translational stage interfaced with a brushed motor controller. The cyclic uniaxial tensile test is ran at maximum velocity of 1.5 mm/s and acceleration of 1.5 mm/s². As the kirigami-inspired graphene electrode is stretched uniaxially, the unit cell is subjected to out-of-plane buckling with gradual tilting towards the vertical direction through both bending and twisting accompanied by the widening of unit cell.

Supplementary Information:

Fabrication of Kirigami-Inspired Strain-Insensitive Graphene Devices

Graphene is synthesized on a 25 μm-thick copper (Cu) foil (MTI, CA) via chemical vapor deposition (CVD) (Rocky Mountain Vacuum Tech Inc., CO). The CVD furnace is heated to 1050° C. under H₂ gas (50 sccm) at 150 mTorr. The Cu foil substrate is moved to the center of the furnace chamber using a load-lock system for the annealing process (60 minutes). After the annealing step, CVD growth of graphene is carried out under CH₄ and H₂ gases (CH₄: 100 sccm and H₂: 50 sccm) for 2 minutes at 520 mTorr. Then, the chamber is slowly cooled down to room temperature under Ar gas (500 sccm) at 330 mTorr. After the synthesis, undesired graphene on the backside of the Cu foil is removed by oxygen plasma etching (Diener GmbH, Germany) with a polymethyl methacrylate (PMMA) coating to passivate the top side. Graphene is used to develop the stretchable kirigami-inspired strain-insensitive graphene electrode and devices.

Cu film (200 nm) is deposited by a thermal evaporator (Nano 36, Kurt J. Lesker, Pa.) on Si wafer to create a sacrificial layer. The first or bottom polyimide layer (Sigma Aldrich, MO) is spincoated (˜2-4 μm). The polyimide layer is first soft baked on a hot plate at 150° C. for 5 minutes and final curing is done at 350° C. for 1.5 hours under N₂ flow. The PMMA-coated graphene is transferred onto the first polyimide layer. The PMMA scaffold layer is subsequently dissolved in acetone for ˜5 minutes. The assembly is then annealed in low pressure (150 mTorr) at 350° C. under Ar flow. Following that, Cr/Au metal electrodes (7 nm/70 nm) is thermally deposited, before patterning the graphene via photolithography and O₂ plasma reactive ion etching (RIE). Subsequently, the second or top polyimide layer is spincoated and cured. A 40 μm Cu etch mask is patterned on the top polyimide layer. Then, the assembly as a whole is patterned into a kirigami shape by O₂ plasma etching. Finally, the device is released by etching the sacrificial layer by sodium persulfate solution.

Fabrication of Buckle-Delaminated Crumpled Graphene

A VHB film (3M, MN), a highly stretchable acrylic film, is biaxially pre-strained by ε_{pre,x}˜350% and ε_{pre,y}˜200%. CVD grown graphene on a Cu foil is then transferred onto a pre-strained VHB film. The Cu foil is then chemically etched with sodium persulfate aqueous solution. The crumpling of graphene structure is accomplished by subsequent releasing of the elastomeric substrate. Thin gold film (40 nm) is deposited by thermal evaporator (Nano 36, Kurt J. Lesker, PA) with a shadow mask to create contact pads. The device is biaxially re-stretched during the thermal deposition to create corrugated gold contact electrodes enabling the device stretchability.

Fabrication of Kirigami Inspired Graphene Electrode with PDMS Encapsulation

The contact window of top layer PDMS (Gel-Pak, CA) was first patterned via laser cutting (Potomac, MD). The CVD graphene was transferred onto the bottom PDMS via stamping. The Cu catalyst was removed by wet etchant. The transfer was completed by rinsing the sample in multiple water baths. Before bonding the top and bottom PDMS, the top PDMS was surface activated by oxygen plasma reactive-ion etching (March Jupiter III, CA) for 30 seconds (75 W). To improve the adhesion between the PDMS layers, the assembly was heat treated at 65° C. inside an oven.

Calculation of Normalized Transconductance of a Solution-Gated Field-Effect Transistor

The transconductance, gₘ is obtained by taking the linear slope (I_{DS}/V_{g}) of the transfer curve (FIG. 6E), while the normalized transconductance, g_{mN} is calculated as follows:

$${g}_{mN} = {g}_{m} \frac{L}{{WV}_{DS}} = \frac{{dI}_{DS}}{{dV}_{g}} \frac{L}{{WV}_{DS}} \qquad ( 1 )$$

where L and W are, respectively, the length (350 μm) and width (150 μm) of the FET channel, V_{DS} is the drain-source bias (30 mV), I_{DS} is the drain-source current, and V_{g} is the gate potential.

Open source web-based kirigami simulation tool—GAMIAN. A supplementary open source web-based kirigami simulation design and mechanical assist tool, GAM IAN, is developed to assist computationally-driven morphology prediction of kirigami structure under strain. Starting from designing cuts or incisions on any thin-film structure to solving for its final deformed configuration under planar loading, all the steps can be carried out using GAMIAN. GAMIAN provides functionalities to select material, define the kirigami geometry, perform meshing, and numerically solve for the deformation response using the nonlinear finite-element method. Using these capabilities, a user can iterate over the choice of materials and geometric dimensions and cut-patterns and achieve the desired deformation pattern of a kirigami structure. Website: https://nanohub.org/tools/gamian

### REFERENCES CORRESPONDING TO EXAMPLE 2

[1] W. A. D. M. Jayathilaka, K. Qi, Y. Qin, A. Chinnappan, W. Serrano-Garcia, C. Baskar, H. Wang, J. He, S. Cui, S. W. Thomas, S. Ramakrishna, Adv. Mater. 31 (2019) 1805921.
[2] K. Kang, Y. Cho, K. J. Yu, Micromachines 9 (2018) 263.
[3] Y. J. Hong, H. Jeong, K. W. Cho, N. Lu, D. H. Kim, Adv. Funct. Mater. 29 (2019) 1808247.
[4] Y. J. Park, B. K. Sharma, S. M. Shinde, M. S. Kim, B. Jang, J. H. Kim, J. H. Ahn, ACS Nano 13 (2019) 3023-3030.
[5] W. Gao, S. Emaminejad, H. Y. Y. Nyein, S. Challa, K. Chen, A. Peck, H. M. Fahad, H. Ota, H. Shiraki, D. Kiriya, D. H. Lien, G. A. Brooks, R. W. Davis, A. Javey, Nature 529 (2016) 509-514.
[6] S. Kabiri Ameri, R. Ho, H. Jang, L. Tao, Y. Wang, L. Wang, D. M. Schnyer, D. Akinwande, N. Lu, ACS Nano 11 (2017) 7634-7641.
[7] S. Xu, Y. Zhang, L. Jia, K. E. Mathewson, K. I. Jang, J. Kim, H. Fu, X. Huang, P. Chava, R. Wang, S. Bhole, L. Wang, Y. J. Na, Y. Guan, M. Flavin, Z. Han, Y. Huang, J. A. Rogers, Science 344 (2014) 70-74.
[8] S. K. Kang, R. K. J. Murphy, S. W. Hwang, S. M. Lee, D. V. Harburg, N. A. Krueger, J. Shin, P. Gamble, H. Cheng, S. Yu, Z. Liu, J. G. McCall, M. Stephen, H. Ying, J. Kim, G. Park, R. C. Webb, C. H. Lee, S. Chung, D. S. Wie, A. D. Gujar, B. Vemulapalli, A. H. Kim, K. M. Lee, J. Cheng, Y. Huang, S. H. Lee, P. V. Braun, W. Z. Ray, J. A. Rogers, Nature 530 (2016) 71-76.
[9] D. Akinwande, N. Petrone, J. Hone, Nat. Commun. 5 (2014) 5678.
[10] K. S. Novoselov, V. I. Fal'ko, L. Colombo, P. R. Gellert, M. G. Schwab, K. Kim, Nature 490 (2012) 192-200.
[11] K. Yong, A. Ashraf, P. Kang, S. Nam, Sci. Rep. 6 (2016) 24890.
[12] P. Kang, M. C. Wang, P. M. Knapp, S. Nam, Adv. Mater. 28 (2016) 4565-4565.
[13] M. C. Wang, J. Leem, P. Kang, J. Choi, P. Knapp, K. Yong, S. W. Nam, 2D Mater. 4 (2017) 022002.
[14] P. Kang, M. C. Wang, S. Nam, Microelectron. Eng. 161 (2016) 18-35.
[15] N. Liu, A. Chortos, T. Lei, L. Jin, T. R. Kim, W. G. Bae, C. Zhu, S. Wang, R. Pfattner, X. Chen, R. Sinclair, Z. Bao, Sci. Adv. 3 (2017) e1700159.
[16] K. S. Kim, Y. Zhao, H. Jang, S. Y. Lee, J. M. Kim, K. S. Kim, J.-H. Ahn, P. Kim, J.-Y. Choi, B. H. Hong, Nature 457 (2009) 706-10.
[17] T. Yamada, Y. Hayamizu, Y. Yamamoto, Y. Yomogida, A. Izadi-Najafabadi, D. N. Futaba, K. Hata, Nat. Nanotechnol. 6 (2011) 296-301.
[18] T. C. Shyu, P. F. Damasceno, P. M. Dodd, A. Lamoureux, L. Xu, M. Shlian, M. Shtein, S. C. Glotzer, N. A. Kotov, Nat. Mater. 14 (2015) 785-789.
[19] Y. Zhang, C. J. Sheehan, J. Zhai, G. Zou, H. Luo, J. Xiong, Y. T. Zhu, Q. X. Jia, Adv. Mater. 22 (2010) 3027-3031.
[20] Y. Kim, J. Zhu, B. Yeom, M. Di Prima, X. Su, J. G. Kim, S. J. Yoo, C. Uher, N. A. Kotov, Nature 500 (2013) 59-63.
[21] J. Zang, S. Ryu, N. Pugno, Q. Wang, Q. Tu, M. J. Buehler, X. Zhao, Nat. Mater. 12 (2013) 321-325.
[22] M. Kim, P. Kang, J. Leem, S. W. Nam, Nanoscale 9 (2017) 4058-4065.
[23] S. Won, J. H. Kim, Y. Hwangbo, S. K. Lee, K. S. Kim, K. S. Kim, S. M. Lee, H. J. Lee, J. H. Ahn, S. B. Lee, Nanoscale 6 (2014) 6057-6064.
[24] Y. Zhang, Z. Yan, K. Nan, D. Xiao, Y. Liu, H. Luan, H. Fu, X. Wang, Q. Yang, J. J. Wang, W. Ren, H. Si, F. Liu, L. Yang, H. Li, J. J. Wang, X. Guo, H. Luo, L. Wang, Y. Huang, J. A. Rogers, Proc. Natl. Acad. Sci. 112 (2015) 11757-11764.
[25] S. Xu, Z. Yan, K. I. Jang, W. Huang, H. Fu, J. Kim, Z. Wei, M. Flavin, J. McCracken, R. Wang, A. Badea, Y. Liu, D. Xiao, G. Zhou, J. Lee, H. U. Chung, H. Cheng, W. Ren, A. Banks, X. Li, U. Paik, R. G. Nuzzo, Y. Huang, Y. Zhang, J. A. Rogers, Science 347 (2015) 154-159.
[26] W. Lee, Y. Liu, Y. Lee, B. K. Sharma, S. M. Shinde, S. D. Kim, K. Nan, Z. Yan, M. Han, Y. Huang, Y. Zhang, J. H. Ahn, J. A. Rogers, Nat. Commun. 9 (2018) 1417.
[27] Z. Liu, H. Du, J. Li, L. Lu, Z. Y. Li, N. X. Fang, Sci. Adv. 4 (2018) eaat4436.
[28] A. Lamoureux, K. Lee, M. Shlian, S. R. Forrest, M. Shtein, Nat. Commun. 6 (2015) 8092.
[29] Y. Morikawa, S. Yamagiwa, H. Sawahata, R. Numano, K. Koida, M. Ishida, T. Kawano, Adv. Healthc. Mater. 7 (2018) 1701100.
[30] D. G. Hwang, K. Trent, M. D. Bartlett, ACS Appl. Mater. Interfaces 10 (2018) 6747-6754.
[31] W. Zheng, W. Huang, F. Gao, H. Yang, M. Dai, G. Liu, B. Yang, J. Zhang, Y. Q. Fu, X. Chen, Y. Qiu, D. Jia, Y. Zhou, P. Hu, Chem. Mater. 30 (2018) 6063-6070.
[32] D. G. Hwang, M. D. Bartlett, Sci. Rep. 8 (2018) 3378.
[33] M. Isobe, K. Okumura, Sci. Rep. 6 (2016) 24758.
[34] A. Rafsanjani, K. Bertoldi, Phys. Rev. Lett. 118 (2017) 084301.
[35] Y. Cho, J.-H. Shin, A. Costa, T. A. Kim, V. Kunin, J. Li, S. Y. Lee, S. Yang, H. N. Han, I.-S. Choi, D. J. Srolovitz, Proc. Natl. Acad. Sci. 111 (2014) 17390-17395.
[36] Y. Tang, G. Lin, S. Yang, Y. K. Yi, R. D. Kamien, J. Yin, Adv. Mater. 29 (2017) 1604262.
[37] Y. Tang, G. Lin, L. Han, S. Qiu, S. Yang, J. Yin, Adv. Mater. 27 (2015) 7181-7190.
[38] M. K. Blees, A. W. Barnard, P. A. Rose, S. P. Roberts, K. L. McGill, P. Y. Huang, A. R. Ruyack, J. W. Kevek, B. Kobrin, D. A. Muller, P. L. McEuen, Nature 524 (2015) 204-207.
[39] A. Miyamoto, S. Lee, N. F. Cooray, S. Lee, M. Mori, N. Matsuhisa, H. Jin, L. Yoda, T. Yokota, A. Itoh, M. Sekino, H. Kawasaki, T. Ebihara, M. Amagai, T. Someya, Nat. Nanotechnol. 12 (2017) 907-913.
[40] J. Leem, M. C. Wang, P. Kang, S. Nam, Nano Lett. 15 (2015) 7684-7690.
[41] T. Jiang, R. Huang, Y. Zhu, Adv. Funct. Mater. 24 (2014) 396-402.
[42] B. J. Kim, H. Jang, S. K. Lee, B. H. Hong, J. H. Ahn, J. H. Cho, Nano Lett. 10 (2010) 3464-3466.
[43] Y. Wang, Z. Liu, B. Dong, in: Proc. Annu. Int. Conf. IEEE Eng. Med. Biol. Soc. EMBS, 2016, pp. 3511-3514.
[44] F. H. L. Koppens, T. Mueller, P. Avouris, A. C. Ferrari, M. S. Vitiello, M. Polini, Nat. Nanotechnol. 9 (2014) 780-793.
[45] F. Xia, T. Mueller, Y.-M. Lin, A. Valdes-Garcia, P. Avouris, Nat. Nanotechnol. 4 (2009) 839-843.
[46] W. Y. Chang, T. H. Fang, Y. C. Lin, in: Appl. Phys. A Mater. Sci. Process., 2008, pp. 693-701.

### Example 3: Additional Embodiments

Embodiments of the invention provide wearable sensors utilizing kirigami cuts to be insensitive to strain.

Embodiments of the invention are useful in measuring glucose levels in sweat and other biological fluids.

Embodiments provide sensors that are strain-insensitive because the kirigami cuts are the ones that induce the strain.

Embodiments provide sensors that are insensitive to strains so that they can induce stretches and twist and produce accurate readings.

Embodiments allow for sensor to be induced to stretching and twisting but still produce accurate readings.

Embodiments provide wearable sensors.

Embodiments provide a strain-insensitive sensor comprising: a first layer of polyimide wherein the polyimide is deposited on a sacrificial layer; a second layer of graphene, wherein said graphene is deposited on top of said first layer; a third layer of polyimide, wherein said third layer is deposited on said second layer; wherein the said layers include notches and cuts to form a serpentine structure.

Embodiments provide a strain-insensitive sensor comprising: a sensor housing unit, wherein said sensor housing unit is two polyimide layers with graphene in between, wherein said sensor housing unit includes a sensor to measure bodily fluids, wherein said sensor is embedded; wherein said sensor housing unit has an open notch in one of the polyimide layers.

Embodiments of the invention provide: non-aqueous strain-insensitive sensors; polyimide and Graphene based sensors; kirigami cut based sensors.

### Example 4A: Multiaxially-Stretchable Kirigami-Patterned Mesh Design for Graphene Sensor Devices

Abstract: In wearable electronics, significant research has gone into imparting stretchability and flexibility to otherwise rigid electronic components while maintaining their electrical properties. Thus far, this has been achieved through various geometric modifications of the rigid conductive components themselves, such as with microcracked, buckled, or planar meander structures. Additionally, strategic placement of these resulting components within the overall devices, such as embedding them at the neutral plane, has been found to further enhance mechanical stability under deformation. However, these strategies are still limited in performance, failing to achieve fully strain-insensitive electrical performance under biaxial stretching, twisting, and mixed strain states. Here, we develop a new platform for wearable, motion artifact-free sensors using a graphene-based multiaxially stretchable kirigami-patterned mesh structure. The normalized resistance change of the electrodes and graphene embedded in the structure is smaller than 0.5% and 0.23% under 180° torsion and 100% biaxial strain, respectively. Moreover, the resistance change is limited to 5% under repeated stretching-releasing cycles from 0% to 100% biaxial strain. In addition, we investigate the deformation mechanisms of the structure with finite element analysis. Based on the simulation results, we derive a dimensionless geometric parameter that enables prediction of stretchability of the structure with high accuracy. Lastly, as a proof-of-concept, we demonstrate a biaxially-stretchable graphene-based sensor array capable of monitoring of temperature and glucose level with minimized motion-artifacts.

Introduction: Wearable sensors have the potential to enable real-time monitoring of an individual's state of health or remote diagnosis of diseases simply via attachment to the skin. To achieve this goal, a wide variety of wearable sensors capable of continuous bio-signal monitoring have been developed and investigated [1-4]. When developing such wearable sensors, user movement must be taken into account because body movements are normally accompanied by stretching or contraction of the skin [5]. This can cause deformation of the active sensing element or even delamination of the active sensing element from the skin [6], which will severely distort the output bio-signals. To avoid this susceptibility to motion artifacts, the components in wearable devices must be reversibly stretchable up to >30% without change in their electrical properties, and they should fully adhere to the skin under body movements [7]. This task has been commonly accomplished by fabricating sensors on deformable planar substrates that adhere to the skin [8]. In particular, island-bridge configurations have been widely adopted using deformable planar substrates to achieve high stretchability for electronic components. In an island-bridge configuration, rigid sensing components (islands) are exemplary active-sensing regions (e.g., active-sensing region 120) and are separated and joined by stretchable metal interconnects (bridges), each of which is an exemplary perforated region (e.g., perforated region 110). Any overall strains become delocalized from the rigid islands (e.g., active-sensing region(s) 120), instead deforming the stretchable interconnect bridges (e.g., a perforated region(s) 110), thereby minimizing the strain experienced by the sensing components (e.g., sensor-portion(s) 121). Despite significant progress in developing wearable sensors with this strategy, the stretchable planar substrates used can be problematic due to their limited softness [9]. Additionally, stretchable planar substrates are inherently not breathable, inhibiting gas permeation and potentially causing severe skin irritation after prolonged use [10].

Another promising platform for motion artifact-free wearable devices is mesh electronic structures [11, 12]. Porous mesh structures are highly deformable, even enabling syringe injectable mesh electronics to reach targeted internal cavities before unfolding into their fully expanded state [13]. In addition, thin mesh structures can ensure conformal contact to complex curvilinear surfaces [14]. The breathability of porous mesh structures is significantly better than that of stretchable planar substrates. Furthermore, multi-sensor devices can be fabricated using mesh structures by means of island-bridge concepts [15].

As a potential strategy for making highly stretchable mesh structures, kirigami techniques have attracted much attention. Kirigami, a subgenre of the better-known origami (paper folding), involves the creation of three-dimensional (3D) structures through strategic incisions of two-dimensional (2D) sheets [16-20]. Thin films with kirigami patterns have out-of-plane deformation responses to elongation, redistributing in-plane stress into out-of-plane deformations under stretching, thereby providing macroscopic deformability of materials beyond their intrinsic mechanical properties. However, previously reported kirigami-based devices [21-23] were designed primarily for uniaxial stretching, only maintaining electrical properties under some specific mechanical deformations. Additionally, these devices were simple in functionality, with only one type of sensor, and therefore capable of only measuring a single signal.

Atomically thin materials offer unique advantages for wearable sensor applications, with enhanced electronic and functional properties over their bulk counterparts and readily tunable structures [24, 25]. In particular, graphene, an atomically-thin layer of carbon atoms, is mechanically robust [26], electrochemically stable [4], and biocompatible [27], which makes it a promising material for flexible or wearable sensors [28, 29]. Recently, we have developed wearable graphene kirigami-based devices capable of withstanding high uniaxial strains (up to 240%) [30]. Here, we improve upon our previous kirigami design by expanding it to a strain-insensitive, biaxially-stretchable, graphene-based sensor array. To this end, we combine kirigami techniques with the concept of island-bridge mesh electronics. The electrodes embedded in the kirigami-patterned mesh structure exhibit nearly constant electrical resistance under biaxial stretching of 100% and torsion of 180°. Moreover, the resistance change is limited to 5% under repeated stretching-releasing cycles from 0% to 100%. We additionally investigate the deformation mechanisms of the kirigami structure using finite element analysis (FEA) and propose a simple dimensionless geometric parameter that can predict the overall stretchability of our kirigami or similar structures. Furthermore, we demonstrate strain-insensitive temperature sensing, and solution-gated graphene field-effect-transistor (GFET)-based glucose sensing using these devices.

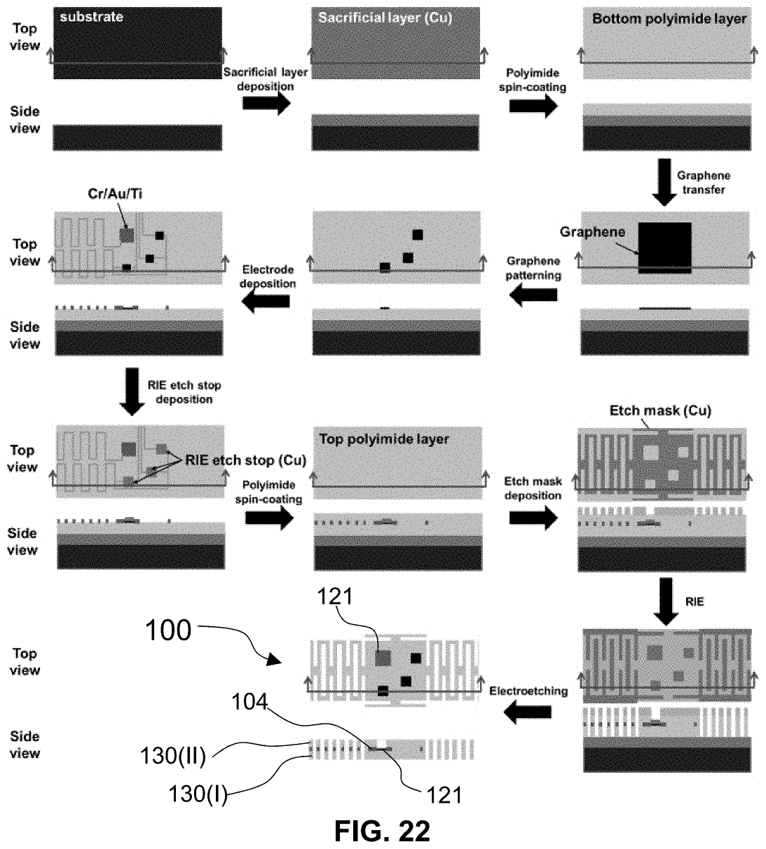

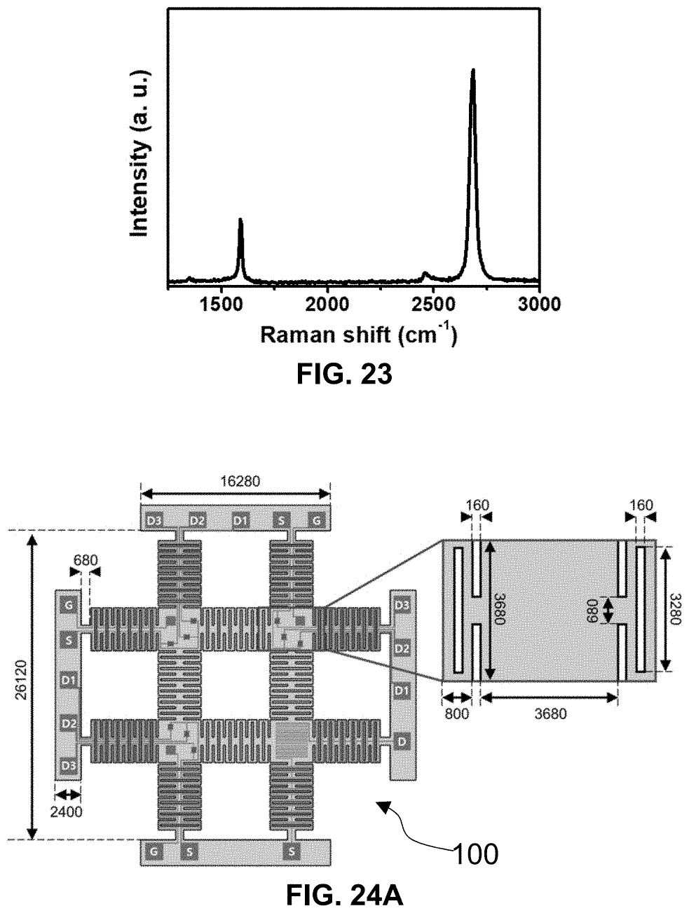

2 Experimental: 2.1 Fabrication of Kirigami-patterned Mesh Sensors: The fabrication scheme is shown in FIG. 22. First, a sacrificial layer (150 nm-thick copper film) was deposited onto a Si wafer via electron beam evaporation. The bottom polyimide layer was spin-coated and then cured at 350° C. for 4 hours under low pressure nitrogen flow. Graphene grown by chemical vapor deposition on copper foil (FIG. 23) was used for the GFET glucose sensors. After transferring graphene onto the bottom polyimide layer and annealing under argon flow, the graphene channels were patterned via photolithography and reactive ion etching (RIE). Next, Cr/Au/Ti metal electrodes (15/150/15 nm), including the contact pads and planar gates, were deposited. Additionally, an RIE etch stop (40 nm thick copper film) to protect the graphene channels was deposited before the top polyimide layer was spin-coated and cured. A 40 nm thick copper etch mask was then patterned on the top polyimide layer and the entire sandwich structure was then etched by RIE to create the kirigami cuts entirely through the polyimide. Finally, the device was released from the wafer by electroetching of the sacrificial layer, protective layer, and etch mask. The released device consists of a sandwich structure containing the electrodes and graphene between two polyimide layers with selective holes in the top layer enabling electrical contact to the graphene channels and contact electrodes. Polyimide was specifically chosen as the structural material for our design as it is biocompatible, readily spincoat-able, and highly inert to the chemicals and high temperatures involved in the photolithography process.

2.2 Finite Element Analysis of Kirigami-patterned Mesh Structures: Non-linear finite element analysis was carried out using the Structural Mechanics Module in COMSOL Multiphysics®. For the polyimide structural material of the kirigami devices, we assumed a true stress-strain curve of the material as follows,

σ=E₁ε if σ≤σ_{y}

E₂(ε−ε_{y})+E₁ε_{y} if σ>σ_{y} (I)

where E₁ is 2.1 GPa, E₂ is 214 MPa, σ_{y} is 144 MPa and σ_{y} is the strain where E₁ε=σ_{y} [30]. The loading was imposed either by moving the ends along the plane in steps or directly applying axial forces to the ends. The increments of displacement or axial force were kept small for convergence of the non-linear problem.

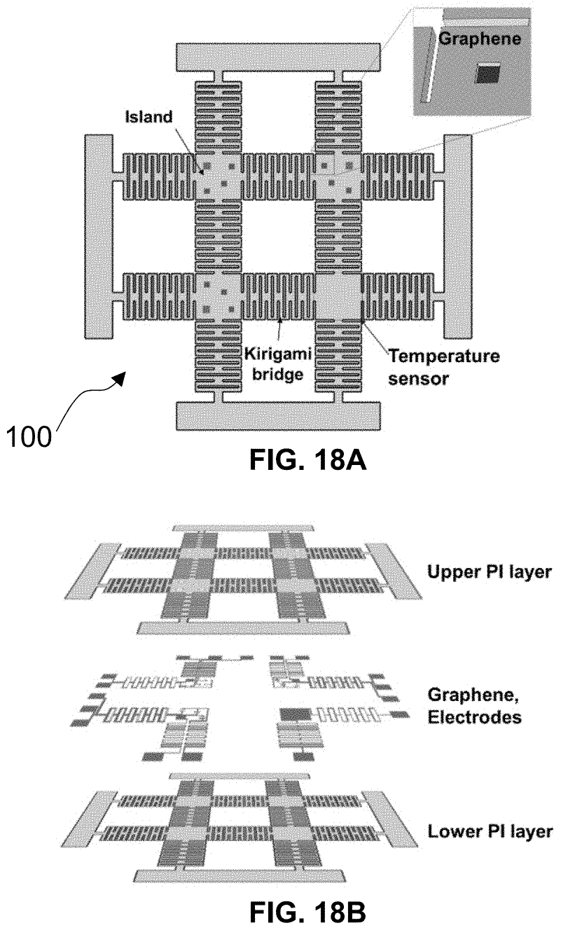

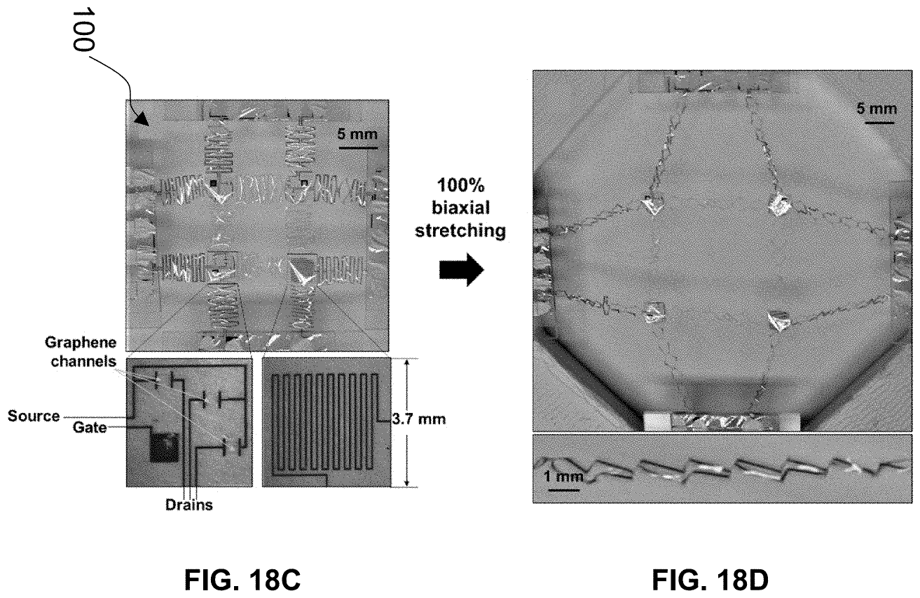

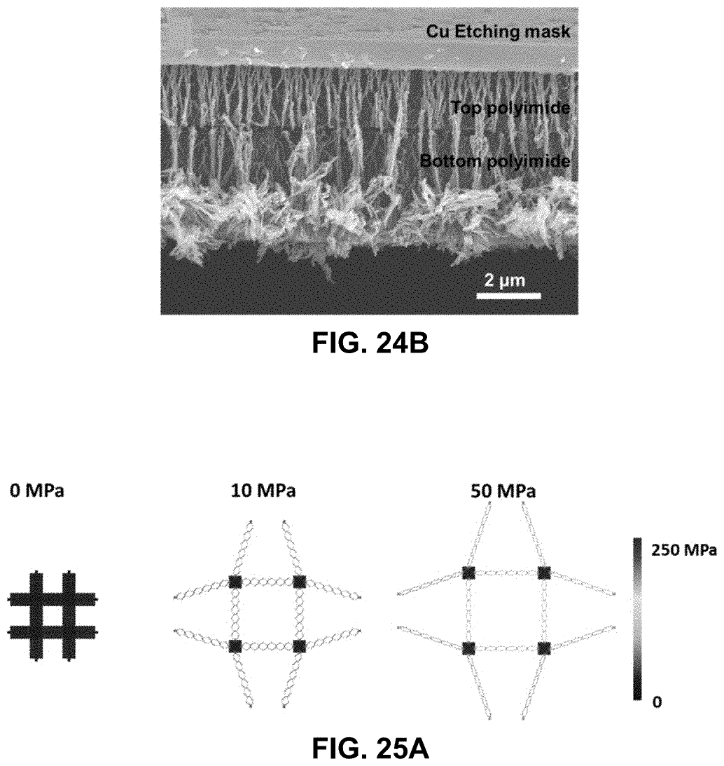

3 Results and Discussion: 3.1 Design of Kirigami-Patterned Mesh Structure for Strain-Insensitive Devices: FIGS. 18A-18B show the overall structural design of our kirigami devices for strain-insensitive wearable sensing. We adopted a 2×2 island-bridge mesh structure with four separate islands, enabling multifunctional sensing (e.g., glucose, temperature) on the same device (FIG. 18A). The four islands are connected to each other and the outer contact pads with bridges. The island-to-contact pad bridges carry electrodes, while the island-to-island bridges do not. FIG. 18B shows the final design of our kirigami devices (see also FIG. 24A). To impose stretchability and enhance the breathability of the mesh structure, kirigami cuts and notches were added to the bridges. On the islands, temperature and GFET glucose sensors were fabricated. As shown in FIG. 18B, all of the electronic components are sandwiched at the neutral plane of the kirigami-patterned mesh structure. The thickness of the top and the bottom polyimide layers was 3˜5 μm (FIG. 24B). Small windows in the top layer of polyimide allow for electrolyte solution gating between the gates and graphene channels of the GFET-based glucose sensors. An island, as the term is used herein, is an exemplary active-sensing region and a bridge, as the term is used herein, is an exemplary perforated region.

FIGS. 18C and 18D show a graphene-based kirigami-patterned multi-sensor device in an unstretched (εₙ=0%) and biaxially stretched (εₙ=100%) state, respectively. Similar to previously reported kirigami structures with stretchable conducting electrodes [30], stretching of the overall structure causes out-of-plane deformations of the kirgami bridges. However, the additional 4-fold rotational symmetry of our kirigami structure allows it to stretch under biaxial loading.

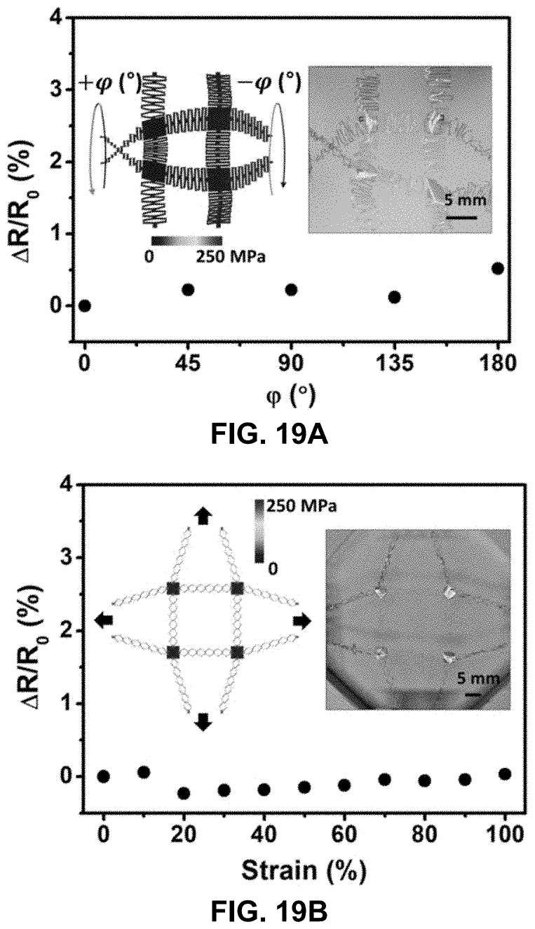

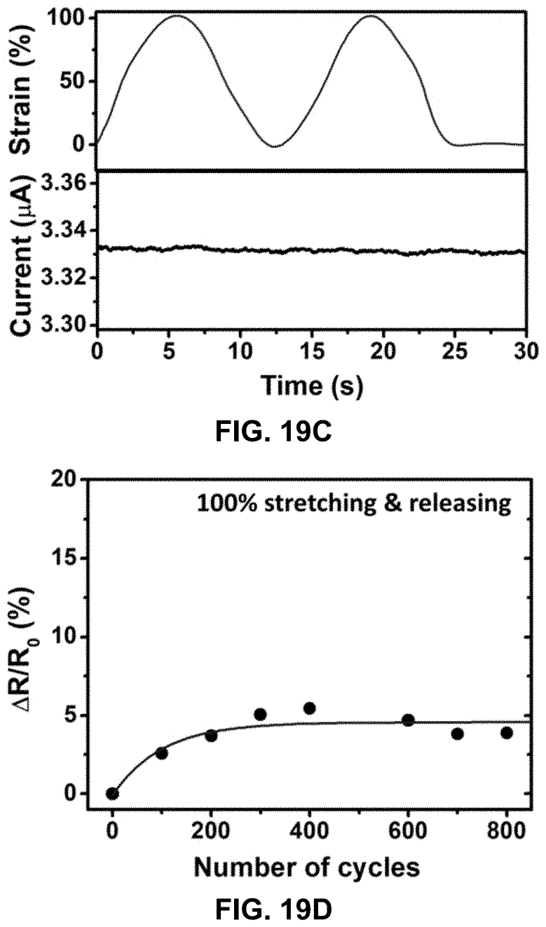

In order to achieve motion artifact-free sensing for wearable devices, the most important requirement is that the electrical responses of electrodes and sensing electronics remain unchanged under various deformation conditions. Therefore, we assessed the normalized change in resistance (ΔR/R₀) of the electrodes and graphene-based FET sensors embedded in our kirigami structure (FIGS. 19A-19D). As the kirigami was twisted by applying torsional stress at the left and right ends (with the top and bottom ends fixed), there was a negligibly small change in resistance (<0.5%) under torsional deformation (FIG. 19A). Similarly, stable electrical resistance was observed under biaxial stretching, with a change in resistance smaller than 0.3% for biaxial strain from εₙ=0% to εₙ=100% (FIG. 19B). The estimated strain gauge factor, defined as ΔR/R₀/εₙ was less than 6×10⁻⁴ for biaxial stretching. For both torsional biaxial strains, the mechanical responses of the fabricated kirigami-patterend devices matched well with the FEA simulations. We also carried out time-resolved current measurements for the electrode embedded in a kirigami structure while stretching it biaxially from 0 to 100%. The current remained stable over time, which demonstrates stability during movement (FIG. 19C).

Another important feature for wearable sensors is cyclic reversibility, as human skin is repeatedly stretched and contracted. In order to demonstrate reversibility and durability, the normalized resistance change was measured under repeated biaxial stretching-releasing cycles between εₙ=0% and εₙ=100% (FIG. 19D). Although there was an approximately 3.7% initial increase of resistance in the first 200 cycles, the normalized resistance stabilized and the resistance change was less than 2% between 200 and 800 stretching-releasing cycles. We attribute the small changes in resistance to unintentional overstretching (>100%) of the kirigami structure during stretching-releasing cycles.

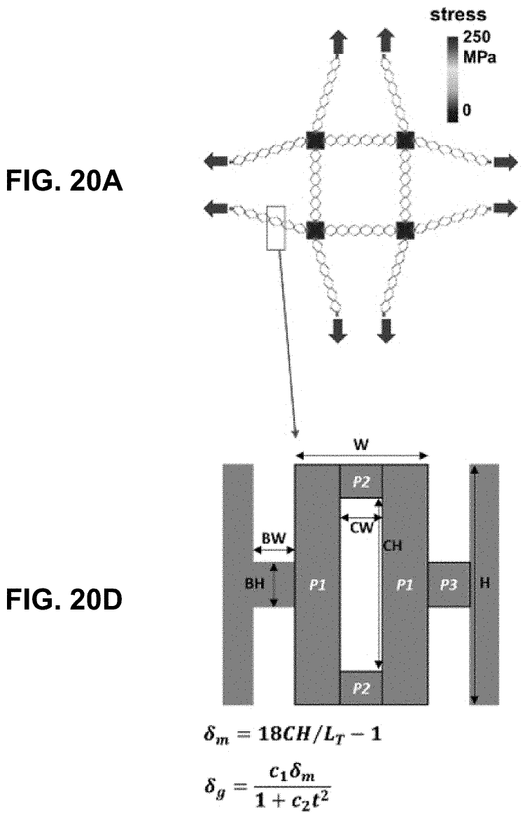

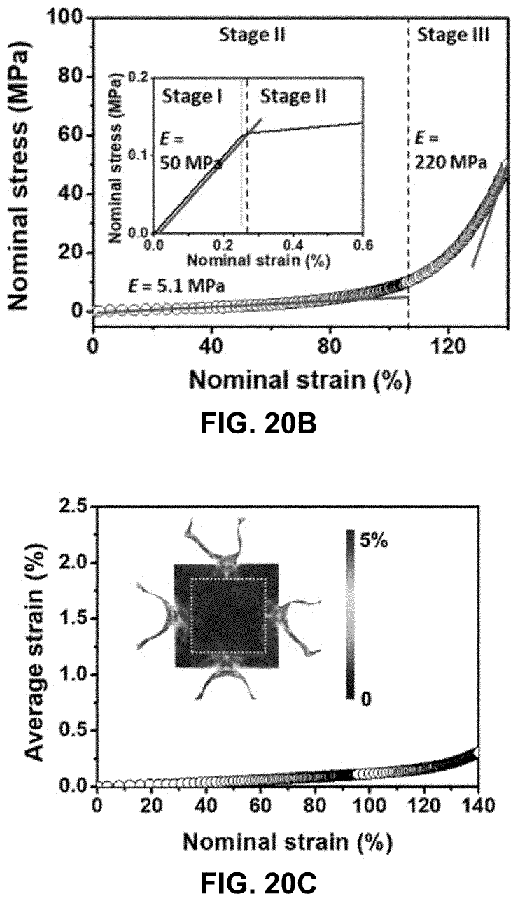

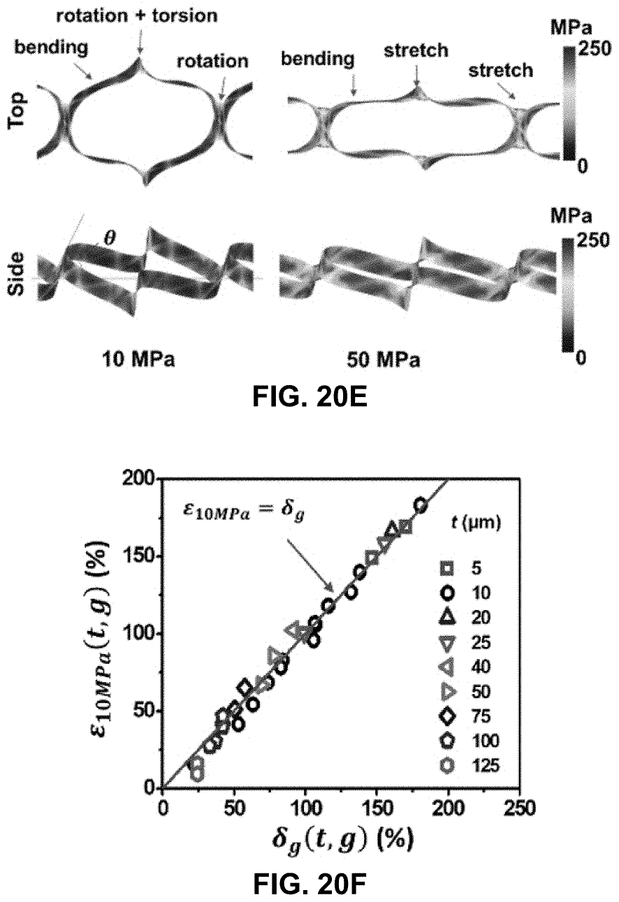

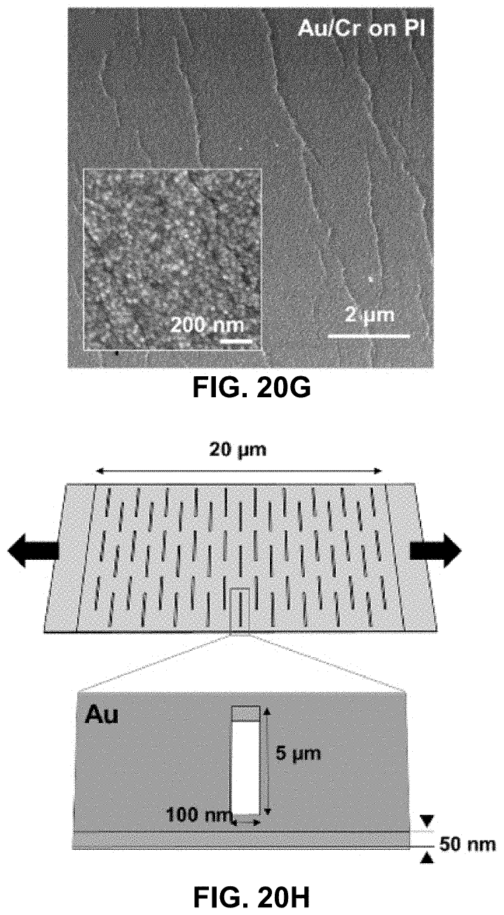

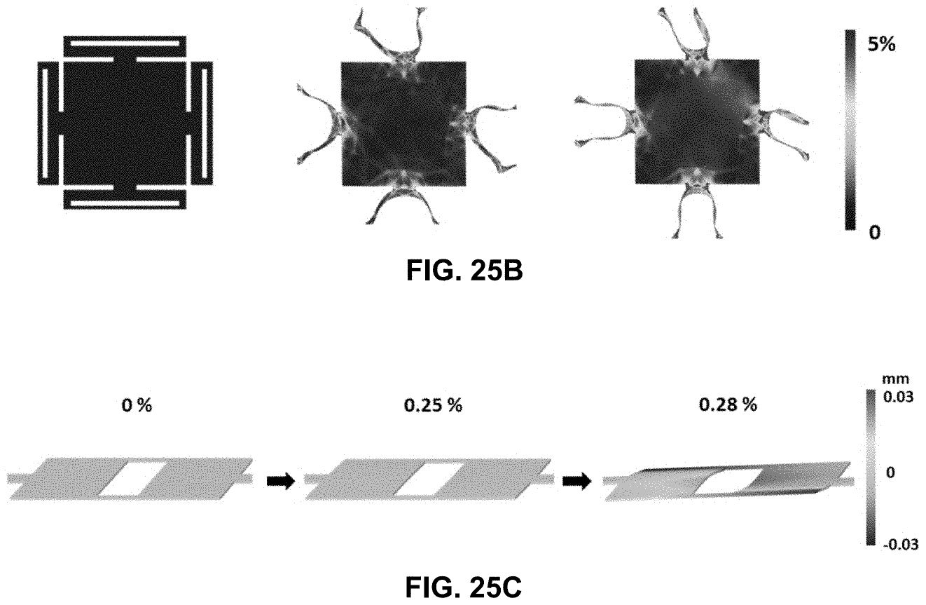

3.2 Finite Element Analysis and Mechanics Model of Kirigami-Patterned Mesh Structure: In order to understand the deformation mechanisms of our kirigami structure, we first characterized the mechanical response of a 10 μm-thick kirigami structure under biaxial loading using FEA (FIG. 20A, see also Section 2. Experimental). The simulated nominal stress-nominal strain (σₙ−εₙ) responses of the kirigami show three different stages (FIG. 20B). In stage I (0≤σₙ≤0.125 MPa, 0≤εₙ≤0.25%), σₙ and εₙ have a linear relationship with the slope of 50 MPa. In this stage, the main deformation mechanism of the kirigami structure is in-plane bending of the bridges (see also FIGS. 25A-25C). Next, in stage II (0.125 MPa≤σₙ≤10 MPa, 0.25≤εₙ≤105%), the average tangent modulus drops significantly to 5.1 MPa as a result of the out-of-plane deformation of the bridges. As εₙ increases above 105% (stage III), the kirigami becomes rapidly stiffer. The slope at εₙ=140% is 220 MPa, which is similar to the modulus of polyimide above its yield point (214 MPa).

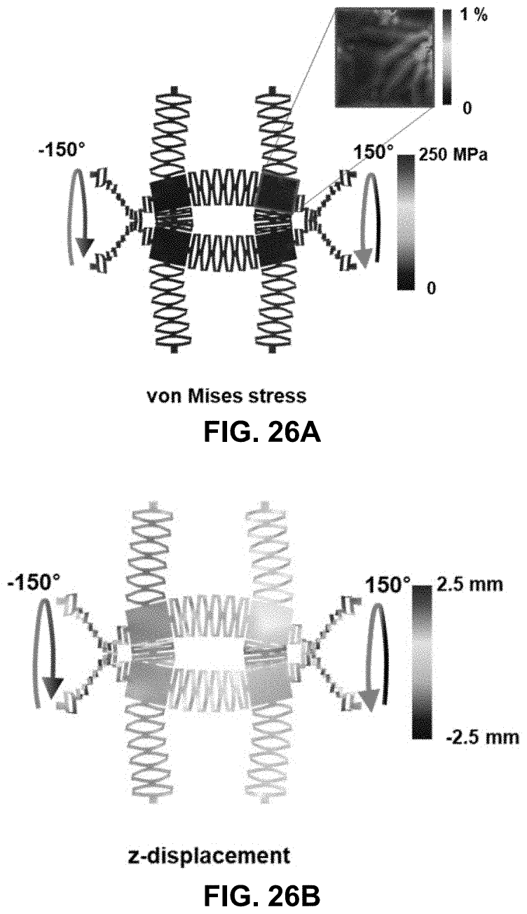

On the islands, the average strain does not exceed 0.4% over the entire simulated range of σₙ (FIG. 20C), indicating that our kirigami design effectively distributes the stress away from the islands. Strain in the islands was estimated to be very limited under torsion of the overall device as well (FIGS. 26A-26B).

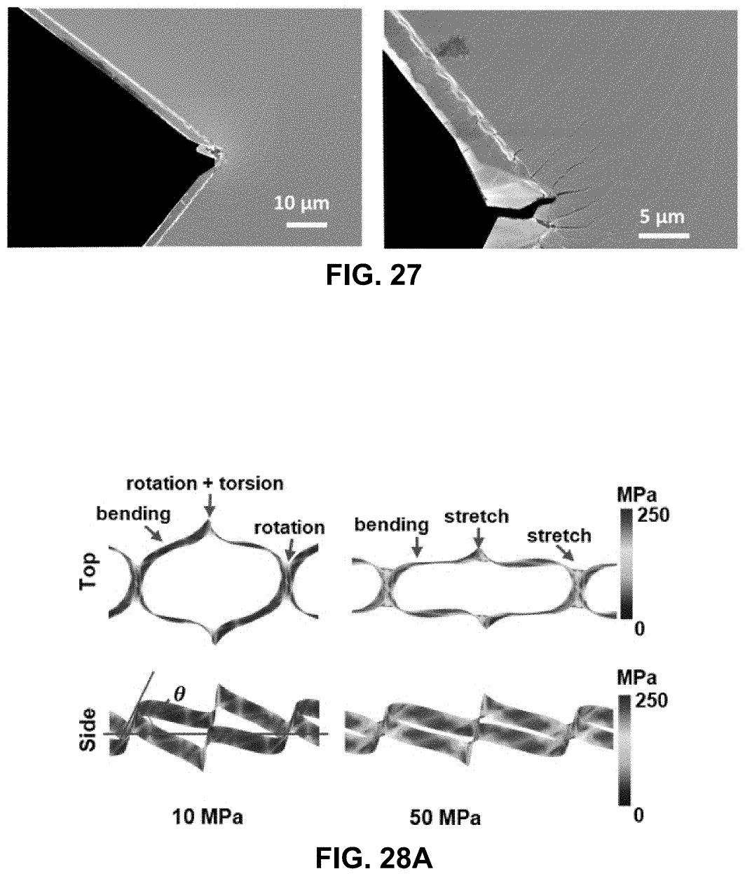

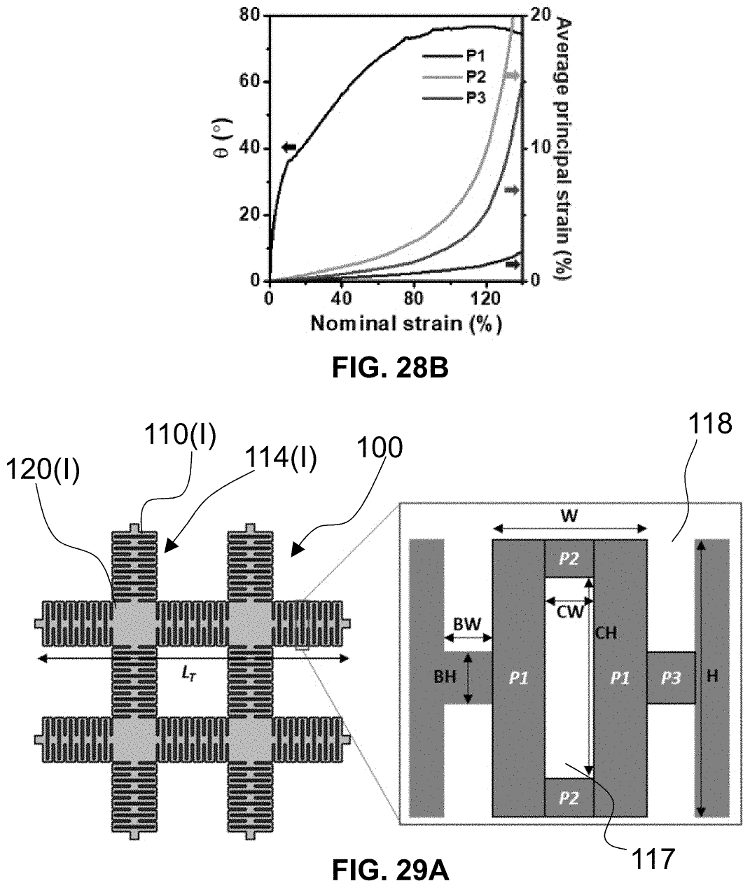

The mechanical deformation of the kirigami bridges in stage II and stage III was further analyzed by dividing the unit cell of bridges into three plates. The unit cell of kirigami bridges consists of two long plates (P1), two connection plates at the cuts (P2) and one connection plate at the notch (P3) (FIG. 20D). FIG. 20E shows the von Mises stress distribution in a kirigami bridge and its deformed structure at σₙ=10 MPa and 50 MPa. The stress was localized near the tip of cuts (see also FIG. 27). Under in-plane loading, the bending of P1 with out-of-plane rotation was predicted (FIG. 20E), which is consistent with our experimental observations (lower image of FIG. 20D). Owing to the out-of-plane bending of P1, the kirigami structure can be elongated in the in-plane direction significantly with a relatively small loading force. In stage II, the rotation angle (θ) of P1 plates gradually increases and then saturates at 76° (FIGS. 28A-28B). The rotation of P1 accompanied by the torsion of P2 and rotation of P3 rather than stretching of P2 or P3 in stage II, results in a low effective modulus for the whole structure. After reaches to the saturation value, the main deformation mechanism of the kirigami structure transitions to stretching around P2 and P3 (stage III). Therefore, the in-plane stress starts to concentrate around P2 and P3 in stage III, and the effective modulus of the kirigami structure becomes similar to the modulus of polyimide. It is expected that mechanical failure of kirigami structures can easily take place when it is in stage III.

Next, 10 μm thick kirigami designs with varying design parameters g (including W, BW, CW, H, BH, CH) shown in FIG. 20D were also evaluated to explore the relationship between the stretchability of kirigami designs and their design parameters (see also FIGS. 29A-29G). CW and BH, which are not related to initial total length of the kirigami structure (L_{T} [μm]=18 W+21BW+2H+1000), barely affect the mechanical response of the kirigami structure (FIGS. 29B and 29C). On the other hand, the increase of CH allows for more elongation of the kirigami structure (FIG. 29D). In addition, increasing either BW or W, which increases L_{T}, reduces the stretchability of the kirigami structure (FIGS. 29E and 29F). This parametric study clearly gives an insight into the effects of geometric parameters on the stretchability of the kirigami; the bendability of the P1 plate, which is proportional to CH, determines the overall stretchability of kirigami structure.

Our finding on how CH is related to kirigami stretchability is supported by following explanations. Assuming P1 can be completely folded with out-of-plane rotation of 90° and the bending of P1 plates is the only deformation mechanism, the total length of the kirigami structure after complete bending of P1 plates would be approximately 18×CH. Nominal nominal strain in this case can be approximated as δₘ(g)=18CH/L_{T}−1. Next, we compare δₘ with the nominal strain of a 10 μm-thick kirigami structure at a nominal stress of 10 MPa (i.e., ε_{10MPa}(10 μm,g)). Here, 10 MPa was chosen because at that stress, kirigami structures will be in stage II or early stage III, with large deformations but minimized mechanical failure. We found that ε_{10MPa}(10 μm,g) and δₘ have a strong linear correlation (FIG. 29G).

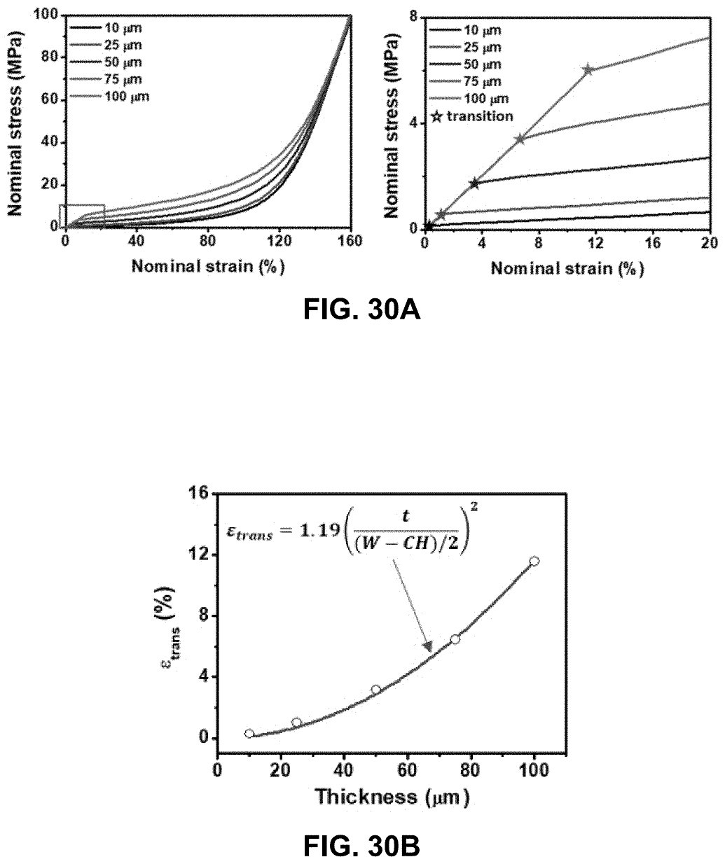

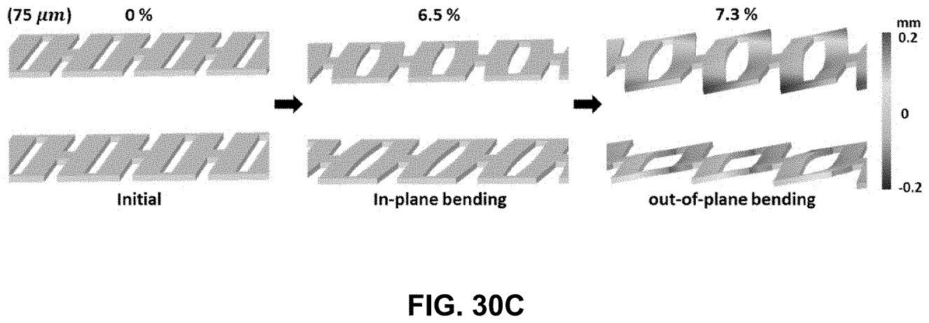

We also investigated the effects of thickness on the mechanical response of the kirigami structure (FIGS. 30A-30C). In stage III, as P1 bending is no longer the main deformation mechanism, a thickness effect is not observed. On the other hand, stages I and II are affected by a change in thickness. First, the transition strain at which the out-of-plane deformation initiates increases as the thickness increases (FIGS. 30A and 30B), which is consistent with the previous results [31]. In addition, the kirigami structures in stage II become stiffer as thickness (t) increases because the bending stiffness of the P1 plate increases with t³.

From the above parametric study, we can derive an analytical equation that is capable of describing the σₙ-εₙ relation of the kirigami structure in stage II. At a certain nominal stress (σₙ), we can express the nominal strain (εₙ) of a kirigami structure given certain design parameters (g) and thickness, as δ_{g}(t,g), which is approximately given by the following equation,

δ_{g}(t,g)=c₁δₘ/(1+c₂t²) (2)

where c₁ and c₂ are constants and δₘ(g)=18CH/L_{T}−1 (see Discussions in Example 4B). In the derivation, we assumed that the bendability of the P1 plate determines the overall stretchability of the kirigami structure. To confirm the validity of eq. (2), we correlated δ_{g}(t,g) with FEA-simulated ε_{10MPa}(t,g) of the kirigami structure by changing the various design parameters and t. Notably, ε_{10MPa}≈δ_{g} with proper values of c₁ and c₂ (FIG. 20F). The resulting δ_{g} therefore enables a nearly analytical prediction of the stretchability for a kirigami structure with parameters g and thickness at a certain applied stress without requiring complex FEA simulations. In addition, the linear relation between ε_{10MPa} and δ_{g} further demonstrates that out-of-plane bending of P1 dominates overall deformation of kirigami structures.

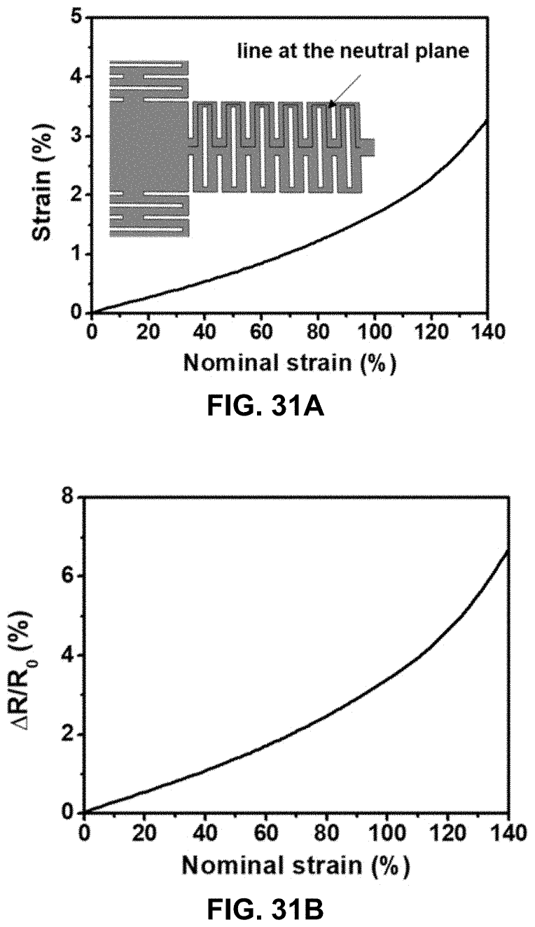

To investigate the strain-insensitive electrical resistance of the patterned metal features (e.g., patterned Cr/Au/Ti temperature sensor in FIG. 18C) in our kirigami devices, we also simulated the strain of a line at the neutral plane (ε_{L}) of the kirigami bridge structure as a function of εₙ (FIG. 31A). At εₙ=100%, ε_{L} is predicted to be 1.7%. The simulated E_{L} is then converted to the change in electrical resistance using the equation with assumption that no cracks are formed in the electrode, ΔR/R₀=(1+E_{L})²−1 (FIG. 31B) [32]. As a result, ΔR/R₀ is predicted to be 3.5% at εₙ=100%, which is higher than our experimental results. We attributed the difference between simulation and experimental results to formation of multiple microcracks or nanocracks in the electrodes during the fabrication processes. We confirmed these features by observing multiple microcracks and nanocracks (FIG. 20G) formed in Cr/Au thin film deposited on a polyimide kirigami structure. Such cracks may be formed during fabrication processes that induce unintentional mechanical deformation of the kirigami structure. When microcracks or nanocracks are formed, applied stresses are localized to the crack tips (FIG. 20H) [33]. This can lead to a significant reduction of strain in metal thin films (FIG. 20I). As a result, under small strains that do not induce additional crack propagation (<5%), the change in electrical resistance of the cracked metal can be negligible [34].

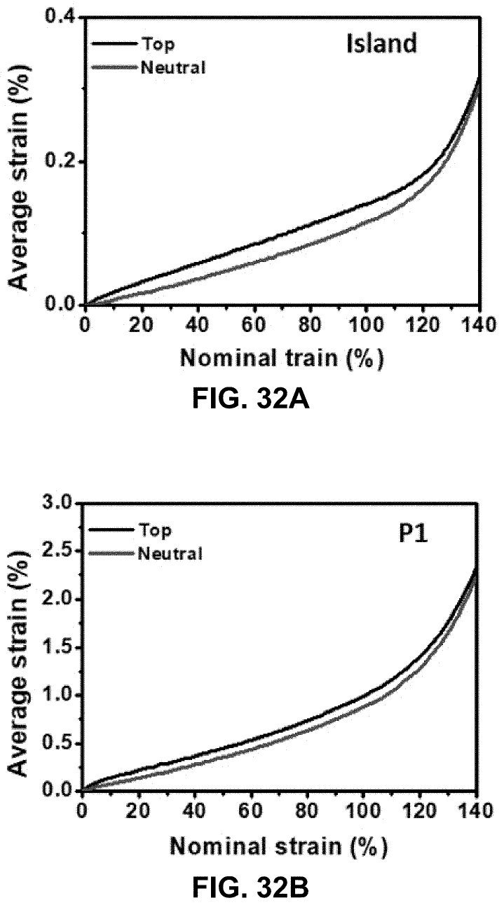

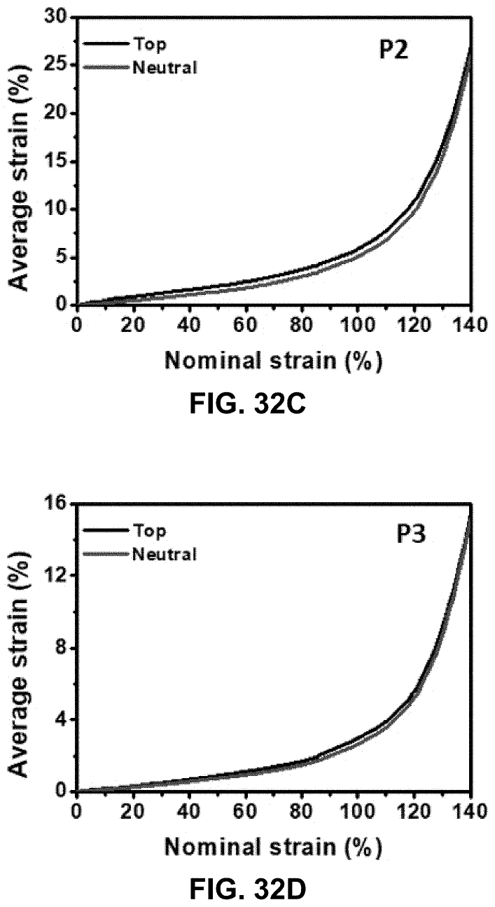

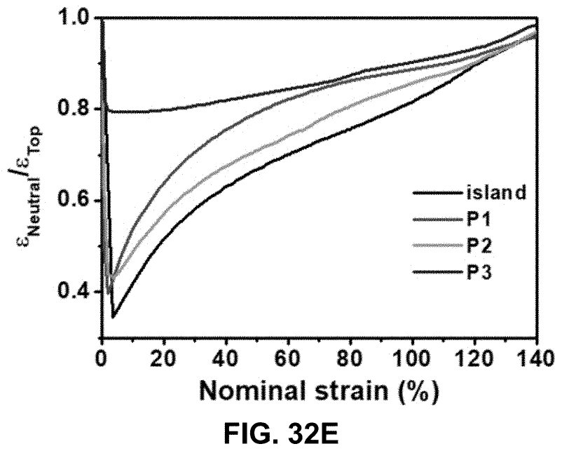

It is worth noting here that the average strain in the neutral plane was predicted to be 60˜80% of the average strain in the top plane, which indicates that placing all electrodes in the middle of the polyimide film helps to achieve strain-insensitive electrical resistance (FIGS. 32A-32E).

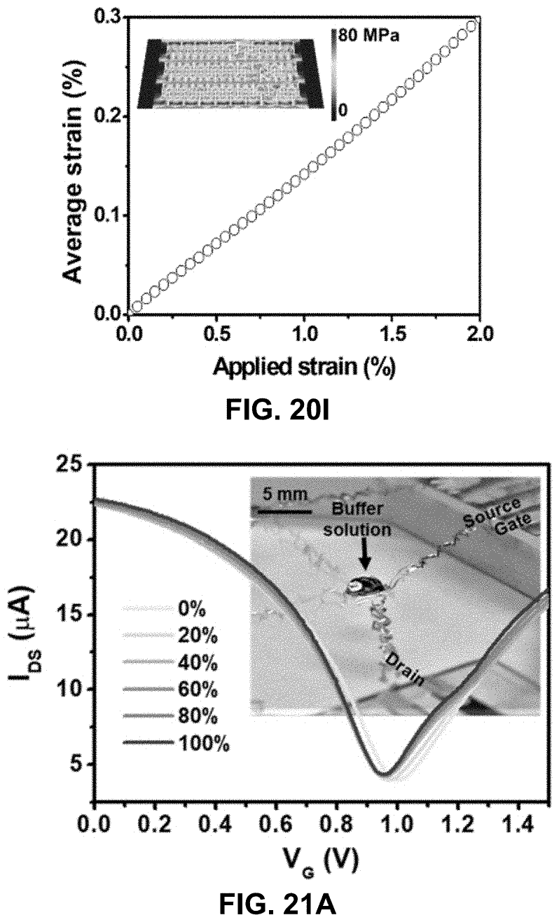

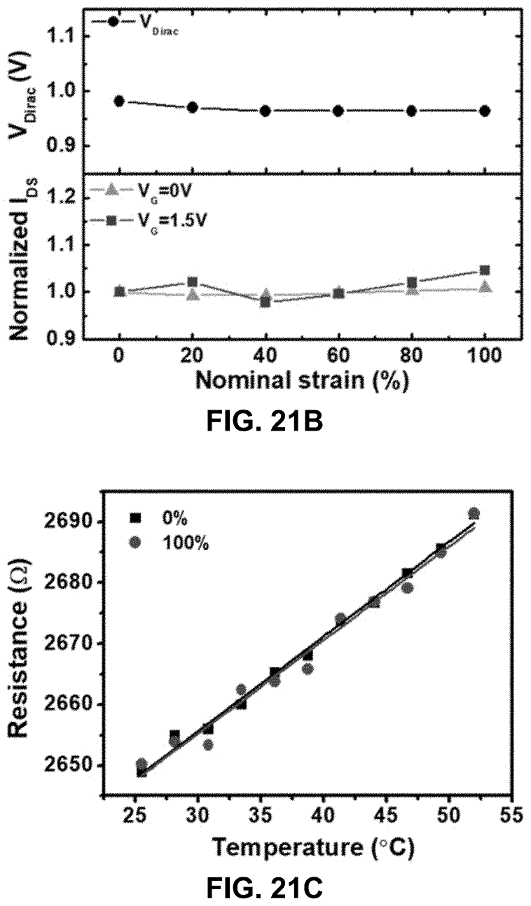

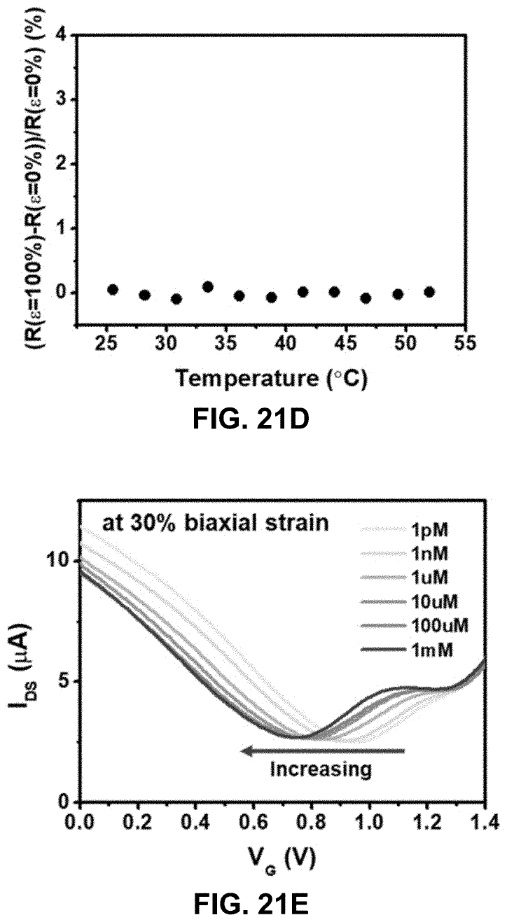

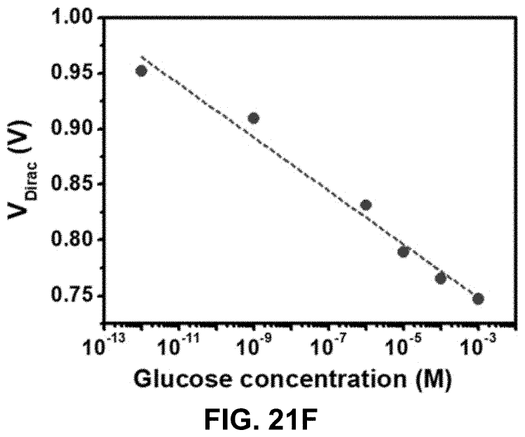

3.3 Solution-Gated GFET-based Sensors: As a demonstration of our kirigami devices for wearable sensor applications, we assessed the strain-insensitive sensor outputs by integrating the solution-gated graphene FETs in our kirigami-patterned mesh structures (FIG. 21A). Owing to their high conductivity, high surface area and robust chemical properties of graphene, solution-gated graphene transistors are considered one of the most promising bio/chemical sensors for quantifying analytes in solution using electrical signals. For the gate, an integrated planar gate electrode (Cr/Au/Ti) with thickness 15/150/15 nm was used. To measure the gate-modulated current of our GFETs, a droplet of phosphate-buffered saline (PBS), mimicking sweat, was placed on the island, thereby linking the integrated gate electrode to the three graphene channels through openings on the polyimide. The transfer curves of the GFETs were characterized by applying a varying gate voltage from 0V to 1.5V during stretching. Our GFETs exhibited stable transfer curves during stretching. Furthermore, the Dirac voltage (V_{Dirac}) changed by less than 2% at applied strains between Eₙ=0% and εₙ=100%, and the I_{DS} current at V_{G} of 0 and 1.5V were also nearly independent of stretching (FIG. 21B). This stable operation of our GFETs clearly demonstrates that the graphene channel in the island remains intact during large degree of stretching. This compares favorably against conventional solution-gated GFETs fabricated on elastomers, which showed severe degradation due to the formation of microcracks when stretched more than 3% [35].

In addition, we also assessed the performance of a resistive temperature sensor on one of the islands from 25-55° C. at εₙ=0% and εₙ=100% (FIG. 21C). In the measured range, the resistance of the temperature sensor increased linearly with temperature as a result of enhanced electron-phonon scattering in the Cr/Au/Ti electrode. The sensitivity of the temperature sensor was 1.56Ω/K and 1.54Ω/K at the neutral state and stretched state, respectively. The normalized resistance change between 100% and 0% stretching at each measured temperature was negligibly small (FIG. 21D), thereby showing strain insensitivity.

Lastly, we demonstrated a solution-gated GFET-based glucose sensor embedded in our kirigami-patterned mesh structure. For the detection of glucose, glucose oxidase (GOₓ) was deposited on graphene channel surface. When glucose is oxidized by GOₓ, gluconic acid and hydrogen peroxide (H₂O₂) are produced via following reaction [36]:

Glucose+H₂O+O₂→Gluconic acid+H₂O₂ (reaction 1)

GFET-based glucose sensors monitor the amount of H₂O₂ produced, which is equal to the amount of glucose consumed [37]. The electrochemical reaction of H₂O₂ at gate electrode, H₂O₂→O₂+2H⁺⁺2e⁻, modifies the voltage drop at an electric double layer on gate/electrode interface. It changes effective gate voltage that applies on the graphene channel, resulting in the shift in the Dirac voltage of the GFETs. At a biaxial strain of 30%, when glucose concentration decreased from 1 mM to 1 pM, a change in V_{Dirac} from 0.95 V to 0.75 V was observed (FIG. 21E). The sensitivity of our glucose sensor with integrated gate electrode was −24 mV/decade in the glucose concentration range of 1 pM to 1 mM (FIG. 21F), consistent with previous results [38]. Since the reported glucose concentration in sweat for diabetic patients is between 0.01 and 1 mM [39], this shows that our glucose sensor can be used as wearable sweat sensor for non-invasive monitoring.

4 Conclusions: In conclusion, we demonstrated a biaxially-stretchable kirigami-patterned mesh platform for motion-artifact free, graphene-based wearable sensors. When graphene and metal electrodes were embedded in the structure, the change in their electrical resistance was less than ˜0.5% under mechanical deformations such as 180° twisting and 100% biaxial stretching. Using FEA simulations, the deformation mechanism of the structure was investigated, revealing that out-of-plane deformation of kirigami bridges is a key factor that governs the stretchability of kirigami structures. In addition, we derived a simple equation that relates the stretchability of a kirigami structure with various design parameters. This equation gives insight into the deformation mechanisms of kirigami structures, and also enables prediction for the stretchability of future kirigami designs. Moreover, we demonstrated strain-insensitive performance of solution-gated GFETs, which offers promising potential for various bio-sensing applications. Lastly, we demonstrated strain-insensitive stretchable sensors that can monitor temperature and glucose concentration. Although our demonstration of kirigami devices is limited to sensing one signal at a time, we believe our kirigami devices can be integrated with electronic circuits for wearable healthcare systems that enable simultaneous monitoring of multiple bio-signals, data processing and data transmission.

### REFERENCES ASSOCIATED WITH EXAMPLE 4A

[1] Gao, W.; Emaminejad, S.; Nyein, H. Y. Y.; Challa, S.; Chen, K.; Peck, A.; Fahad, H. M.; Ota, H.; Shiraki, H.; Kiriya, D.; Lien, D. H.; Brooks, G. A.; Davis, R. W.; Javey, A. Fully integrated wearable sensor arrays for multiplexed in situ perspiration analysis. Nature 2016, 529, 509-514.
[2] Koh, A.; Kang, D.; Xue, Y.; Lee, S.; Pielak, R. M.; Kim, J.; Hwang, T.; Min, S.; Banks, A.; Bastien, P.; Manco, M. C.; Wang, L.; Ammann, K. R.; Jang, K. I.; Won, P.; Han, S.; Ghaffari, R.; Paik, U.; Slepian, M. J.; Balooch, G.; Huang, Y.; Rogers, J. A. A soft, wearable microfluidic device for the capture, storage, and colorimetric sensing of sweat. Sci. Transl. Med. 2016, 8, 366ra165.
[3] Kim, J.; Campbell, A. S.; de Avila, B. E.; Wang, J. Wearable biosensors for healthcare monitoring. Nat. Biotechnol. 2019, 37, 389-406.
[4] Lee, H.; Choi, T. K.; Lee, Y. B.; Cho, H. R.; Ghaffari, R.; Wang, L.; Choi, H. J.; Chung, T. D.; Lu, N.; Hyeon, T.; Choi, S. H.; Kim, D. H. A graphene-based electrochemical device with thermoresponsive microneedles for diabetes monitoring and therapy. Nat. Nanotechnol. 2016, 11, 566-572.
[5] Jeong, J. W.; Yeo, W. H.; Akhtar, A.; Norton, J. J.; Kwack, Y. J.; Li, S.; Jung, S. Y.; Su, Y.; Lee, W.; Xia, J.; Cheng, H.; Huang, Y.; Choi, W. S.; Bretl, T.; Rogers, J. A. Materials and optimized designs for human-machine interfaces via epidermal electronics. Adv. Mater. 2013, 25, 6839-6846.
[6] Bariya, M.; Nyein, H. Y. Y.; Javey, A. Wearable sweat sensors. Nature Electronics 2018, 1, 160-171.
[7] Yamada, T.; Hayamizu, Y.; Yamamoto, Y.; Yomogida, Y.; Izadi-Najafabadi, A.; Futaba, D. N.; Hata, K. A stretchable carbon nanotube strain sensor for human-motion detection. Nat. Nanotechnol. 2011, 6, 296-301.
[8] Kim, D. H.; Lu, N.; Ma, R.; Kim, Y. S.; Kim, R. H.; Wang, S.; Wu, J.; Won, S. M.; Tao, H.; Islam, A.; Yu, K. J.; Kim, T. I.; Chowdhury, R.; Ying, M.; Xu, L.; Li, M.; Chung, H. J.; Keum, H.; McCormick, M.; Liu, P.; Zhang, Y. W.; Omenetto, F. G.; Huang, Y.; Coleman, T.; Rogers, J. A. Epidermal electronics. Science 2011, 333, 838-843.
[9] Kim, D. H.; Song, J.; Choi, W. M.; Kim, H. S.; Kim, R. H.; Liu, Z.; Huang, Y. Y.; Hwang, K. C.; Zhang, Y. W.; Rogers, J. A. Materials and noncoplanar mesh designs for integrated circuits with linear elastic responses to extreme mechanical deformations. Proc. Natl. Acad. Sci. USA 2008, 105, 18675-18680.
[10] Miyamoto, A.; Lee, S.; Cooray, N. F.; Lee, S.; Mori, M.; Matsuhisa, N.; Jin, H.; Yoda, L.; Yokota, T.; Itoh, A.; Sekino, M.; Kawasaki, H.; Ebihara, T.; Amagai, M.; Someya, T. Inflammation-free, gas-permeable, lightweight, stretchable on-skin electronics with nanomeshes. Nat. Nanotechnol. 2017, 12, 907-913.
[11] Tian, B.; Liu, J.; Dvir, T.; Jin, L.; Tsui, J. H.; Qing, Q.; Suo, Z.; Langer, R.; Kohane, D. S.; Lieber, C. M. Macroporous nanowire nanoelectronic scaffolds for synthetic tissues. Nat. Mater. 2012, 11, 986-994.
[12] Hong, G.; Fu, T. M.; Qiao, M.; Viveros, R. D.; Yang, X.; Zhou, T.; Lee, J. M.; Park, H. G.; Sanes, J. R.; Lieber, C. M. A method for single-neuron chronic recording from the retina in awake mice. Science 2018, 360, 1447-1451.
[13] Liu, J.; Fu, T. M.; Cheng, Z.; Hong, G.; Zhou, T.; Jin, L.; Duvvuri, M.; Jiang, Z.; Kruskal, P.; Xie, C.; Suo, Z.; Fang, Y.; Lieber, C. M. Syringe-injectable electronics. Nat. Nanotechnol. 2015, 10, 629-636.
[14] Kim, D. H.; Viventi, J.; Amsden, J. J.; Xiao, J.; Vigeland, L.; Kim, Y. S.; Blanco, J. A.; Panilaitis, B.; Frechette, E. S.; Contreras, D.; Kaplan, D. L.; Omenetto, F. G.; Huang, Y.; Hwang, K. C.; Zakin, M. R.; Litt, B.; Rogers, J. A. Dissolvable films of silk fibroin for ultrathin conformal bio-integrated electronics. Nat. Mater. 2010, 9, 511-517.
[15] Fu, T. M.; Hong, G.; Viveros, R. D.; Zhou, T.; Lieber, C. M. Highly scalable multichannel mesh electronics for stable chronic brain electrophysiology. Proc. Natl. Acad. Sci. USA 2017, 114, E10046-E10055.
[16] Blees, M. K.; Barnard, A. W.; Rose, P. A.; Roberts, S. P.; McGill, K. L.; Huang, P. Y.; Ruyack, A. R.; Kevek, J. W.; Kobrin, B.; Muller, D. A.; McEuen, P. L. Graphene kirigami. Nature 2015, 524, 204-207.
[17] Song, Z.; Wang, X.; Lv, C.; An, Y.; Liang, M.; Ma, T.; He, D.; Zheng, Y. J.; Huang, S. Q.; Yu, H.; Jiang, H. Kirigami-based stretchable lithium-ion batteries. Sci. Rep. 2015, 5, 10988.
[18] Lamoureux, A.; Lee, K.; Shlian, M.; Forrest, S. R.; Shtein, M. Dynamic kirigami structures for integrated solar tracking. Nat. Commun. 2015, 6, 8092.
[19] Won, P.; Park, J. J.; Lee, T.; Ha, I.; Han, S.; Choi, M.; Lee, J.; Hong, S.; Cho, K. J.; Ko, S. H. Stretchable and Transparent Kirigami Conductor of Nanowire Percolation Network for Electronic Skin Applications. Nano. Lett. 2019, 19, 6087.
[20] Tang, Y.; Lin, G.; Yang, S.; Yi, Y. K.; Kamien, R. D.; Yin, J. Programmable Kiri-Kirigami Metamaterials. Adv. Mater. 2017, 29, 1604292.
[21] Shyu, T. C.; Damasceno, P. F.; Dodd, P. M.; Lamoureux, A.; Xu, L.; Shlian, M.; Shtein, M.; Glotzer, S. C.; Kotov, N. A. A kirigami approach to engineering elasticity in nanocomposites through patterned defects. Nat. Mater. 2015, 14, 785-789.
[22] Morikawa, Y.; Yamagiwa, S.; Sawahata, H.; Numano, R.; Koida, K.; Ishida, M.; Kawano, T. Ultrastretchable Kirigami Bioprobes. Adv. Healthc. Mater. 2018, 7, 1701100.
[23] Xu, R.; Zverev, A.; Hung, A.; Shen, C.; Irie, L.; Ding, G.; Whitmeyer, M.; Ren, L.; Griffin, B.; Melcher, J.; Zheng, L.; Zang, X.; Sanghadasa, M.; Lin, L. Kirigami-inspired, highly stretchable micro-supercapacitor patches fabricated by laser conversion and cutting. Microsyst. Nanoeng. 2018, 4, 36.
[24] Novoselov, K. S.; Fal'ko, V. I.; Colombo, L.; Gellert, P. R.; Schwab, M. G.; Kim, K. A roadmap for graphene. Nature 2012, 490, 192-200.
[25] Akinwande, D.; Petrone, N.; Hone, J. Two-dimensional flexible nanoelectronics. Nat. Commun. 2014, 5, 5678.
[26] Lee, C.; Wei, X.; Kysar, J. W.; Hone, J. Measurement of the elastic properties and intrinsic strength of monolayer graphene. Science 2008, 321, 385-388.
[27] Chung, C.; Kim, Y. K.; Shin, D.; Ryoo, S. R.; Hong, B. H.; Min, D. H. Biomedical applications of graphene and graphene oxide. Acc. Chem. Res. 2013, 46, 2211-2224.
[28] Snapp, P.; Kang, P.; Leem, J.; Nam, S. Colloidal Photonic Crystal Strain Sensor Integrated with Deformable Graphene Phototransducer. Adv. Funct. Mater. 2019, 29, 1902216.
[29] Kang, P.; Wang, M. C.; Knapp, P. M.; Nam, S. Crumpled Graphene Photodetector with Enhanced, Strain-Tunable, and Wavelength-Selective Photoresponsivity. Adv. Mater. 2016, 28, 4639-4645.
[30] Yong, K.; De, S.; Hsieh, E. Y.; Leem, J.; Aluru, N. R.; Nam, S.-W. Kirigami-inspired strain-insensitive sensors based on atomically-thin materials. Mater. Today 2019, DOI: 10.1016/j.mattod.2019.08.013.
[31] Isobe, M.; Okumura, K. Initial rigid response and softening transition of highly stretchable kirigami sheet materials. Sci. Rep. 2016, 6, 24758.
[32] Lu, N.; Wang, X.; Suo, Z.; Joost, V. Metal films on polymer substrates stretched beyond 50%. Appl. Phys. Lett. 2007, 91, 221909.
[33] Matsuhisa, N.; Jiang, Y.; Liu, Z.; Chen, G.; Wan, C.; Kim, Y.; Kang, J.; Tran, H.; Wu, H.-C.; You, I.; Bao, Z.; Chen, X. High-Transconductance Stretchable Transistors Achieved by Controlled Gold Microcrack Morphology. Adv. Electron. Mater. 2019, 5, 1900347.
[34] Cao, W.; Görrn, P.; Wagner, S. Modeling the electrical resistance of gold film conductors on uniaxially stretched elastomeric substrates. Appl. Phys. Lett. 2011, 98, 212112.
[35] Lee, S. K.; Kim, B. J.; Jang, H.; Yoon, S. C.; Lee, C.; Hong, B. H.; Rogers, J. A.; Cho, J. H.; Ahn, J. H. Stretchable graphene transistors with printed dielectrics and gate electrodes. Nano. Lett. 2011, 11, 4642-4646.
[36] Feldman, B.; Heller, A. Electrochemical glucose sensors and their applications in diabetes management Chem. Rev. 2008, 108, 2482-2505.
[37] Huang, Y.; Dong, X.; Shi, Y.; Li, C. M.; Li, L. J.; Chen, P. Nanoelectronic biosensors based on CVD grown graphene. Nanoscale 2010, 2, 1485-1488.
[38] Zhang, M.; Liao, C.; Mak, C. H.; You, P.; Mak, C. L.; Yan, F. Highly sensitive glucose sensors based on enzyme-modified whole-graphene solution-gated transistors. Sci. Rep. 2015, 5, 8311.
[39] Lee, H.; Song, C.; Hong, Y. S.; Kim, M. S.; Cho, H. R.; Kang, T.; Shin, K.; Choi, S. H.; Hyeon, T.; Kim, D. H. Wearable/disposable sweat-based glucose monitoring device with multistage transdermal drug delivery module. Sci. Adv. 2017, 3, e1601314.

### Example 4B: Supplementary Material to Example 4A

We evaluated the mechanical response of 10 μm thick kirigami designs with varying design parameters g where g={W,BW,CW,H,BH,CH}. Here, initial total length of the kirigami structure L_{T}[μm]=18 W+21BW+2H+1000 (FIG. 29A). L_{T} is the sum of the width of 36 P1 plates, 18 P2 plates, 21 P3 plates, and 2 islands. The width of P3 plates that is connected to the pads at the end of the kirigami design is defined as BW+500 μm, so the sum of the width of 21 P3 plates is 21BW+1000 μm. As shown in FIGS. 29B and 29C, CW and BH, which are not related to L_{T} barely affected the mechanical response of the kirigami structure. On the other hand, the increase of CH allowed more elongation of the kirigami structure (FIG. 29D). In addition, increasing either BW or W, which increases L_{T}, caused reduced stretchability of the kirigami structure (FIGS. 29E and 29F). This parametric study gives clear insight into the effects of geometric parameters on the stretchability of the kirigami; the bendability of the P1 plate, which is proportional to CH, determines the overall stretchability of kirigami structure.

FIGS. 30A-30C show a σₙ-εₙ curve of the kirigami structure for different PI film thicknesses. As the thickness of the PI film increases, the strain at which transition from stage I to stage II occurs (εₜᵣₐₙₛ) increases (FIG. 30A). M. Isobe and K. Okumura derived an analytical solution of εₜᵣₐₙₛ using simplified beam theory and with the assumption that the transition from stage I to stage II occurs when the deformation energy of in-plane bending becomes equal to that of out-of-plane bending [1]:

εₜᵣₐₙₛ≅(t/((W−CH)/2))² (S1)

Our simulation result was consistent with eq. (51) (FIG. 30B).

In stage II, where the out-of-plane bending is the main deformation mechanism, the thicker kirigami structure is stiffer. On the other hand, in stage III, the σₙ-εₙ curves were independent of the thickness of PI film. This indicates that the main deformation mechanism changes from the bending to in-plane stretching in stage III.

Discussions:

Here, we derive an analytic equation that relates the nominal strain εₙ of kirigami structures at a certain nominal stress a with the design parameters (g) and thickness (t) to stretchability (δ₉). g is a set of design parameters ({W,BW,CW,H,BH,CH}).

First, because out-of-plane bending of the P1 plate is a key factor in determining the overall deformation of kirigami structures, the relationship between εₙ and t can be derived as follows. When t is negligibly small, the stretchability of the kirigami structure is no longer limited by the bending of the P1 plates but rather by the geometric restrictions. This implies that εₙ(σ) is asymptotically independent of t and is a sole function of g as t approaches 0. On the other hand, when t becomes large, the bending of P1 plates is the limiting factor for deformation. In this case of large t, εₙ(σ)∝σ/t⁻² [2].

Therefore, nominal strain at a stress a can be expressed as follows:

εₙ(σ;t,g)=k₃(σ;t,g)(k₁(g)/(1+k₂t²))σ (S2)

where k₁ is a stiffness of zero-thickness kirigami structure with a certain g, k₂ is a thickness-correction factor, and k₃ is an additional factor to compensate for the non-linear εₙ-σ relationship, which is a function of σ, t, g.

If the bending of the P1 plates dominates the deformation of kirigami structures, eq. (S2) should satisfy the aforementioned asymptotic behaviors. When t is sufficiently small, eq. (S2) reduces to

$${ɛ}_{n} ( σ ; t , g ) = {lim}_{t \to 0} {k}_{3} ( σ ; t , g ) = {k}_{1} ( g ) σ , so {ɛ}_{n} ( σ )$$

is asymptotically independent of t as expected. However, in the case of large t, εₙ(σ; t, g) is proportional to (k₃(σ; t, g))σ/t⁻² according to eq. (S2). Therefore, eq. (S2) can satisfy the asymptotic behavior εₙ(σ)∝σ/t⁻² only if k₃(σ; t, g) is weak function of t. In other words, the assumption that the bending of P1 plates governs the deformation of kirigami structures means that k₃(σ; t, g) is weak function of t.

Then, to incorporate δₘ in eq. (S2), we define one additional factor k₄(σ; g) as follows:

$${lim}_{t \to 0} {ɛ}_{n} ( σ ; t , g ) = {k}_{4} ( σ ; g ) {δ}_{m} ( g ) . \qquad ( S3 )$$

From the comparison between eq. (S3) and the relation εₙ(10 MPa; 10 μm, g)≈0.8×δₘ(g) obtained from FEA simulations (FIG. 29G), it can be inferred that k₄(δ; g) is a weak function of g when σ is around 10 MPa. That is, at a certain σ˜10 MPa, k₄(σ; g) can be treated as a constant regardless of g.

$$\begin{matrix}Since {lim}_{t \to 0} {ɛ}_{n} ( σ ; t , g ) = ( {lim}_{t \to 0} {k}_{3} ( σ ; t , g ) ) {k}_{1} ( g ) σ , {k}_{1} ( g ) can be re \text{-} expressed with {k}_{4} ( σ ; g ) , & ( S4 ) \\ {k}_{1} ( g ) = {k}_{4} ( σ ; g ) {δ}_{m} / [ {lim}_{t \to 0} {k}_{3} ( σ ; t , g ) σ ] . & \end{matrix}$$

By substituting eq. (S4) into eq. (S2),

$${ɛ}_{n} ( σ ; t , g ) = \frac{{k}_{3} ( σ ; t , g )}{{lim}_{t \to 0} {k}_{3} ( σ ; t , g )} ( \frac{{k}_{4} ( σ ; g )}{1 + {k}_{2} {t}^{2}} ) {δ}_{m} ( g ) \qquad ( S5 )$$

Equation (S5) is exact and it holds for every range of σ, t and g.

Since k₃(σ; t, g) is a weak function of t and k₄(σ; g) is a weak function of g when σ˜10 MPa in the thickness range of 5 to 125 μm as mentioned above,

$${ɛ}_{n} ( σ ; t , g ) \approx ( \frac{{k}_{4} ( σ )}{1 + {k}_{2} {t}^{2}} ) {δ}_{m} ( g ) \qquad ( S6 )$$

Equation (S6) allows us to define a dimensionless geometric parameter δ_{g} in the main text,

$${δ}_{g} = ( \frac{{c}_{1}}{1 + {c}_{2} {t}^{2}} ) {δ}_{m} ,$$

where c₁ and c₂ are constants.

According to eq. (S5) and (S6), δ₉ with proper choice of c₁ and c₂ represents εₙ(σ; t, g) at a certain σ=σ₀ (εₙ(δ₀; t, g)).

### REFERENCES

[1] Isobe, M.; Okumura, K. Initial rigid response and softening transition of highly stretchable kirigami sheet materials. Sci. Rep. 2016, 6, 24758.
[2] Shyu, T. C.; Damasceno, P. F.; Dodd, P. M.; Lamoureux, A.; Xu, L.; Shlian, M.; Shtein, M.; Glotzer, S. C.; Kotov, N. A. A kirigami approach to engineering elasticity in nanocomposites through patterned defects. Nat. Mater. 2015, 14, 785-789.

### STATEMENTS REGARDING INCORPORATION BY REFERENCE AND VARIATIONS

All references throughout this application, for example patent documents including issued or granted patents or equivalents; patent application publications; and non-patent literature documents or other source material; are hereby incorporated by reference herein in their entireties, as though individually incorporated by reference, to the extent each reference is at least partially not inconsistent with the disclosure in this application (for example, a reference that is partially inconsistent is incorporated by reference except for the partially inconsistent portion of the reference).

The terms and expressions which have been employed herein are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments, exemplary embodiments and optional features, modification and variation of the concepts herein disclosed may be resorted to by those skilled in the art, and that such modifications and variations are considered to be within the scope of this invention as defined by the appended claims. The specific embodiments provided herein are examples of useful embodiments of the present invention and it will be apparent to one skilled in the art that the present invention may be carried out using a large number of variations of the devices, device components, methods steps set forth in the present description. As will be obvious to one of skill in the art, methods and devices useful for the present methods can include a large number of optional composition and processing elements and steps.

As used herein and in the appended claims, the singular forms “a”, “an”, and “the” include plural reference unless the context clearly dictates otherwise. Thus, for example, reference to “a cell” includes a plurality of such cells and equivalents thereof known to those skilled in the art. As well, the terms “a” (or “an”), “one or more” and “at least one” can be used interchangeably herein. It is also to be noted that the terms “comprising”, “including”, and “having” can be used interchangeably. The expression “of any of claims XX-YY” (wherein XX and YY refer to claim numbers) is intended to provide a multiple dependent claim in the alternative form, and in some embodiments is interchangeable with the expression “as in any one of claims XX-YY.”

When a group of substituents is disclosed herein, it is understood that all individual members of that group and all subgroups, including any isomers, enantiomers, and diastereomers of the group members, are disclosed separately. When a Markush group or other grouping is used herein, all individual members of the group and all combinations and subcombinations possible of the group are intended to be individually included in the disclosure. When a compound is described herein such that a particular isomer, enantiomer or diastereomer of the compound is not specified, for example, in a formula or in a chemical name, that description is intended to include each isomers and enantiomer of the compound described individual or in any combination. Additionally, unless otherwise specified, all isotopic variants of compounds disclosed herein are intended to be encompassed by the disclosure. For example, it will be understood that any one or more hydrogens in a molecule disclosed can be replaced with deuterium or tritium. Isotopic variants of a molecule are generally useful as standards in assays for the molecule and in chemical and biological research related to the molecule or its use. Methods for making such isotopic variants are known in the art. Specific names of compounds are intended to be exemplary, as it is known that one of ordinary skill in the art can name the same compounds differently.

Certain molecules disclosed herein may contain one or more ionizable groups [groups from which a proton can be removed (e.g., —COOH) or added (e.g., amines) or which can be quaternized (e.g., amines)]. All possible ionic forms of such molecules and salts thereof are intended to be included individually in the disclosure herein. With regard to salts of the compounds herein, one of ordinary skill in the art can select from among a wide variety of available counterions those that are appropriate for preparation of salts of this invention for a given application. In specific applications, the selection of a given anion or cation for preparation of a salt may result in increased or decreased solubility of that salt.

Every sensor, device, system, material, combination of components, or method described or exemplified herein can be used to practice the invention, unless otherwise stated.

Whenever a range is given in the specification, for example, a temperature range, a time range, or a composition or concentration range, all intermediate ranges and subranges, as well as all individual values included in the ranges given are intended to be included in the disclosure. It will be understood that any subranges or individual values in a range or subrange that are included in the description herein can be excluded from the claims herein.

All patents and publications mentioned in the specification are indicative of the levels of skill of those skilled in the art to which the invention pertains. References cited herein are incorporated by reference herein in their entirety to indicate the state of the art as of their publication or filing date and it is intended that this information can be employed herein, if needed, to exclude specific embodiments that are in the prior art. For example, when composition of matter are claimed, it should be understood that compounds known and available in the art prior to Applicant's invention, including compounds for which an enabling disclosure is provided in the references cited herein, are not intended to be included in the composition of matter claims herein.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. In each instance herein any of the terms “comprising”, “consisting essentially of” and “consisting of” may be replaced with either of the other two terms. The invention illustratively described herein suitably may be practiced in the absence of any element or elements, limitation or limitations which is not specifically disclosed herein.

One of ordinary skill in the art will appreciate that starting materials, biological materials, reagents, synthetic methods, purification methods, analytical methods, assay methods, and biological methods other than those specifically exemplified can be employed in the practice of the invention without resort to undue experimentation. All art-known functional equivalents, of any such materials and methods are intended to be included in this invention. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

1. A sensor characterized by strain-insensitivity, the sensor comprising:
a sheet in electrical communication with a positive electrode and a negative electrode;
wherein the sheet comprises:
an electrically conductive primary layer in electrical communication with the positive electrode and the negative electrode;
at least one active-sensing region comprising at least one sensor-portion of the primary layer and in electrical communication with the positive electrode and the negative electrode; wherein the sensor is configured to perform sensing at the at least one active-sensing region;
at least one secondary layer covering or encapsulating the primary layer except at each sensor-portion; and
at least one perforated region having a perforation design configured to provide for the sensor's strain-insensitivity.

2. The sensor of claim 1, wherein the strain-insensitivity is characterized by a strain-induced change of at least one figure-of-merit of the sensor being less than 10% if the sheet is strained; wherein strain experienced by the strained sheet is characterized by uniaxial strain of at least 50%, multiaxial strain of at least 50%, torsional strain of at least 90°, or a combination of these.

3. A sensor characterized by strain-insensitivity, comprising:
a sheet in electrical communication with a positive electrode and a negative electrode;
wherein the sheet comprises:
an electrically conductive primary layer in electrical communication with the positive electrode and the negative electrode;
at least one active-sensing region comprising at least one sensor-portion of the primary layer and in electrical communication with the positive electrode and the negative electrode; wherein the sensor is configured to perform sensing at the at least one active-sensing region; and
a perforated region having a perforation design configured to provide for the sensor's strain-insensitivity; wherein the strain-insensitivity is characterized by a strain-induced change of at least one figure-of-merit of the sensor being less than 10% if the sheet is strained;
wherein strain experienced by the strained sheet is characterized by uniaxial strain of at least 50%, multiaxial strain of at least 50%, torsional strain of at least 90°, or a combination of these.

4-18. (canceled)

19. The sensor of claim 1, wherein the strain-insensitivity is further characterized by stress at the least one active-sensing region being at most 10 MPa if the sheet is strained.

20. (canceled)

21. The sensor of claim 1, wherein stress within 40% of maximum stress is localized at locations of highest curvature at the at least one perforated region when the sheet is strained; and wherein a location corresponding to stress within 20% of maximum stress is constant if the sheet is strained.

22-24. (canceled)

25. The sensor of claim 1, wherein the perforation design is further configured such that, if the sheet is strained, at least a portion of the sheet is characterized by an out-of-plane deformation.

26. The sensor of claim 25, wherein the out-of-plane deformation occurs at one or more perforated regions of the at least one perforated region.

27. (canceled)

28. The sensor of claim 2, wherein the at least one figure-of-merit is selected from the group consisting of a strain gauge factor (SGF), a specific detectivity, a normalized photocurrent, a responsivity, a transconductance, efficiency, fill factor, turn-on voltage, minimum detectable analyte concentration, resistance or resistivity, a normalized change in resistance or resistivity, and any combination thereof.

29. (canceled)

30. The sensor of claim 1, wherein the sensor is selected from the group consisting of a photodetector, a biological analyte sensor, a temperature sensor, a pressure sensor, a field-effect transistor, or a combination of these.

31. The sensor of claim 1, wherein the sensor comprises a plurality of sensor-portions and the plurality of sensor-portions are configured for sensing of a plurality of analytes or environmental characteristics.

32-35. (canceled)

36. The sensor of claim 1, wherein each active-sensing region is directly connected to at least one perforated region.

37-38. (canceled)

39. The sensor of claim 1, wherein when the sheet is strained, the resulting stress is highest at a perforated region and lowest at an active-sensing region.

40. (canceled)

41. The sensor of claim 1, wherein the sheet comprises a plurality of active-sensing regions.

42-44. (canceled)

45. The sensor of claim 1, wherein the sensor comprises a plurality of positive electrodes, a plurality of negative electrodes, a plurality of perforated regions, and a plurality of active-sensing regions.

46. The sensor of claim 1, wherein the primary layer or the sensor-portion of the primary layer comprises graphene, a metal, or a metal alloy.

47. The sensor of claim 1, wherein a top-view area of the primary layer corresponds at least 80% of a top-view area of the sheet.

48. (canceled)

49. The sensor of claim 1, wherein the perforated region comprises a perforated portion and a remaining portion; wherein a top-view area of the remaining portion is 30% to 90% of a top-view area of the perforated region.

50. The sensor of claim 1, wherein a thickness of the sheet is less than or equal to 100 μm.

51. (canceled)

52. The sensor of claim 1, wherein the secondary layer is electrically insulating.

53-59. (canceled)

60. The sensor of claim 1, wherein the perforation design comprises a plurality of internal cutouts and a plurality of external cutouts.

61. The sensor of claim 1, wherein each perforated region forms a bridge (i) between one active-sensing region and one of a positive electrode or a negative electrode or (ii) between two active sensing regions.

62-63. (canceled)

64. The sensor of claim 1 comprising a plurality of the perforated regions; wherein the plurality of the perforated regions comprises at least one perforated region having a first length axis and at least one perforated region having a second length axis; wherein the first length axis and the second length axis are different.

65. The sensor of claim 64, wherein each active-sensing region is physically connected to at least one perforated region characterized by a first length axis and to at least one perforated region characterized by a second length axis; wherein the second length axis is different from the first length-direction.

66. (canceled)

67. The sensor of claim 1, wherein each perforated region and each active-sensing region is at least partially suspended in air.

68-70. (canceled)

71. The sensor of claim 1, wherein each perforated region is: (i) between one active-sensing region and one of a positive electrode or a negative electrode, or (ii) between two active sensing regions; wherein each perforated region has a first end and a second end; and wherein the first end of each perforated region is physically connected to an active-sensing region or a positive electrode or a negative electrode and the second end of each perforated region is physically connected to a different one of an active-sensing region or a positive electrode or a negative electrode.

72-75. (canceled)

76. A method of making a strain-insensitive sensor, the method comprising steps of:
perforating a sheet according to a perforation design to form at least one perforated region of the sheet; and
providing the sheet in electrical communication with a positive electrode and a negative electrode;
wherein the sheet comprises:
an electrically conductive primary layer in electrical communication with the positive electrode and the negative electrode; and
at least one active-sensing region comprising at least one sensor-portion of the primary layer and in electrical communication with the positive electrode and the negative electrode; wherein the sensor is configured to perform sensing during use at the at least one active-sensing region;
wherein the perforation design is configured to provide for the sensor's strain-insensitivity.

77-79. (canceled)
